(19) United States
(12) Patent Application Publication
(10) Pub. No.: US 2015/0054594 A1
(43) Pub. Date: Feb. 26, 2015

(54) SWITCH

(71) Applicant: Nanyang Technological University, Singapore (SG)

(72) Inventors: Anak Agung Alit Apriyana, Singapore (SG); Yue Ping Zhang, Singapore (SG)

(21) Appl. No.: 14/377,108

(22) PCT Filed: Feb. 5, 2013
(86) PCT No.: PCT/SG2013/000046

§ 371 Date: Aug. 6, 2014

Related U.S. Application Data
(60) Provisional application No. 61/595,468, filed on Feb. 6, 2012.

(51) Int. Cl. H03H 11/30

(52) U.S. Cl. CPC H03H 11/30
USPC 333/103

(57) ABSTRACT

A switch for controlling signal propagation between a first and second contact is proposed. This switch comprises a control mechanism configured to allow signal propagation between the first and second contacts when the switch is turned on and prevent signal propagation between the first and second contacts when the switch is turned off. The switch also comprises a compensating member having a transmission line and a ground plane. The ground plane in turn comprises at least one defect configured to affect one or both of the inductance and capacitance of the transmission line when signals propagate through the transmission line.

### FIELD OF THE INVENTION

The present invention relates to a switch, in particular a Single-Pole-Single-Throw (SPST) switch. The SPST switch can be used to construct Single-Pole-Multiple-Throws (SPMT) switches, Multiple-Poles-Single-Throw (MPST) switches or Multiple-Pole-Multiple-Throws (MPMT) switches. These SPMT, MPST or MPMT switches can in turn be used to implement transmit/receive (T/R) switches.

### BACKGROUND OF THE INVENTION

Due to an increasing demand for system miniaturization, the Time Division Multiple Access (TDMA) system is becoming more favored over the full duplex system. This is because using the TDMA system facilitates the integration of components in the RF front-end system into a single chip or package. This is in turn due to the following reasons.

Firstly, the TDMA system uses the same transmit and receive frequencies, and thus, can use a single antenna to transmit and receive signals. To allow only either the transmitter section (having at least one transmitter) or the receiver section (having at least one receiver) to operate at any one time, the TDMA system employs a T/R switch to alternately connect the antenna to the transmitter and receiver sections. On the other hand, the full duplex system uses separate transmit and receive frequencies, and thus, usually requires separate antennas and one or more duplexers to isolate the transmitter and receiver sections. As integration of multiple antennas into a single chip or package can be very costly, using the TDMA system allows for a more cost-effective way of integrating components in the RF front-end system into a single chip or package.

Secondly, a more compact and low cost wireless system can be achieved with a full silicon integration of the baseband and RF functionality into a single chip. With the advance in CMOS process technology, it is possible to implement T/R switches for TDMA systems using silicon-based technology. In fact, it is becoming more attractive to replace current off-chip non-silicon-based T/R switches (such as the pin-diode and GaAs switch) with silicon-based T/R switches (which utilize CMOS transistors as the control elements). This is because although the GaAs switch has been the benchmark of T/R switches due to its good insertion loss and isolation performance, the silicon-based CMOS process can be performed at a substantially lower cost than the GaAs process. Furthermore, as compared to GaAs devices, enhancement mode CMOS devices are more suitable for use in hand-held battery operated applications due to their positive control signals [1]. Thus, it is attractive to implement TDMA systems using silicon-based technology. However, this is not the case for full duplex systems. Full duplex systems generally require duplexers which are now mostly fabricated using the Surface Acoustic Wave (SAW) technology. This SAW technology is based on piezoelectric substrates rather than on silicon substrates i.e. it is a non-silicon-based technology. Although duplexers fabricated using silicon-based technology are available, the performance of such duplexers is usually not as good as that of duplexers fabricated using SAW technology. This is because of the high conductivity of silicon substrates which in turn makes it challenging to obtain a good insertion loss and isolation performance for duplexers fabricated with silicon substrates. Therefore, to implement a full silicon integration of the baseband and RF functionality into a single chip, it is preferable to use the TDMA system.

As mentioned above, in a TDMA system, a T/R switch is used to alternately connect the antenna to the transmitter and receiver sections. In other words, the T/R switch is responsible for bridging the three main departments of a wireless system, i.e. the antenna, the transmitter section and the receiver section. Therefore, T/R switches play a very crucial role in TDMA systems. FIGS. 1 and 2 respectively show a single-band TDMA system and a dual-band TDMA system, each having a T/R switch. Specifically, in the single-band TDMA system as shown in FIG. 1, a T/R switch in the form of a Single-Pole-Dual-Throws (SPDT) switch is used to alternately connect an antenna port to a transmitter port and a receiver port. The antenna port is in turn connected to an antenna, whereas the transmitter and receiver ports are in turn respectively connected to a transmitter and a receiver. In the dual-band TDMA system as shown in FIG. 2, a T/R switch in the form of a Single-Pole-Four-Throws (SP4T) switch is used to selectively connect an antenna port to one of four transmitter and receiver ports. Similarly, the antenna port is in turn connected to an antenna, whereas the transmitter and receiver ports are in turn respectively connected to transmitters TX1, TX2 and receivers RX1, RX2.

Designing CMOS T/R switches so as to match the performance of GaAs T/R switches is a very challenging task. This is due to the high conductivity, low carrier mobility, and low breakdown voltage of the silicon substrate. Designing CMOS T/R switches for millimeter wave applications is even more challenging due to the nearby cut-off frequency (f_{c}) and maximum oscillation frequency (fₘₐₓ) of such switches. In particular, depending on the devices' lengths, the cut-off frequencies and maximum oscillation frequencies for T/R switches fabricated with 65 nm CMOS technology lie in the range of 200-300 GHz. Thus, the knee frequencies for such devices can occur as early as 80-90 GHz after which the frequency roll-off for the devices is inevitable.

Several attempts have been made to develop SPST and SPMT switches which can be used to implement T/R switches. Some of these attempts are described below.

For example, FIGS. 3(a) and (b) respectively show the schematic and die micrograph of a 60 GHz SPST switch proposed by He et al. [17]-[18]. As shown in FIGS. 3(a) and (b), this SPST switch comprises a series inductor L₁ and two shunt transistors M₁, M₂, with the series inductor L₁ and the shunt transistors M₁, M₂ forming a π-network. The series inductor L₁ serves to compensate the parasitic capacitances of the shunt transistors M₁ and M₂. This can help improve the matching performance of the SPST switch and in turn, improve the return loss and insertion loss performance of the SPST switch. However, as reported in [17]-[18], even with the compensation by the series inductor L₁, the SPST switch is only able to achieve a moderate insertion loss of 2.8 dB, a return loss of 6 dB and an isolation of 20 dB across the frequency range of 1-70 GHz. The poor return loss performance of the SPST switch was attributed to a saddling problem arising around the frequency of 40 GHz, which, according to He et al., is introduced by the narrowband matching of the series inductor L₁ which has a high Q-factor. Besides its less than ideal return loss, insertion loss and isolation performance, the SPST switch proposed by He et al. also has the disadvantage that the series inductor L₁ is fixed by the foundry. Thus, there is little design flexibility for tuning the impedance of the SPST switch so as to meet a particular matching condition. Furthermore, as the size of the series inductor L₁ is large, the footprint of the SPST switch is large as well. In particular, the active footprint for the SPST switch is 140×96 μm² whereas the overall chip size for the SPST switch is 340×340 μm².

FIGS. 4(a) and (b) respectively show the schematic and die macrograph of a 94 GHz SPST switch proposed by Tomkins et al. [19]. Similar to the SPST switch proposed by He et al., the SPST switch proposed by Tomkins et al. comprises a series inductor L₁ and a plurality of shunt transistors M₁ₐ, M_{1b}, M_{1c}, M₂ₐ, M_{2b}, M_{c2}. The series inductor L₁ also serves to compensate the parasitic capacitances of the shunt transistors M₁ₐ, M_{1b}, M_{1c}, M₂ₐ, M_{2b}, M_{2c}. In the SPST switch proposed by Tomkins et al. the gate biasing of the shunt transistors M₁ₐ, M_{1b}, M_{1c}, M₂ₐ, M_{2b}, M_{2c} are digitally controlled by a 3-bit control signal. This allows the equivalent on-resistance of the transistors, and hence the isolation performance of the SPST switch, to be digitally adjusted to suit different applications. As reported in [19], the SPST switch when realized in 65 nm Bulk CMOS Technology has a reasonably good performance. In particular, it has an insertion loss of 1.6 dB and an isolation greater than 30 dB across the frequency range of between DC to 94 GHz. However, even though the active footprint of the SPST switch (without including the control pins, testing pads and routing of the 3-bit control signal) is only 65×35 μm², the overall footprint of the switch is much larger (specifically, 520×290 μm²). This is because the use of the 3-bit control signal increases the number of control pins required and the routing complexity in the switch.

FIGS. 5(a)-(b) respectively show the schematic and chip micrograph of a T/R switch in the form of a 60-110 GHz SPDT switch as proposed by Lai et al. [20]. The T/R switch comprises two SPST switches 502a, 502b respectively serving as its TX and RX branches. As shown in FIG. 5(a), each SPST switch 502a, 502b also comprises shunt transistors. However, unlike the SPST switches proposed by He et al. and Tomkins et al., each SPST switch 502a, 502b uses a transmission line to compensate the parasitic capacitances of its shunt transistors. More specifically, each SPST switch 502a, 502b comprises two shunt transistors and a series-stub transmission line between these shunt transistors. Each SPST switch 502a, 502b also comprises short-circuited shunt-stub transmission lines with high characteristic impedance in parallel with the shunt transistors. This helps to improve the matching at the antenna port and the isolation between the TX and RX branches. Although the SPDT switch proposed by Lai et al. can achieve a wide operating frequency range (60 GHz up to 110 GHz) due to the wideband tuning capability of the transmission line, and reasonably good return loss performance (beyond 13 dB across the frequency range of 60-110 GHz) and isolation performance (greater than 25 dB), the insertion loss performance (3-4 dB) of the SPDT switch can at best be considered moderate. Furthermore, due to the use of the two series-stub transmission lines and the four shunt-stub transmission lines to obtain wideband matching across the frequency range of 60-110 GHz, the overall footprint of the SPDT switch is huge (specifically, 750×400 μm²). Hence, it is not cost-effective to implement the chip for the SPDT switch proposed by Lai et al.

FIGS. 6(a)-(b) respectively show the schematic and chip micrograph of a T/R switch in the form of a 50-70 GHz SPDT switch as proposed by Uzunkol et al. [21]. This T/R switch also uses two SPST switches 602a, 602b as its TX and RX branches. As shown in FIG. 6(a), each SPST switch 602a, 602b uses a λ/4 Coplanar Wave-guide (CPW) transmission line and a shunt inductor stub L_{sub} to achieve impedance matching at the antenna port. As reported in [21], the SPDT switch proposed by Uzunkol et al. has a reasonably good performance. In particular, its insertion loss is less than 2 dB and its isolation is more than 25 dB across its operating frequency range. However, due to the use of the λ/4 CPW transmission lines and the shunt inductor stubs L_{sub}, the overall size of the SPDT switch is large (specifically, about 550×500 μm²). This can be seen from FIG. 6(b) which shows the long CPW transmission line (“λ/4 T-line”) forming the bulk of the overall footprint of the SPDT switch. Hence, it is also not cost-effective to implement the SPDT switch proposed by Uzunkol et al.

FIG. 7 shows the lumped equivalent circuit representation of a SPDT switch as proposed by Hettak et al. [22], whereas FIG. 8 shows the chip micrograph and layout for this SPDT switch. As shown in FIGS. 7-8, this SPDT switch comprises elevated coplanar waveguides (ECPW) series stubs and coplanar strip (CPS) series stubs. In FIG. 7, the ECPW series stubs and CPS series stubs are respectively represented by their inductances L_{ECPW} and L_{CPS}. Reference [22] describes the implementation of this SPDT switch in 90 nm CMOS technology. With such an implementation, the multi-level metallization capability of the CMOS process can be exploited to achieve more compact ECPW and CPS series stubs. However, even with such an implementation, the size of the final footprint of the SPDT switch is still large (specifically, the overall chip size for this SPDT switch is 470×161 μm²). Moreover, the insertion loss performance of the SPDT switch is only moderate (about 3.8 dB in the frequency range of between DC to 70 GHz).

References [23]-[26] describe the design and development of CMOS SPDT switches using the travelling wave concept for extending their operating frequency ranges. In particular, FIG. 9(a) shows a T/R switch in the form of a SPDT switch proposed by Chang et al. [24], whereas FIG. 9(b) shows the chip micrograph of this SPDT switch. As shown in FIG. 9(a), the SPDT switch proposed by Chang et al. comprises two SPST switches 902a, 902b. Each SPST switch 902a, 902b in turn comprises a transmission line and a series of shunt transistors controlled by the same control signal (V_{CTRL} or V̅_{CTRL}). Each SPST switch 902a, 902b basically works by periodically loading its inductive transmission line with its shunt transistors. More specifically, for each SPST switch 902a, 902b, when the shunt transistors are turned on, the low on-resistances of the shunt transistors cause RF signals from RX, TX or ANT to sink to ground via the transistors. Therefore, the RF signals are prevented from passing through the switch 902a, 902b. On the other hand, when the shunt transistors are turned off, RF signals are allowed to pass through the inductive transmission line. Specifically, an equivalent transmission line effect is formed via the inductive transmission line and the equivalent shunt capacitances of the transistors. This allows the SPST switch 902a, 902b to have a very wide frequency response. As further shown in FIG. 9(a), the T/R switch proposed by Chang et al. uses a matching T-junction 904 as an impedance transformer to match the impedances of the inductive transmission lines to a 50Ω antenna. Although the switches using the traveling wave concept in references [23]-[26] were found to have an isolation performance better than 38 dB in the frequency range from DC to 70 GHz, these switches were reported to have poor insertion loss performance. In particular, the insertion losses for the switches in references [23]-[24] and [26] were found to be between 4-6 dB in the millimeter wave range. The switch in reference [25] was able to achieve a lower insertion loss (about 2.7-3.3 dB) but this was only possible with a trade off in its isolation performance. Furthermore, due to the use of multiple λ/4 transmission lines to enhance their operating frequency ranges, the overall footprints of switches using the traveling wave concept are usually large. For example, the overall footprint of the switch in reference [24] is about 870×680 μm². Hence, it is also not cost-effective to implement switches using the traveling wave concept.

In view of the above, it can be seen that several factors have to be taken into consideration when designing silicon-based T/R switches. These factors include the overall chip size and cost for the switches, performance of the switches, fabrication simplicity of the switches, and design flexibility for the switches. There are trade-offs among these factors and a switch attaining an optimum trade-off point among these factors will be particularly useful. Unfortunately, none of the switches developed to date (including those mentioned above) can be said to have attained this optimum trade-off point.

### SUMMARY OF THE INVENTION

The present invention aims to provide new and useful switches.

In general terms, the present invention proposes a switch which uses a ground plane (i.e. a conductive layer) having defects (i.e. holes through the ground plane or indentations in the ground plane.

Specifically, a first aspect of the present invention is a Single-Pole-Single-Throw (SPST) switch for controlling signal propagation between a first and second contact, the SPST switch comprising: a control mechanism configured to allow signal propagation between the first and second contacts when the SPST switch is turned on and prevent signal propagation between the first and second contacts when the SPST switch is turned off; and a compensating member having a transmission line and a ground plane, wherein signals allowed by the control mechanism to propagate between the first and second contacts propagate through the transmission line and wherein the ground plane comprises at least one defect configured and arranged with the transmission line so as to affect one or both of the inductance and capacitance of the transmission line when signals propagate through the transmission line.

The compensating member may be a DGS (“defective ground structure” or “defected ground structure”, also referred to as “ground defect structure”) LPF (low pass filter). Also, the SPST switch in the first aspect can be used to implement SPMT, MPST or MPMT switches. These switches can in turn be used to implement T/R switches in TDMA systems.

The present invention also proposes a DGS LPF which uses a transmission line with bends along its length.

Specifically, a second aspect of the present invention is a DGS LPF comprising a transmission line through which signals can propagate; and a ground plane comprising a plurality of first defects spaced apart from one another via one or more spaces and at least one second defect connecting a pair of the first defects across the one or more spaces; wherein the transmission line runs parallel and adjacent to at least part of the one or more spaces and wherein the transmission line comprises bends along its length.

The DGS LPF in the second aspect of the present invention may be used as the compensating member in the first aspect of the present invention.

### BRIEF DESCRIPTION OF THE FIGURES

Embodiments of the invention will now be illustrated for the sake of example only with reference to the following drawings, in which:

FIG. 1 shows a block diagram of a single-band TDMA system having a T/R switch in the form of a SPDT switch;

FIG. 2 shows a block diagram of a dual-band TDMA system having a T/R switch in the form of a SP4T switch;

FIGS. 3(a) and (b) respectively show the schematic and die micrograph of a first prior art SPST switch;

FIGS. 4(a) and (b) respectively show the schematic and die micrograph of a second prior art SPST switch;

FIGS. 5(a) and (b) respectively show the schematic and die micrograph of a T/R switch in the form of a first prior art SPDT switch;

FIGS. 6(a) and (b) respectively show the schematic and die micrograph of a T/R switch in the form of a second prior art SPDT switch;

FIG. 7 shows a lumped equivalent circuit of a third prior art SPDT switch;

FIG. 8 shows the chip micrograph and layout for the third prior art SPDT switch in FIG. 7;

FIGS. 9(a) and (b) respectively show the schematic and chip micrograph of a T/R switch in the form of a fourth prior art SPDT switch;

FIG. 10 shows the schematic of a SPST switch according to a first embodiment of the present invention, the SPST switch comprising shunt transistor control elements and a DGS LPF;

FIG. 11(a) shows the layout of the SPST switch in FIG. 10 together with input and output ports, FIG. 11(b) shows the layout in FIG. 11(a) without the shunt transistor control elements, FIG. 11(c) shows a 3D view of the layout of FIG. 11(b), FIG. 11(d) shows another 3D view of the layout of FIG. 11(b) and FIG. 11(e) shows a plan view of the DGS LPF of the SPST switch in FIG. 10;

FIG. 12 shows an equivalent model of a prior art DGS LPF;

FIG. 13 shows an equivalent model of the DGS LPF of the SPST switch in FIG. 10, together with parasitic capacitances of the input and output ports;

FIG. 14 shows an equivalent model of a prior art Butterworth LPF;

FIG. 15 shows the schematic of one of the shunt transistor control elements in the SPST switch of FIG. 10;

FIGS. 16(a) and (b) respectively show the on-state and off-state equivalent circuits of shunt control transistors in the shunt transistor control element of FIG. 15;

FIG. 17 shows the on-state equivalent circuit of the SPST switch of FIG. 10;

FIG. 18 shows parasitic capacitances of a 16 multi-finger gate transistor with an aspect ratio of W/L=80/0.06;

FIG. 19 shows the off-state equivalent circuit of the SPST switch of FIG. 10;

FIGS. 20(a) and (b) respectively show how the return loss performance and insertion loss performance of a DGS LPF with a basic structure change as the sizes of defect patches in the DGS LPF change;

FIG. 21 shows how the characteristic impedance of the DGS LPF with the basic structure changes as the sizes of defect patches in the DGS LPF change;

FIG. 22 shows simulation results illustrating the expected shift in the operating frequency of the SPST switch of FIG. 10 when defect patches of different sizes are used in the DGS LPF of the SPST switch;

FIGS. 23(a) and (b) respectively shows simulated frequency responses and characteristic impedances of (i) the DGS LPF in the SPST switch implemented with certain parameters, (ii) the DGS LPF in (i) with the addition of input and output ports and (iii) the DGS LPF in (i) with the addition of the shunt transistor control elements;

FIG. 24 shows simulated insertion and return losses of (i) a switch identical to the SPST switch of FIG. 10 but with the DGS LPF not having defects, (ii) a device identical to the SPST switch of FIG. 10 but without the shunt transistor control elements and (iii) the SPST switch of FIG. 10;

FIG. 25 shows simulated input impedance characteristics of (i) the switch identical to the SPST switch of FIG. 10 but with the DGS LPF not having defects, (ii) the device identical to the SPST switch of FIG. 10 but without the shunt transistor control elements and (iii) the SPST switch of FIG. 10;

FIG. 26 shows simulated narrow band insertion losses of the SPST switch of FIG. 10, an inductor-based switch and a transmission-line-based switch;

FIG. 27 shows simulated wide band insertion losses of the SPST switch of FIG. 10, the inductor-based switch and the transmission-line-based switch;

FIG. 28 shows simulated return losses of the SPST switch of FIG. 10, the inductor-based switch and the transmission-line-based switch;

FIG. 29 shows simulated isolation performances of the SPST switch of FIG. 10, the inductor-based switch and the transmission-line-based switch;

FIG. 30 shows the schematic of a SPST switch according to a second embodiment of the present invention;

FIG. 31 shows the schematic of a SPST switch according to a third embodiment of the present invention;

FIG. 32 shows the schematic of a SPST switch according to a fourth embodiment of the present invention;

FIG. 33 shows the schematic of a T/R switch in the form of a SPDT switch according to a fifth embodiment of the present invention, wherein the SPDT switch comprises a TX branch and a RX branch, each formed from the SPST switch of FIG. 10;

FIG. 34 shows a lump elements equivalent circuit of the SPDT switch of FIG. 33 when the RX branch is disabled and the TX branch is enabled;

FIG. 35 shows a simplified version of the lump elements equivalent circuit of FIG. 34;

FIG. 36 shows the schematic of a T/R switch in the form of a SPDT switch according to a sixth embodiment of the present invention, wherein the SPDT switch comprises the SPDT switch of FIG. 33 with a first isolating element;

FIG. 37 shows the schematic of a T/R switch in the form of a SPDT switch according to a seventh embodiment of the present invention, wherein the SPDT switch comprises the SPDT switch of FIG. 33 with a second isolating element;

FIG. 38 shows the schematic of a T/R switch in the form of a SPDT switch according to an eighth embodiment of the present invention, wherein the SPDT switch comprises a TX branch and a RX branch, each formed from the SPST switch of FIG. 30;

FIG. 39 shows a lump elements equivalent circuit of the SPDT switch of FIG. 38;

FIG. 40 shows the schematic of a T/R switch in the form of a SPDT switch according to a ninth embodiment of the present invention, wherein the SPDT switch comprises a TX branch formed from the SPST switch of FIG. 31 and a RX branch formed from the SPST switch of FIG. 32;

FIG. 41 shows the schematic of a T/R switch in the form of a SP4T switch according to a tenth embodiment of the present invention, wherein the SP4T switch comprises TX and RX branches, each formed from the SPST switch of FIG. 30;

FIG. 42 shows an equivalent circuit of the SP4T switch of FIG. 41;

FIG. 43 shows an equivalent circuit illustrating the off-impedance of one of the branches of the SP4T switch of FIG. 41;

FIG. 44 shows the schematic of a T/R switch in the form of a SP4T switch according to an eleventh embodiment of the present invention, wherein the SP4T switch comprises TX branches formed from the SPST switch of FIG. 31 and RX branches formed from the SPST switch of FIG. 32;

FIG. 45 shows the schematic of a SPMT switch implemented on the basis of the SPST switch of FIG. 30 using a cascaded multi-throws approach;

FIG. 46 shows an example implementation of the SPMT switch of FIG. 45 as a T/R switch in the form of a SPDT switch;

FIG. 47 shows an example layout implementation of the SPDT switch of FIG. 46;

FIG. 48 shows an example implementation of the SPMT switch of FIG. 45 as a T/R switch in the form of a SP4T switch;

FIG. 49 shows an example layout implementation of the SP4T switch of FIG. 46;

FIG. 50 shows an example layout implementation of a SP8T switch implemented based on the SPMT switch of FIG. 45;

FIGS. 51(a)-(c) show the performance of a SPST switch having the structure of the SPST switch of FIG. 30;

FIGS. 52(a)-(c) respectively show the simulated insertion loss performance, isolation performance and return loss performance of a SPDT switch implemented using the SPST switch with the performance in FIGS. 51(a)-(c);

FIG. 53 shows the simulated characteristic impedance of the SPDT switch with the simulated performances in FIGS. 52(a)-(c);

FIGS. 54(a)-(c) respectively show the simulated insertion loss performance, isolation performance and return loss performance of a SP4T switch implemented using the SPST switch with the performance in FIGS. 51(a)-(c);

FIG. 55 shows the simulated characteristic impedance of the SP4T switch with the simulated performances in FIGS. 54(a)-(c);

FIGS. 56(a)-(c) respectively show simulated insertion loss performance, isolation performance and return loss performance of a SPDT switch implemented using the cascaded multi-throws approach with the structure in FIG. 46 and example layout implementation in FIG. 47;

FIGS. 57(a)-(d) respectively show simulated insertion loss performance, return loss performance, antenna isolation performance and transmitter isolation performance of a SP4T switch implemented using the cascaded multi-throws approach with the structure in FIG. 48 and example layout implementation in FIG. 49;

FIGS. 58(a)-(b) respectively show simulated insertion loss performance and isolation performance of a SP8T switch implemented using the cascaded multi-throws approach with the example layout implementation in FIG. 50;

FIG. 59 shows a perspective view of the DGS LPF with the basic structure having the insertion loss and return loss performance in FIGS. 20(a)-(b) and the characteristic impedance in FIG. 21.;

FIGS. 60(a)-(b) respectively show a plan view and a 3D view of a DGS LPF with a structure derived from the basic structure of FIG. 59;

FIGS. 61(a)-(b) respectively show changes in the insertion loss performance and the return loss performance of the DGS LPF of FIG. 59 as a first dimension of a gap in the DGS LPF changes;

FIGS. 62(a)-(b) respectively show changes in the insertion loss performance and the return loss performance of the DGS LPF of FIG. 59 as a second dimension of the gap in the DGS LPF changes;

FIG. 63 shows a LC network arranged with a NMOS transistor for floating the bulk of the NMOS transistor;

FIG. 64 shows a DGS LPF arranged with a NMOS transistor for floating the bulk of the NMOS transistor;

FIG. 65 shows the schematic of a SPST switch comprising a floating mechanism for floating the bulks of the control transistors in the switch, wherein the floating mechanism comprises DGS LPFs;

FIG. 66 shows the schematic of a SPDT switch comprising a floating mechanism for floating the bulks of the control transistors in the switch, wherein the floating mechanism comprises DGS LPFs;

FIG. 67 shows the schematic of a SP4T switch comprising a floating mechanism for floating the bulks of the control transistors in the switch, wherein the floating mechanism comprises a single DGS LPF;

FIG. 68(a) shows a simulated magnetic field (H-field) distribution across the SPST switch of FIG. 10 in an example implementation of the switch, FIG. 68(b) shows a magnified version of the H-field distribution in FIG. 68(a) across the DGS LPF, and FIG. 68(c) shows a simulated H-field distribution across a switch having the same structure as the switch of FIG. 10 but without defects in the ground plane;

FIG. 69(a) shows a simulated E-field distribution across the SPST switch of FIG. 10 in an example implementation of the switch and FIG. 69(b) shows a magnified view of the E-field distribution in FIG. 69(a) across the DGS LPF.

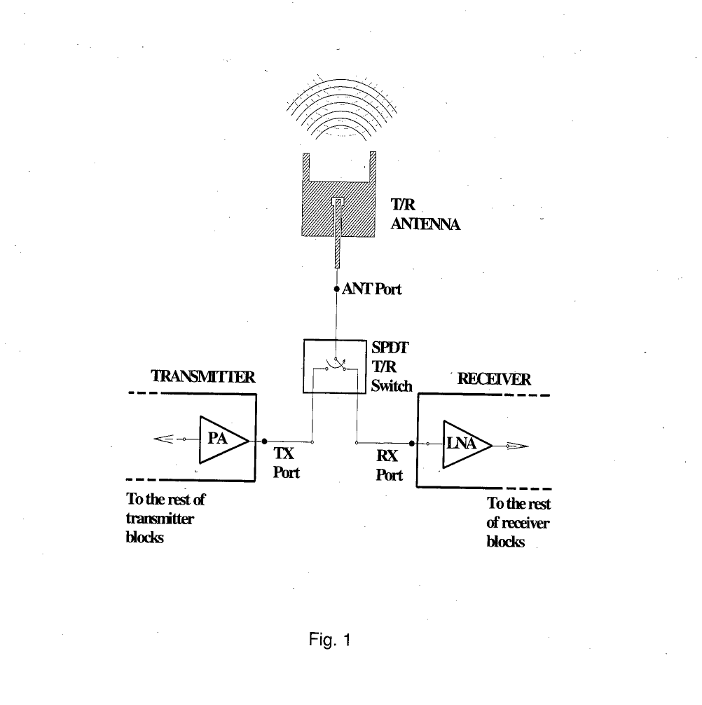

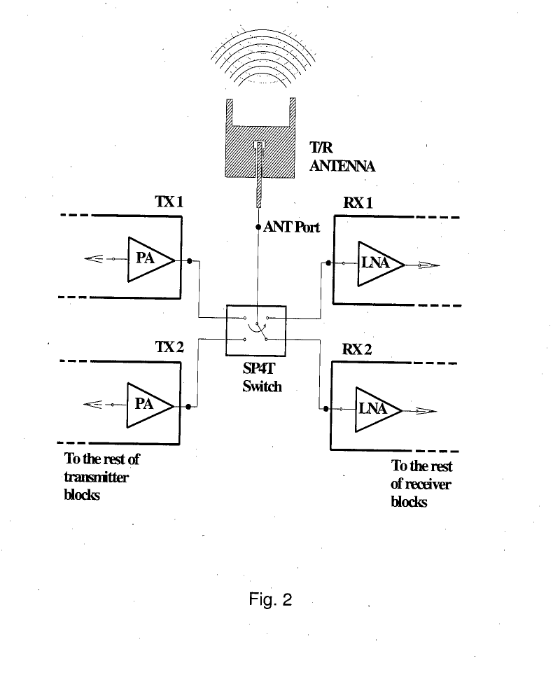

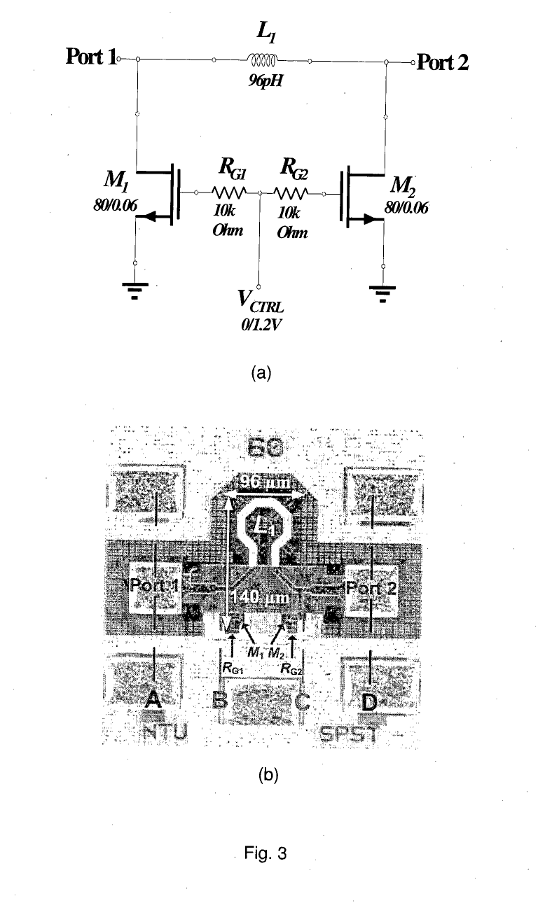

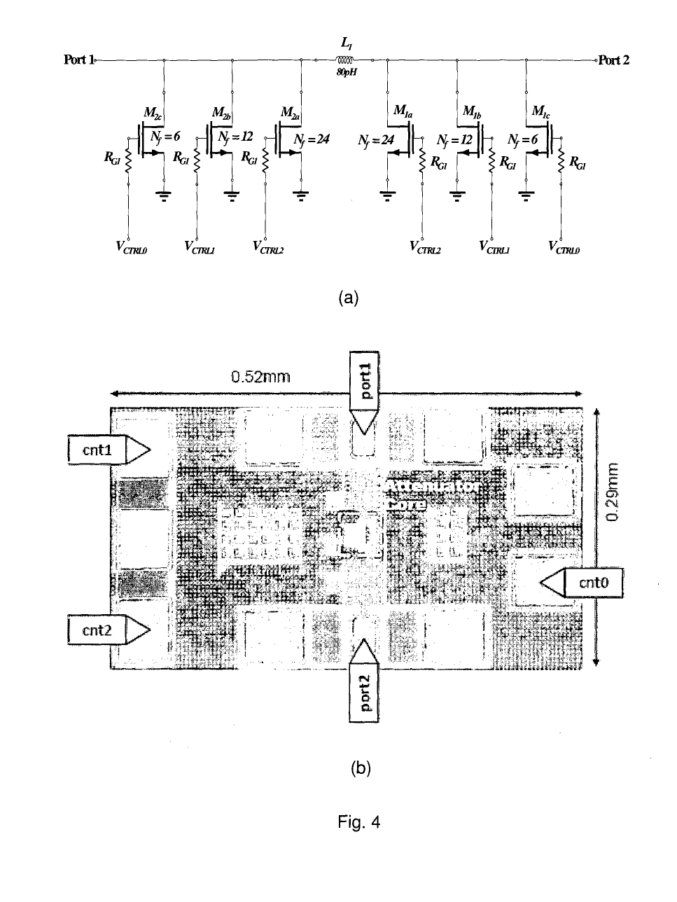

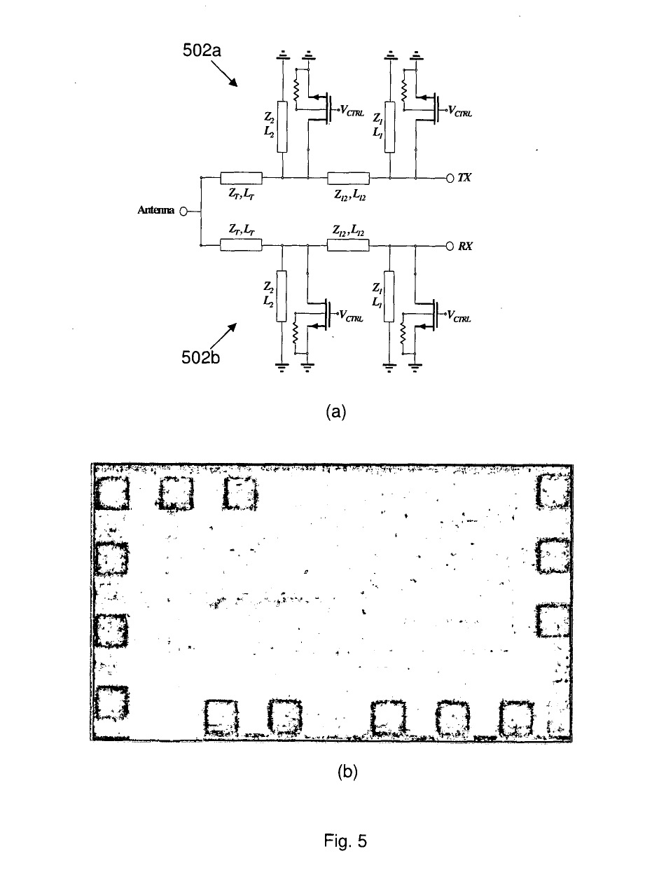

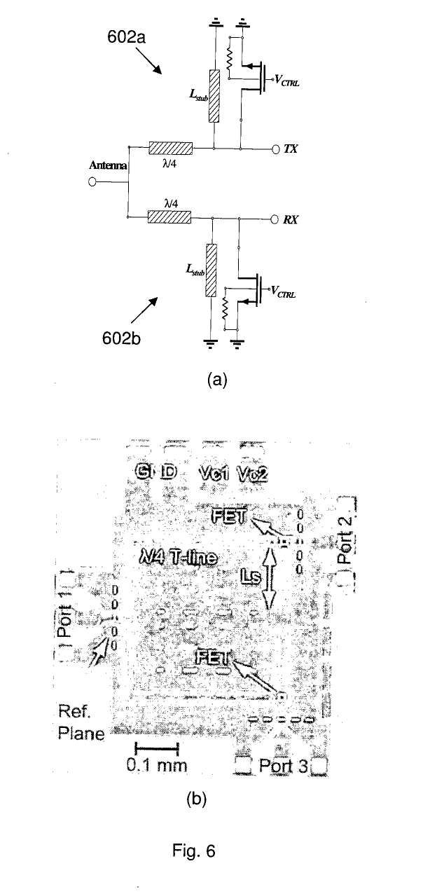

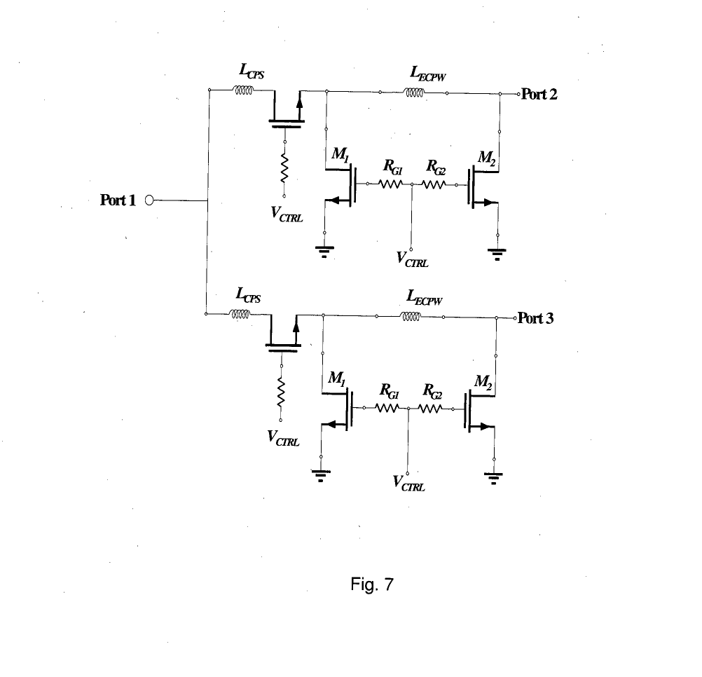

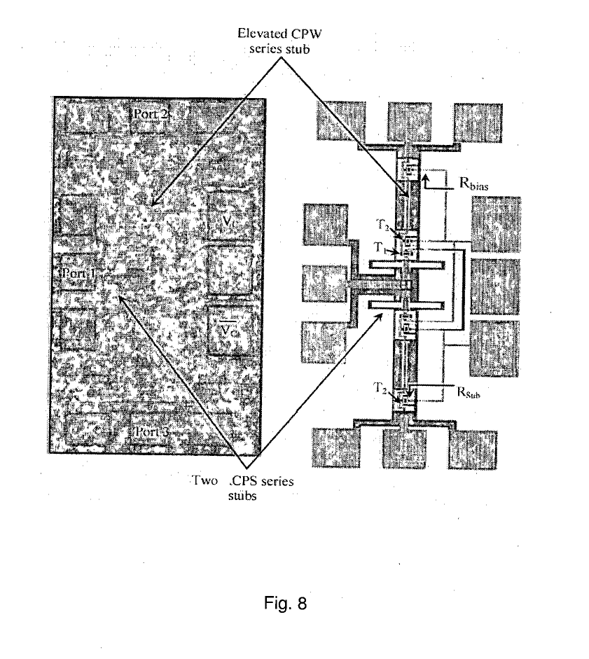

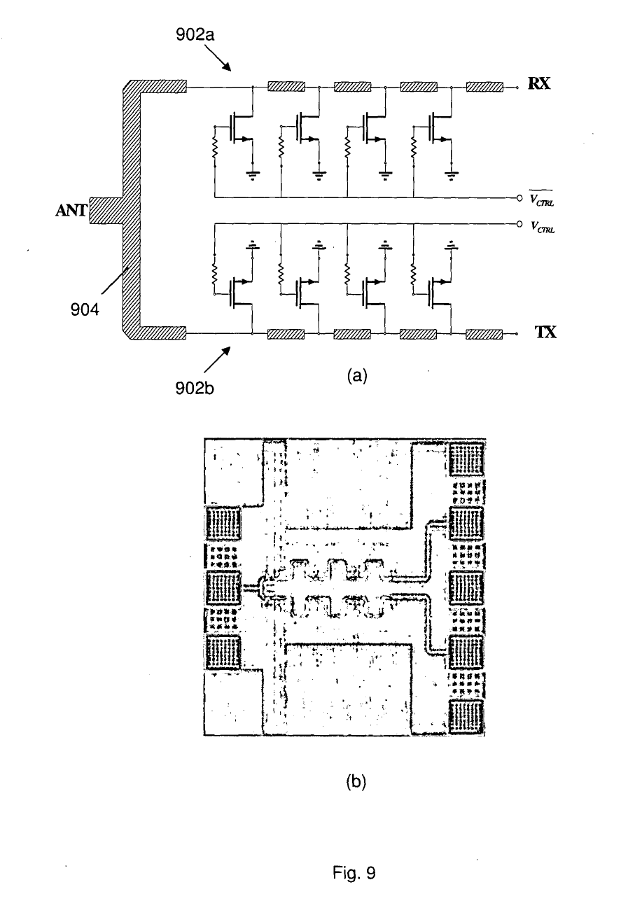

### DETAILED DESCRIPTION OF THE EMBODIMENTS

### Single-Pole-Single-Throw (SPST) Switches

### SPST Switch 1000

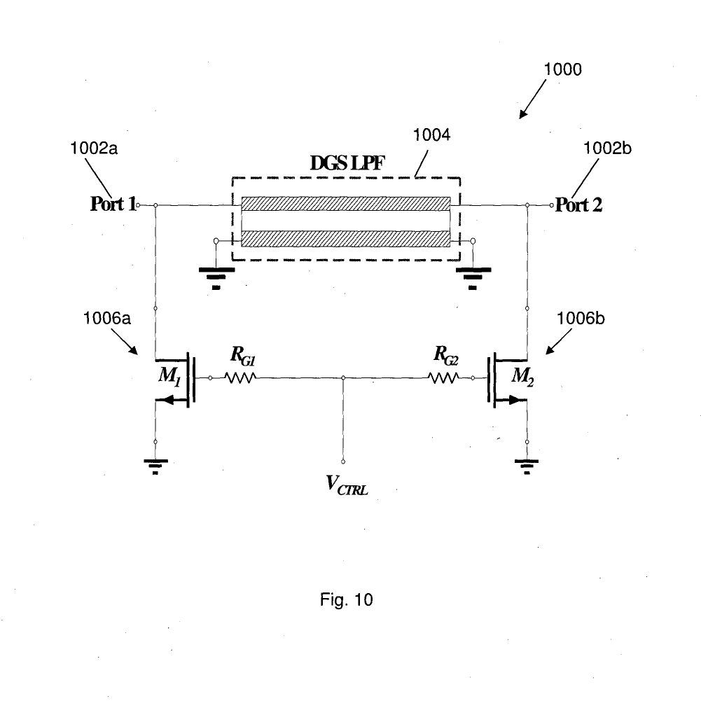

FIG. 10 shows the schematic of a SPST switch 1000 according to an embodiment of the present invention. The SPST switch 1000 serves to control signal propagation between a first contact and a second contact respectively in the form of an input port (Port 1) 1002a and an output port (Port 2) 1002b.

As shown in FIG. 10, the SPST switch 1000 comprises a compensating member in the form of a Defective Ground Structure Low Pass Filter (DGS LPF) 1004 and a control mechanism comprising two shunt transistors M₁, M₂, each in the form of a MOSFET. The SPST switch 1000 further comprises two resistors R_{G1} and R_{G2} which are respectively connected to the gate of the shunt control transistor M₁ and the gate of the shunt control transistor M₂. Each of these resistors R_{G1}, R_{G2}, together with the respective shunt control transistor M₁, M₂ it is connected to, forms a shunt transistor control element 1006a, 1006b. A control signal V_{CTRL} is supplied to the gates of the shunt control transistors M₁, M₂ through the resistors R_{G1}, R_{G2} to control the shunt control transistors M₁, M₂. The drain of the shunt control transistor M₁ is connected to one end of the DGS LPF 1004, whereas the drain of the shunt control transistor M₂ is connected to the other end of the DGS LPF 1004. The sources of both the shunt control transistors M₁ and M₂ are connected to ground. In other words, the DGS LPF and the shunt control transistors M₁, M₂ form a π-network.

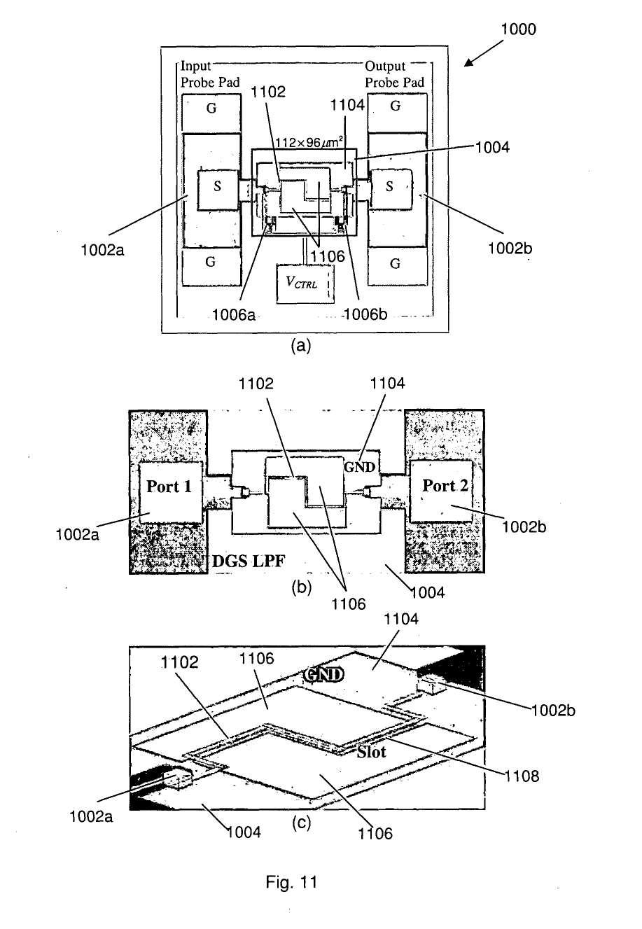

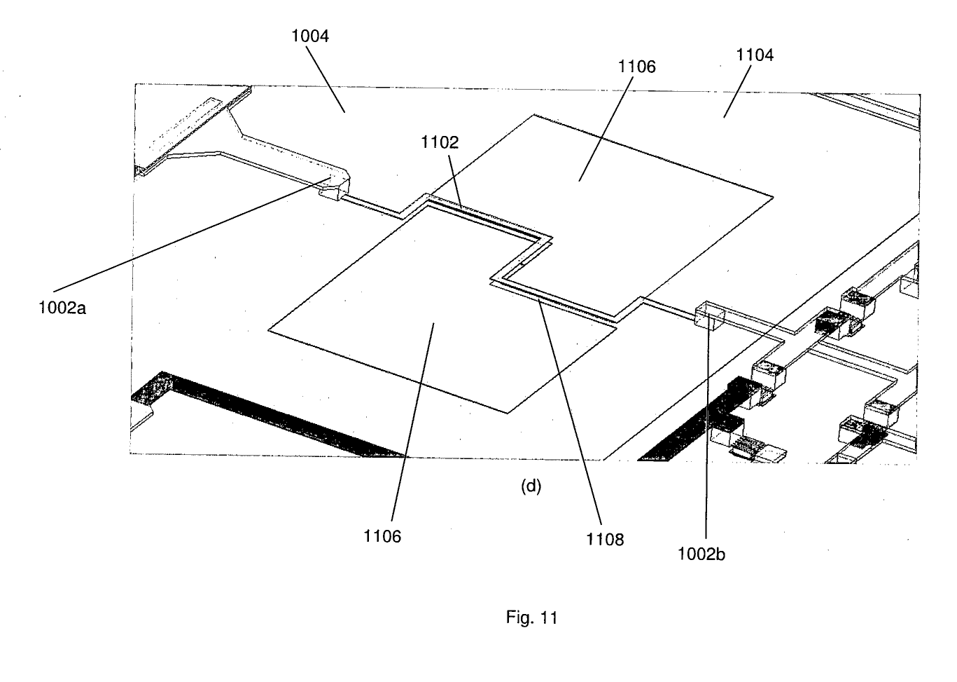

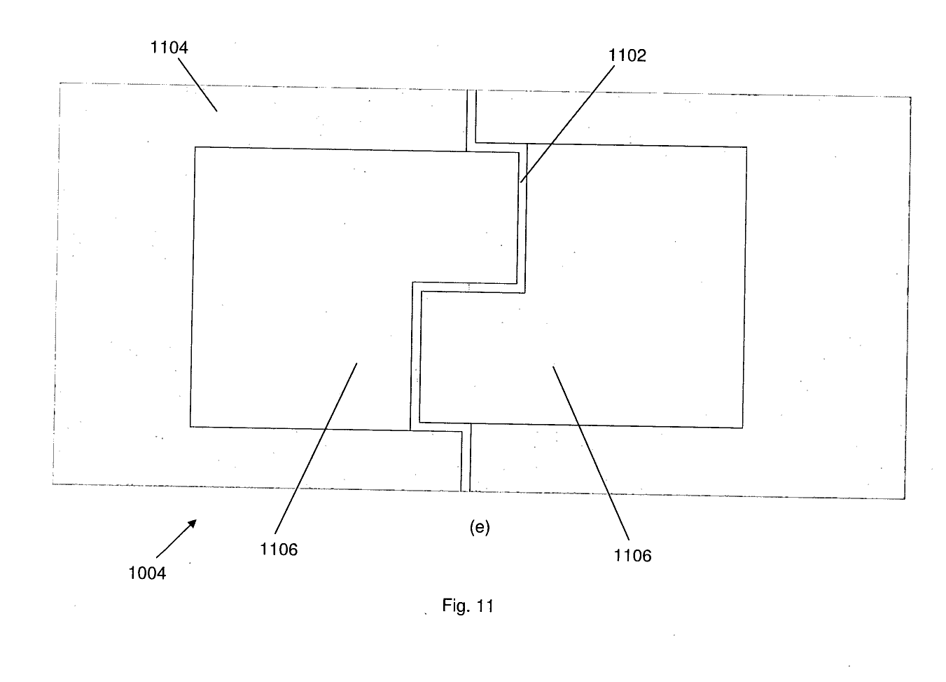

FIGS. 11(a)-(e) show details of the DGS LPF 1004 in the SPST switch 1000. In particular, FIG. 11(a) shows the layout of the SPST switch 1000 together with the input and output ports 1002a, 1002b represented by input and output probe pads, each comprising signal pads (S) and ground pads (G). FIG. 11(b) shows the layout in FIG. 11(a) without the shunt transistor control elements 1006a, 1006b and without details of the input and output ports 1002a, 1002b. FIGS. 11(c) and 11(d) show 3D views of the layout in FIG. 11(b) from different perspectives. FIG. 11(e) shows a plan view of only the DGS LPF 1004. As shown in FIGS. 11(a)-(e), the DGS LPF 1004 comprises a transmission line in the form of a microstrip line 1102 and a ground plane 1104. The ground plane 1104 in turn comprises first defects in the form of two defect patches 1106 and a second defect in the form of a gap or slot (not visible in FIGS. 11(a)-(e)). Hence, the ground plane can be referred to as a Defective Ground Structure (DGS). The defect patches 1106 are L-shaped and are spaced apart from each other via a space 1108. The gap is elongate in shape and connects the defect patches 1106 across the space 1108, thus serving as a channel between the defect patches 1106. The microstrip line 1102 and space 1108 are both made up of straight, elongate portions. A part of the microstrip line 1102 is s-shaped (that is, this part has three parallel elongate portions, spaced pairwise apart by two further elongate portions which are parallel to each other and transverse to the three parallel elongate portions) and the space 1108 has two parallel elongate portions spaced apart by a further elongate portion which is transverse to the two parallel elongate portions. The three portions of the space 1108 are parallel to corresponding portions of the microstrip line 1102 and spaced therefrom in the vertical direction. Thus, the microstrip line 1102 runs parallel and adjacent to the space 1108, spaced apart from the space 1108.

During operation, the SPST switch 1000 is connected between the input and output ports 1002a, 1002b. The shunt control transistors M₁, M₂ allow signal propagation between the input and output ports 1002a, 1002b when the switch 1000 is turned on and prevent signal propagation between the input and output ports 1002a, 1002b when the switch 1000 is turned off. In particular, when the control signal V_{CTRL} is switched to low to turn on the switch 1000, both the shunt control transistors M₁, M₂ turn off, thereby allowing signal propagation between the input and output ports 1002a, 1002b through the DGS LPF 1004 (in particular, through the microstrip line 1102). On the other hand, when the control signal V_{CTRL} is switched to high to turn off the switch 1000, both the shunt control transistors M₁, M₂ turn on. This causes the shunt control transistors M₁, M₂ to float both ends of the DGS LPF 1004 and sink signals from the input port 1002a or from the output port 1002b to ground. As a consequence, no current flows between the input and output ports 1002a, 1002b.

The microstrip line 1102 forms part of the signal path between the input and output ports 1002a, 1002b when the switch 1000 is in operation. In other words, signals allowed to propagate between the input and output ports 1002a, 1002b propagate through the microstrip line 1102. The defect patches 1106 and gap of the ground plane 1104 are configured and arranged with the microstrip line 1102 such that they affect the inductance and capacitance of the microstrip line 1102 when signals propagate through the microstrip line 1102. In particular, the defect patches 1106 and gap affect the current return path in the ground plane 1104, and this in turn affects the inductance and capacitance of the microstrip line 1102 (thus, the equivalent inductance and capacitance of the DGS LPF 1004). This helps to compensate the parasitic capacitances of the shunt control transistors M₁, M₂.

The two resistors R_{G1}, R_{G2} serve as DC isolation resistors for isolating the gates of the respective shunt control transistors M₁, M₂ they are connected to against voltage swing at the sources and drains of these transistors M₁ and M₂ [2], [9]. The value of these resistors R_{G1} and R_{G2} cannot be too large. Otherwise, the switching speed of the shunt control transistors M₁, M₂ may be affected [3].

### Example Implementation of the SPST Switch 1000

The following describes an example implementation of the SPST switch 1000 for operation in the frequency range from millimeter-wave frequencies up to 75 GHz at least. The 65 nm STMicroelectronics CMOS technology is used for this example implementation.

In this example, the SPST switch 1000 is implemented by first setting some characteristics of the SPST switch 1000, and then determining further characteristics of the SPST switch 1000 based on these characteristics and via simulation. The simulation is performed using equivalent models and equations describing the operation of the SPST switch 1000.

### Setting Characteristics of the SPST Switch 1000

The following characteristics of the SPST switch 1000 are set initially.

The microstrip line 1102 of the DGS LPF 1004 is to be formed using either Metal 4 or Metal 5, both of which has a thickness of 0.22 μm, whereas the ground plane 1104 of the DGS LPF 1004 is to be formed using Metal 1 which has a thickness of 0.18 μm. The width of the microstrip line 1102 is set as 2 μm throughout its length. A dielectric layer is to be located between the microstrip line 1102 and the ground plane 1104. This dielectric layer is to comprise four vias (via1-via4) interspersed with three metal layers (m2-m4). Hence, the thickness of this dielectric layer is equal to via1t+m2t+via2t+m3t+via3t+m4t+via4t=1.3 μm since via1t, via2t, via3t, via4t, representing the thickness of via1, via2, via3, via4 respectively are equal to 0.16 μm and m2, m3, m4 representing the thickness of m2, m3, m4 respectively are equal to 0.22 μm. The DGS LPF is to be encapsulated by another dielectric having a thickness of 4.42 μm. This dielectric is to be formed using a plurality of multilayer dielectrics, each having a thickness of 0.38 μm. Each multilayer dielectric is to comprise a series of layers including thin barrier layers (each having a thickness of 0.03 μm and a dielectric constant of ∈ₖ=5.0), low-k dielectric layers (each having a thickness of 0.1 μm and a dielectric constant of ∈ₖ=2.9) and oxide layers (each having a thickness of 0.03 μm and a dielectric constant of ∈ₖ=5.0). The width of the space 1108 is set as 2 μm throughout its length. This is also the width (w) of the gap connecting the defect patches 1106 across the space 1108. More specifically, the size of the gap (w×g) is set as 2 μm×0.2 μm. The DGS LPF 1004 is to be formed above a silicon substrate. In particular, the ground plane 1104 is to be connected to the silicon substrate via a Tungsten metal contact. This Tungsten metal contact is to serve as the connection between the ground plane 1104 and the implantation (source or drain) of the transistors M₁, M₂. The dielectric to be encapsulating the DGS LPF as mentioned above is to extend from above the silicon substrate to a top copper layer that can be used for CMOS applications. This top copper layer is to be implemented using Metal 7. Furthermore, aluminium metalization having different sets of dielectric is to be implemented above this top copper layer.

Each of the shunt control transistors M₁, M₂ in the shunt control transistor elements 1006a, 1006b is to be implemented using a 16 multi-finger gate transistor with an aspect ratio of W/L=80 μm/0.06 μm. Furthermore, the resistance of the resistors R_{G1}, R_{G2} in the shunt control transistor elements 1006a, 1006b are set as 10 kΩ.

The overall metallization structures of the SPST switch 1000 are to be encapsulated inside a 7.64 μm thick structure comprising a plurality of dielectric layers (with an equivalent permittivity i.e. dielectric constant of ∈_{k-eq}=4.187). This thick structure serves to mechanically support the metallization structures of the SPST switch 1000.

### Equivalent Model and Equations Describing the Operation of the SPST Switch 1000

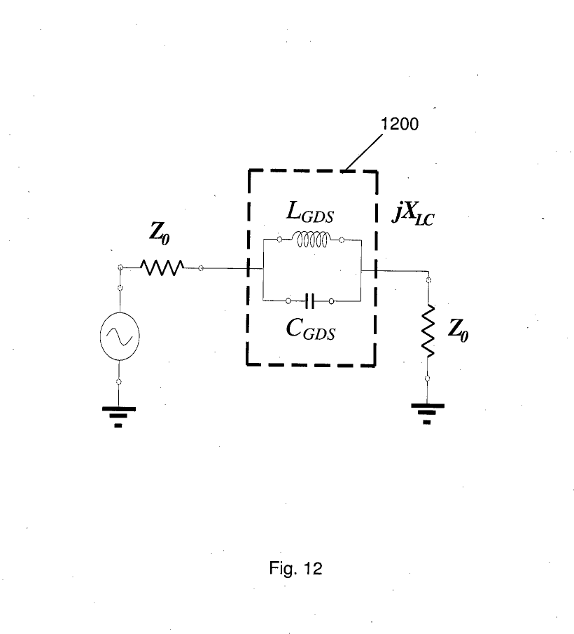

FIG. 12 shows an equivalent model of a prior art DGS LPF 1200 in reference [19] for a 2.4 GHz application. As shown in FIG. 12, the model of the DGS LPF 1200 comprises a LC network having an equivalent inductance L_{GDS} in parallel with an equivalent capacitance C_{GDS}. The two impedances Z₀ that are included in series with the model of the DGS LPF 1200 represent the input characteristic impedance and the load characteristic impedance.

The LC network in FIG. 12 is used as the equivalent model of the DGS LPF 1004 in the switch 1000 for this example implementation. The same modeling strategy as that in reference [19] is also used, except that some adjustments are made to reflect the operation of the switch 1000 in the frequency range from millimeter-wave frequencies up to 75 GHz at least and the implementation of the switch via the CMOS process. It is challenging to model the operation of the DGS LPF 1004 in this example implementation as the DGS LPF 1004 is to be formed above a silicon substrate and the switch 1000 is to be contained within a thick structure comprising a plurality of dielectric layers as mentioned above. Furthermore, the DGS LPF 1004 is to be configured to operate in the millimeter-wave frequency range.

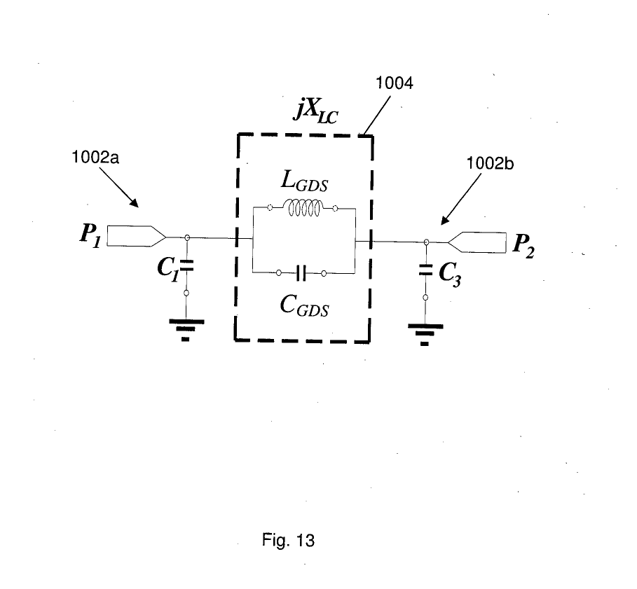

During operation, the DGS LPF 1004 is connected to internal port structures (i.e. the input and output ports 1002a, 1002b) that are capacitive in the frequency range from DC to 230 GHz. FIG. 13 shows a model reflecting this. In particular, the model in FIG. 13 comprises the LC network used as the equivalent model of the DGS LPF 1004, together with parasitic loading capacitances (C₁ and C₃) at both ends of the LC network. These parasitic loading capacitances represent the capacitive loading of the input and output ports 1002a, 1002b on the DGS LPF 1004.

Based on reference [19], the equivalent reactance (X_{LC}) of the LC network used as the equivalent model of the DGS LPF 1004 may be expressed in the form of Equation (1). In Equation (1), ω represents the angular frequency of the LC network and ω₀ represents the resonance angular frequency of the LC network.

$${X}_{LC} = \frac{ω}{{C}_{GDS}} \frac{1}{{ω}_{0}^{2} - {ω}^{2}} \qquad ( 1 )$$

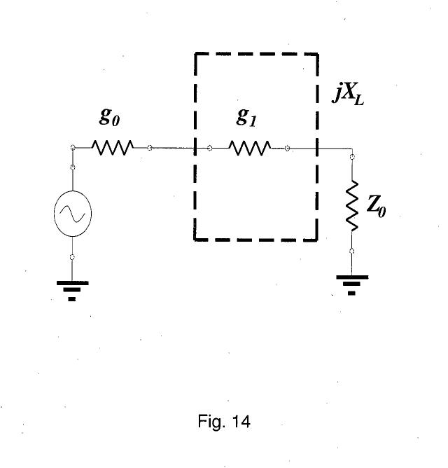

The equivalent reactance (X_{L}) based on a one-pole Butterworth LPF as shown in FIG. 14 may be expressed in the form of Equation (2) where Ω represents the normalized angular frequency of the Butterworth LPF, Zₒ represents the characteristic impedance of the Butterworth LPF and g₁ represents the normalized one-pole parameter of the Butterworth LPF.

X_{L}=∩·Zₒg₁ (2)

In this example implementation, the value of X_{LC} in Equation (1) is set to be equal to the value of X_{L} in Equation (2) at the 3-dB cut-off frequency. In this case, the equivalent capacitance C_{GDS} and the equivalent inductance L_{GDS} of the DGS LPF 1004 may be expressed in the form of Equations (3) and (4) respectively, where ω=2πf_{c}, f_{c} representing the 3-dB cut-off frequency of the DGS LPF 1004 which is also the series resonance frequency of the DGS LPF 1004 and

$${f}_{0} = \frac{{ω}_{0}}{2 π}$$

represents the parallel resonance frequency of the DGS LPF 1004.

$$\begin{matrix}{C}_{GDS} = \frac{{ω}_{c}}{{Z}_{o} {g}_{1}} \frac{1}{{ω}_{0}^{2} - {ω}_{c}^{2}} & ( 3 ) \\ {L}_{GDS} = \frac{1}{4 {π}^{2} {f}_{0}^{2} {C}_{GDS}} . & ( 4 )\end{matrix}$$

Using Equations (3) and (4), HFSS EM simulations can be performed to obtain both the series and parallel resonance frequencies (f_{c} and fₒ) of the DGS LPF 1004 in the switch 1000.

The parasitic loading capacitances (C₁ and C₃) can be obtained from the Y-parameter (Y₁₁) EM simulation of each port 1002a, 1002b without the LC network in FIG. 13. In this example implementation, the input and output ports 1002a, 1002b are set to be the same. Hence, the parasitic loading capacitances (C₁ and C₃) may be expressed in the form of Equation (5), where ω represents the angular frequency of the LC network.

$${C}_{1} = {C}_{3} = - \frac{Im ( {Y}_{11} )}{ω} \qquad ( 5 )$$

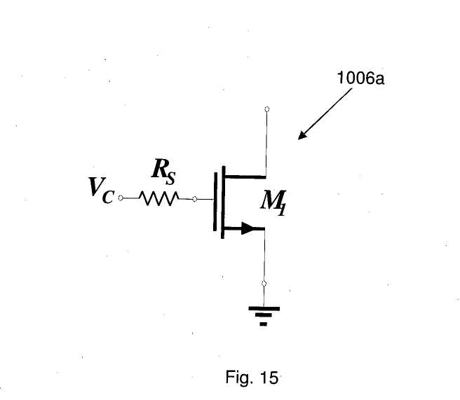

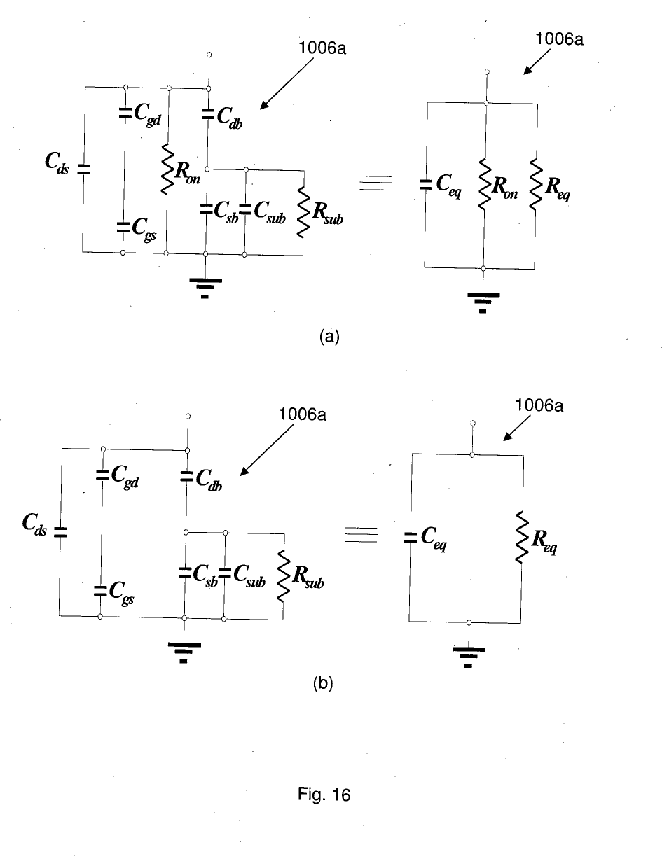

FIG. 15 shows the schematic of the shunt transistor control element 1006a in the switch 1000 with V_{C}=V_{CTRL}. FIGS. 16(a) and (b) respectively show the on-state and off-state equivalent circuits of the shunt control transistor M₁ in the shunt transistor control element 1006a. The on-state and off-state equivalent circuits of the other shunt control transistor. M₂ are similar to those shown in FIGS. 16(a) and (b).

As shown on the left hand side of FIG. 16(a), the on-state equivalent circuit of the shunt control transistor M₁ comprises a plurality of capacitances C_{ds}, C_{gd}, C_{gs}, C_{db}, C_{sb}, C_{sub} and resistances Rₒₙ, R_{sub}. The capacitances C_{ds}, C_{gd}, C_{gs}, C_{db}, C_{sb}, C_{sub} represent the parasitic capacitances of the transistor M₁. In particular, C_{ds}, C_{gd}, C_{gs} respectively represents the drain-to-source coupling capacitance, gate-to-drain coupling capacitance and gate-to-source coupling capacitance, C_{db}, C_{sb} respectively represents the drain-to-bulk junction capacitance and source-to-bulk junction capacitance, and C_{sub} represents the substrate capacitance. Note that the gate-to-bulk junction capacitance C_{gb} of the transistor M₁ is omitted from the on-state equivalent circuit in FIG. 16(a) because the gate of the transistor M₁ is floated under a linear condition due to the presence of a large gate resistance. Furthermore, Rₒₙ represents the on-resistance and R_{sub} represents the substrate resistance of the transistor M₁. The equivalent circuit on the left hand side of FIG. 16(a) may be reduced to a simplified circuit as shown on the right hand side of FIG. 16(a). This simplified on-state equivalent circuit comprises two resistances (the on-resistance Rₒₙ and an equivalent substrate parasitic resistance R_{eq}), and an equivalent parasitic capacitance C_{eq} in parallel.

As shown on the left hand side of FIG. 16(b), the off-state equivalent circuit of the shunt control transistor M₁ is similar to its on-state equivalent circuit except that it does not comprise the on-resistance Rₒₙ. Similarly, as shown on the right hand side of FIG. 16(b), this off-state equivalent circuit can be reduced to a simplified off-state equivalent circuit comprising the equivalent substrate parasitic resistance R_{eq} and the equivalent parasitic capacitance C_{eq} in parallel.

The on-resistance Rₒₙ in the on-state equivalent circuit in FIG. 16(a) may be expressed in the form of Equation (6) where V_{gs} represents the voltage between the gate and source of the transistor M₁, Vₜₕ represents the threshold voltage of the transistor

$${M}_{1} , \frac{W}{L}$$

represents the aspect ratio of the transistor M₁, Cₒₓ represents the gate oxide capacitance of the transistor M₁ and μₙ represents the electron mobility in the transistor M₁.

$${R}_{on} = \frac{1}{{μ}_{n} {C}_{ox} \frac{W}{L} ( {V}_{gs} - {V}_{th} )} \qquad ( 6 )$$

The relationship between the equivalent substrate parasitic resistance R_{eq} in the simplified equivalent circuits on the right hand sides of FIGS. 16(a) and (b), and the capacitances C_{ds}, C_{gd}, C_{gs}, C_{db}, C_{sb}, C_{sub} and resistance R_{sub} in the equivalent circuits on the left hand sides of FIGS. 16(a) and (b) can be expressed in the form of Equations (7) and (8). In Equations (7) and (8), Cⱼ represents either the source-to-bulk junction capacitance C_{sb}, or the drain-to-bulk junction capacitance C_{db}. More specifically, Cⱼ=C_{sb}=C_{db}.

$$\begin{matrix}{R}_{eq} = \frac{4 {R}_{sub}^{2} {ω}^{2} {C}_{j}^{2} + 4 {R}_{sub}^{2} {ω}^{2} {C}_{j} {C}_{sub} + 4 {R}_{sub}^{2} {ω}^{2} {C}_{sub}^{2} + 1}{{R}_{sub} {ω}^{2} {C}_{j}^{2}} \\ = 4 {R}_{sub} ( 1 + \frac{{C}_{sub}}{{C}_{j}} + \frac{{C}_{sub}^{2}}{{C}_{j}^{2}} + \frac{1}{4 {R}_{sub}^{2} {ω}^{2} {C}_{j}^{2}} ) ( 8 )\end{matrix} \qquad ( 7 )$$

The relationship between the equivalent parasitic capacitance C_{eq} in the simplified equivalent circuits on the right hand sides of FIGS. 16(a) and (b), and the capacitances C_{ds}, C_{gd}, C_{gs}, C_{db}, C_{sb}, C_{sub} and resistance R_{sub} in the equivalent circuits on the left hand sides of FIGS. 16(a) and (b) can be expressed according to Equation (9). Similarly, in Equation (9), Cⱼ=C_{sb}=C_{db}.

$${C}_{eq} = \frac{a {C}_{j}}{b} + \frac{{C}_{gs} {C}_{gd}}{{C}_{gs} + {C}_{gd}} + {C}_{ds} \qquad ( 9 )$$

where a=R_{sub}²ω²(2Cⱼ²+3CⱼC_{sub}+C_{sub}²)+1, b=R_{sub}²ω²(4Cⱼ²+4CⱼC_{sub}+C_{sub}²)+1

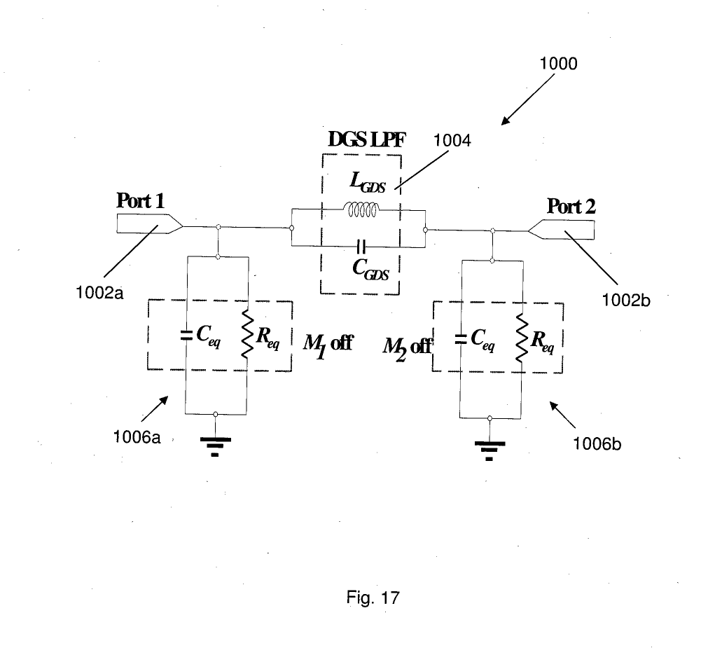

FIG. 17 shows the on-state equivalent circuit of the SPST switch 1000. This on-state equivalent circuit is formed by combining the equivalent model of the DGS LPF 1004 as shown in FIG. 13 (i.e. the LC network), and the simplified off-state equivalent circuits of the shunt control transistors M₁, M₂ as shown in FIG. 16(b) (since the switch 1000 is on when the shunt control transistors M₁, M₂ are off). Note that the on-state equivalent circuit of the SPST switch 1000 in FIG. 17 includes only the internal components of the switch 1000 and not external components such as the ports 1002a, 1002b. Thus, the parasitic loading capacitances C₁, C₃ representing the capacitive loading of the ports 1002a, 1002b in FIG. 13 are not included in this on-state equivalent circuit. The resistors R_{G1}, R_{G2} are also not included in this on-state equivalent circuit because the gates of the transistors M₁, M₂ are floated and hence, the resistors R_{G1}, R_{G2} act like open circuits.

The parallel combination of L_{GDS} and C_{GDS} in the DGS LPF equivalent model can be represented by a first equivalent impedance Z_{X} as shown in Equation (10).

$${Z}_{x} = j ω {L}_{GDS} // \frac{1}{j ω {C}_{GDS}} = \frac{j ω {L}_{GDS}}{1 - {ω}^{2} {L}_{GDS} {C}_{GDS}} \qquad ( 10 )$$

Similarly, the parallel combination of R_{eq} and C_{eq} in the simplified off-state equivalent circuit of each shunt control transistor M₁, M₂ can be represented by a second equivalent impedance Z_{Y} as shown in Equation (11).

$${Z}_{Y} = \frac{1}{j ω {C}_{eq}} // {R}_{eq} = \frac{{R}_{eq} ( 1 - j ω {R}_{eq} {C}_{eq} )}{1 + {ω}^{2} {R}_{eq}^{2} {C}_{eq}^{2}} \qquad ( 11 )$$

Since Z_{X} and Z_{Y} form a π-network in the on-state equivalent circuit of the SPST switch 1000, the insertion loss (IL) of the switch 1000 can be expressed according to Equation (12) where Z₀ represents the characteristic impedance of the π-network.

$$IL = - 20 log \vert \frac{2 {Z}_{Y}^{2} {Z}_{0}}{2 {Z}_{Y}^{2} {Z}_{0} + {Z}_{X} {Z}_{Y}^{2} + 2 {Z}_{0}^{2} {Z}_{Y} + 2 {Z}_{X} {Z}_{Y} {Z}_{0} + 2 {Z}_{0}^{2} {Z}_{X}} \vert \qquad ( 12 )$$

As mentioned above, each shunt control transistor M₁, M₂ is to be implemented using a 16 multi-finger gate transistor with an aspect ratio of W/L=80/0.06. For such a transistor, the equivalent substrate parasitic resistance is much greater than the reactance of the equivalent parasitic capacitance i.e. R_{eq}>>1/(jωC_{eq}). Therefore, Z_{Y} may be approximated as Z_{Y}≅1/(jωC_{eq}).

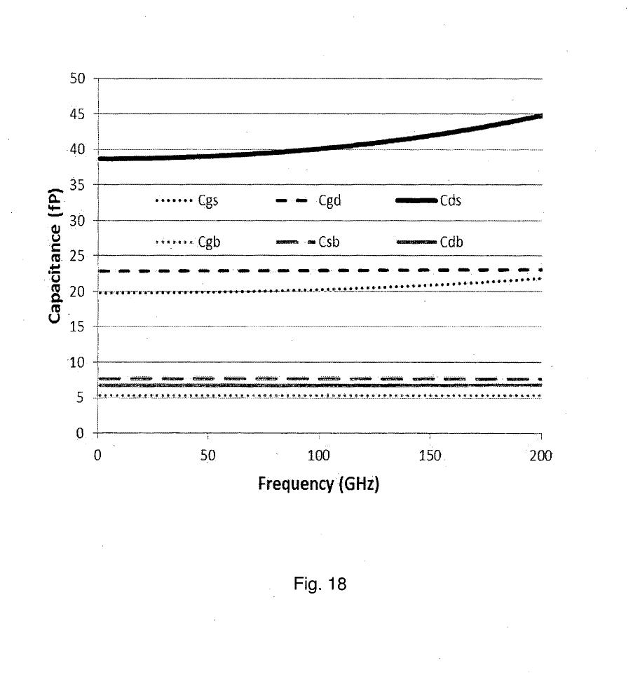

FIG. 18 shows the parasitic capacitances of a 16 multi-finger gate transistor with an aspect ratio of W/L=80/0.06 across different frequencies. As shown in FIG. 18, the junction capacitances C_{gb}, C_{sb}, and C_{db} of the transistor are much smaller as compared to the coupling capacitances C_{gs}, C_{gd}, and Cₐₛ of the transistor. Therefore, the contribution of Cⱼ in Equation (13) may be assumed to be negligible and the equivalent parasitic capacitance C_{eq} of each shunt control transistor M₁, M₂ may be expressed in the form of Equation (13).

$${C}_{eq} ≅ \frac{{C}_{gs} {C}_{gd}}{{C}_{gs} + {C}_{gd}} + {C}_{ds} \qquad ( 13 )$$

Since the multi-finger metalizations start and end with the drain fingers, the gate-to-drain coupling capacitance C_{gd} of the transistor tends to be at most only slightly higher than its gate-to-source coupling capacitance C_{gs}. Furthermore, there is an equal number of fingers in the source and drain multi-finger metalizations of the 16 multi-finger gate transistor to be used to implement the shunt control transistors M₁, M₂ in this example. Therefore, the gate-to-drain coupling capacitance C_{gd} of each shunt control transistor M₁, M₂ can be assumed to be equal to the gate-to-source coupling capacitance C_{gs} of the transistor M_{I}, M₂ i.e. C_{gs}=C_{gd} This assumption allows Equation (13) to be further simplified as follows.

$${C}_{eq} ≅ \frac{1}{2} {C}_{gd} + {C}_{ds} \qquad ( 14 )$$

FIG. 18 also shows that the overall parasitic capacitance of the 16 multi-finger gate transistor is mainly dominated by the drain-to-source coupling capacitance C_{ds}, especially from the millimeter-wave frequency range onwards (more specifically, from 50 GHz onwards). Hence, Equation (14) may be further simplified as follows.

C_{eq}≅C_{ds}|_{f>50 GHz} (15)

As mentioned above, Z_{Y} may be approximated as Z_{Y}≅1/(jωC_{eq}) in this example implementation. In view of this and Equation (15), Z_{Y} may be approximated as a function of the drain-to-source coupling capacitance C_{ds} at frequencies beyond 50 GHz. This is shown in Equation (20).

$${Z}_{Y} {\vert}_{f > 50 G H z} ≅ \frac{1}{jω {C}_{ds} {\vert}_{f > 50 G H z}} \qquad ( 16 )$$

Furthermore, the width of the space 1108 in the DGS LPF 1004 does not change with frequency and thus, the equivalent capacitance C_{GDS} in the DGS LPF equivalent model is expected to be almost constant throughout all frequencies. Hence, working from Equation (10), the first equivalent impedance Z_{X} can be expressed as a function of only the equivalent inductance L_{GDS} in the DGS LPF equivalent model. This is shown in Equation (17).

Z_{X}=f(L_{GDS}) (17)

Similarly, working from Equation (4), the resonance frequency f₀ of the DGS LPF 1004 can also be expressed as a function of only the equivalent inductance L_{GDS} in the DGS LPF equivalent model. This is shown in Equation (18).

f₀(L_{GDS}) (18)

From Equations (16), (17) and (18), it can be seen that the insertion loss of the SPST switch 1000 is dependent on two factors, namely the drain-to-source coupling capacitances C_{ds} of the shunt control transistors M₁, M₂, and the equivalent inductance L_{GDS} in the DGS LPF equivalent model. The equivalent inductance L_{GDS} in the DGS LPF equivalent model helps to compensate the capacitive effects contributed by the drain-to-source parasitic capacitances C_{ds} of the shunt control transistors M₁, M₂. This in turn helps to improve the matching performance for the SPST switch 1000, and hence the insertion loss performance and the return loss performance of the SPST switch 1000.

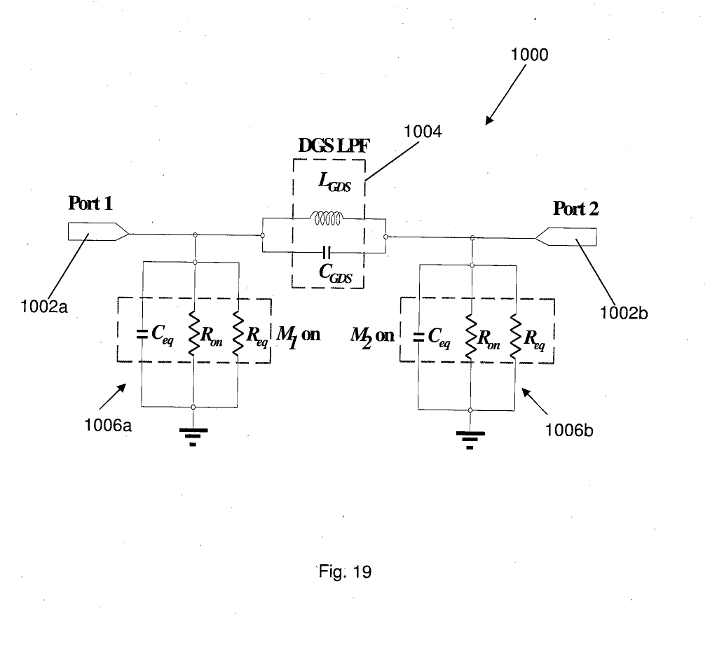

FIG. 19 shows the off-state equivalent circuit of the SPST switch 1000. This off-state equivalent circuit is formed by combining the equivalent model of the DGS LPF 1004 in FIG. 13 (i.e. the LC network), and the simplified on-state equivalent circuits of the shunt control transistors M₁, M₂ as shown in FIG. 16(a) (since the switch 1000 is off when the shunt control transistors M₁, M₂ are on). Similarly, the off-state equivalent circuit of the SPST switch 1000 includes only the internal components of the switch 1000 and not external components such as the ports 1002a, 1002b. Thus, the parasitic loading capacitances C₁, C₃ representing the capacitive loading of the ports 1002a, 1002b in FIG. 13 are not included in this off-state equivalent circuit. The resistors R_{G1}, R_{G2} are also not included in this off-state equivalent circuit because as mentioned above, the gates of the transistors M₁, M₂ are floated and hence, the resistors R_{G1}, R_{G2} act like open circuits.

The parallel combination of R_{eq}, Rₒₙ and C_{eq} in the simplified on-state equivalent circuit of each shunt control transistor M₁, M₂ can be represented by a third equivalent impedance Z_{W} as shown in Equation (19).

$${Z}_{W} = \frac{1}{{jωC}_{eq}} // {R}_{on} // {R}_{eq} \qquad ( 19 )$$

In this example implementation, the on-resistance Rₒₙ of each shunt control transistor M₁, M₂ can be assumed to be much smaller than its equivalent substrate parasitic resistance R_{eq} (i.e. Rₒₙ<<R_{eq}). Thus, the contribution of R_{eq} to the third equivalent impedance Z_{W} can be assumed to be negligible at low frequencies. This allows the simplification of Equation (19) to Equation (20).

$${Z}_{W} {\vert}_{Low frequencies} ≅ \frac{1}{{jωC}_{eq} {\vert}_{Low frequencies}} // {R}_{on} {\vert}_{Low frequencies} \qquad ( 20 )$$

Furthermore, for each shunt control transistor M₁, M₂, when the transistor is turned on, the drain-to-source coupling capacitance C_{ds} dominates the equivalent parasitic capacitance C_{eq} of the transistor. Therefore, the third equivalent impedance Z_{W} in Equation (20) may be expressed in the form of Equation (21).

$${Z}_{W} {\vert}_{Low frequencies} ≅ \frac{1}{{jωC}_{ds} {\vert}_{Low frequencies}} // {R}_{on} {\vert}_{Low frequencies} \qquad ( 21 )$$

In addition, the on-resistance Rₒₙ of each shunt control transistor M₁, M₂ can be assumed to be much smaller than the drain-to-source coupling capacitance C_{ds} of the transistor M₁, M₂. Therefore, Equation (21) may be further simplified as follows.

Z_{W}|_{Low frequencies}≅Rₒₙ|_{Low frequencies} (22)

Since Z_{X} and Z_{W} form a π-network in the off-state equivalent circuit of the SPST switch 1000, the isolation performance (ISO) of the SPST switch 1000 can be expressed according to Equation (23) where Z₀ represents the characteristic impedance of the π-network.

$$ISO = - 20 log \vert \frac{2 {Z}_{W}^{2} {Z}_{0}}{2 {Z}_{W}^{2} {Z}_{0} + {Z}_{X} {Z}_{W}^{2} + 2 {Z}_{0}^{2} {Z}_{W} + 2 {Z}_{X} {Z}_{W} {Z}_{0} + 2 {Z}_{0}^{2} {Z}_{X}} \vert \qquad ( 23 )$$

As mentioned above, when the shunt control transistors M₁, M₂ are turned on, the input and output ports 1002a, 1002b are both shorted to ground via the shunt control transistors M₁, M₂. In other words, the DGS LPF 1004 is shorted to ground. Therefore, the first equivalent impedance Z_{X} is zero (i.e. Z_{X}=0) and Equation (23) can be simplified as follows.

$$ISO \approx - 20 log \vert \frac{{Z}_{W}}{{Z}_{W} + {Z}_{0}} \vert \qquad ( 24 )$$

Furthermore, as mentioned above (see Equations (20)-(22)), the third equivalent impedance Z_{W} representing the equivalent impedance of each shunt control transistor M₁, M₂ is approximately equal to the on-resistance Rₒₙ of the transistor M₁, M₂ at low frequencies. Therefore, Equation (24) can be simplified to the form as shown in Equation (25) below. In other words, at low frequencies, the isolation performance of the SPST switch 1000 in this example implementation is mainly determined by the on-resistances Rₒₙ of the shunt control transistors M₁, M₂.

$$ISO {\vert}_{Low frequencies} \approx \frac{{R}_{on} {\vert}_{Low frequencies}}{{R}_{on} {\vert}_{Low frequencies} + {Z}_{0}} \qquad ( 25 )$$

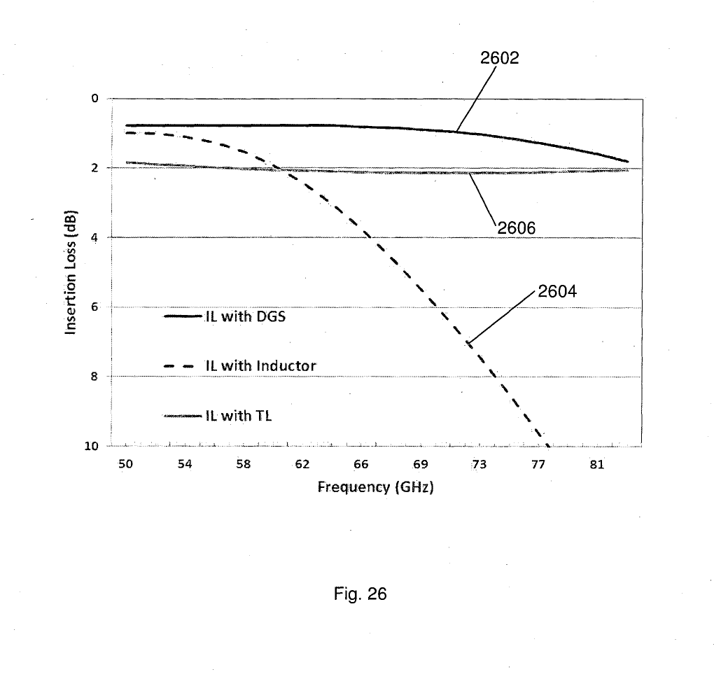

At higher frequencies, there is an increase in the channel resistivity in each shunt control transistor M₁, M₂ due to the electron scattering effect. More specifically, because of the scattering of electrons at higher frequencies, the average electron drift velocity in each transistor M₁, M₂ is reduced and thus the mobility of the electrons in the transistor M₁, M₂ is lowered. As a consequence, the channel conductivity of each shunt control transistor M₁, M₂ is degraded and in turn, the channel resistivity (represented by the on-resistance Rₒₙ) of the transistor M₁, M₂ increases. Furthermore, the drain-to-source coupling capacitances C_{ds} of the shunt control transistors M₁, M₂ also increase at higher frequencies due to an increase in the electric coupling between the source and drain metallizations in the transistors M₁, M₂. The increase in both the channel resistivity and the drain-to-source coupling capacitance C_{ds} of each shunt control transistor M₁, M₂ in turn results in an increase in the third equivalent impedance Z_{W} of the transistor M₁, M₂ (see Equation (19)). Thus, the isolation performance of the SPST switch 1000 is worse at higher frequencies than at lower frequencies. In the example implementation, the shunt control transistors M₁, M₂ have sufficiently low drain-to-source coupling capacitances (C_{ds}) such that the insertion loss and isolation performance of the SPST switch 1000 remains reasonably good even at higher frequencies (as shown in FIGS. 26-29 which will be discussed later on).

### Determining Further Characteristics of the SPST Switch 1000

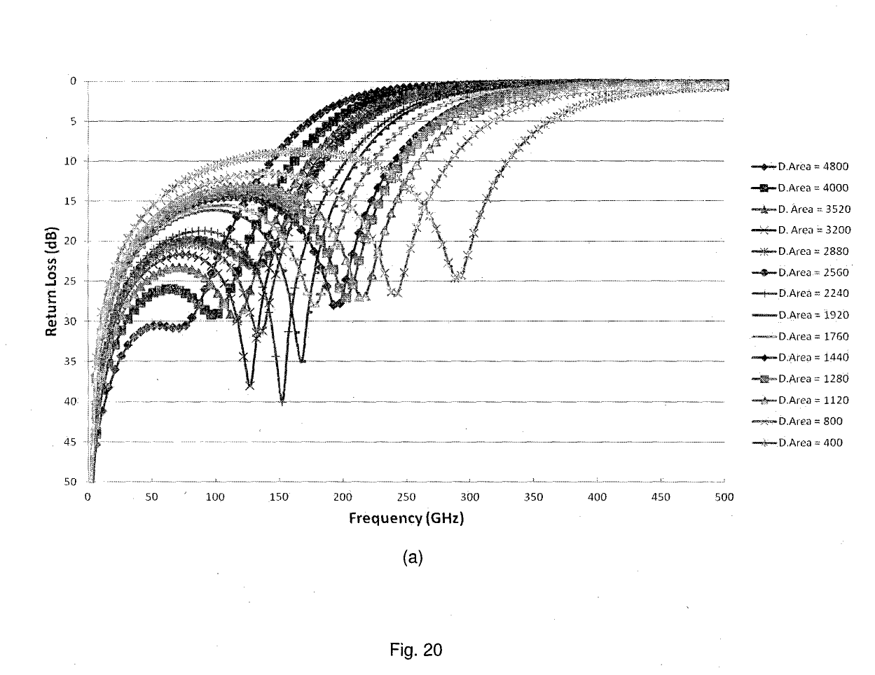

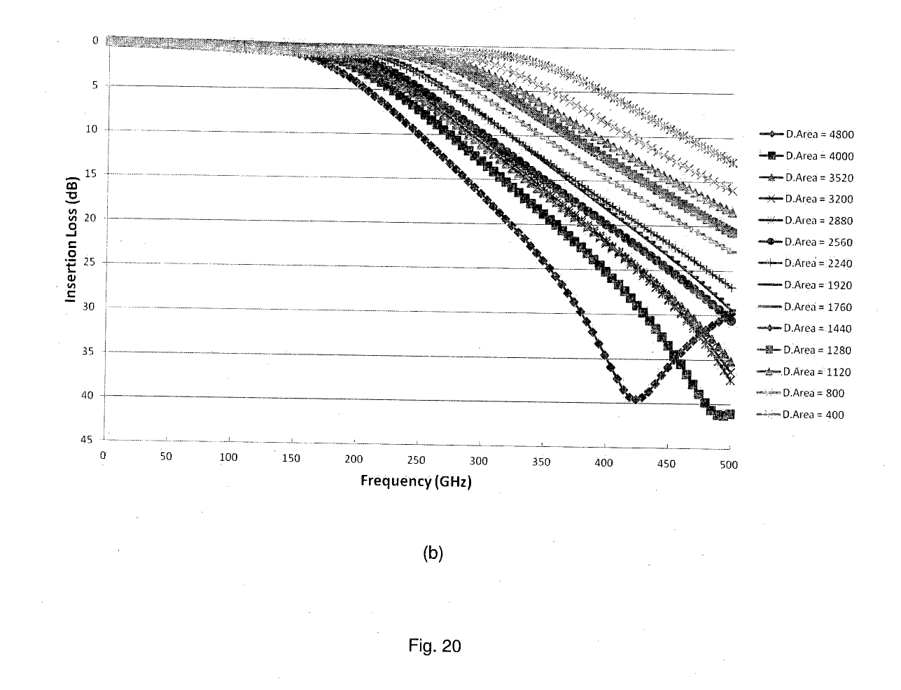

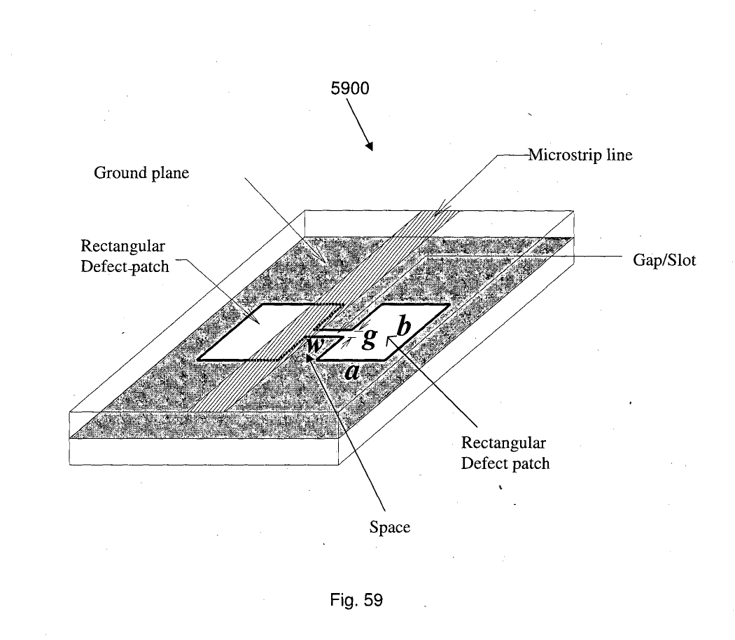

As mentioned above, the defect patches 1106 affect the inductance and/or capacitance of the microstrip line 1102 when signals propagate through the microstrip line 1102. More specifically, the defect patches 1106 disturb the ground current in the ground plane 1104 and this increases the equivalent inductance L_{GDS} and equivalent capacitance C_{GDS} in the DGS LPF equivalent model. This causes a shift in the operating frequency of the DGS LPF 1004, and hence a shift in the operating frequency of the switch 1000. The amount of this shift depends on the sizes of the defect patches 1106. This is illustrated as follows using a DGS LPF with a basic structure (this DGS LPF will be elaborated in greater detail later on with reference to FIG. 59). The structure of the DGS LPF 1004 is derived from this basic structure. In particular, this basic structure comprises two defect patches which are rectangular in shape and which each has a size of a×b. These two defect patches are also spaced apart from each other via a space and a further defect in the form of an elongate gap with size w×g runs across the space to connect the two defect patches (similar to the elongate gap in the DGS LPF 1004). FIGS. 20(a)-(b) respectively show changes in the return losses and insertion losses of this DGS LPF with the basic structure as the total size (2×[a×b]) of the defect patches in this DGS LPF changes. As shown in FIGS. 20(a)-(b), increasing the total size of the defect patches moves the 3-dB resonance frequency of the DGS LPF to a lower frequency.

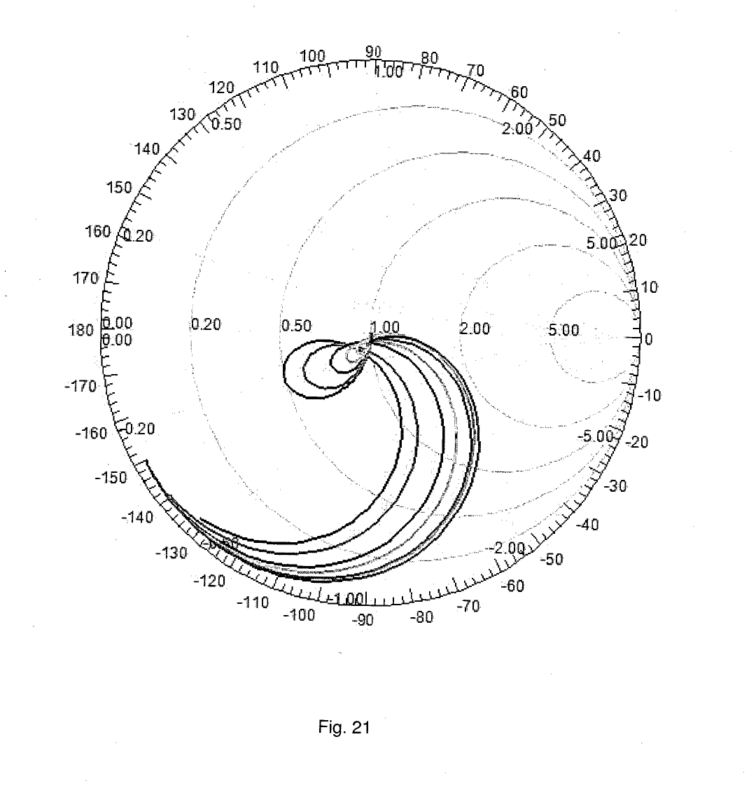

The characteristic impedance of the DGS LPF 1004 (and hence, the characteristic impedance of the switch 1000) is also affected by the sizes of the defect patches 1106. This is because the defect patches 1106 enhance the equivalent series inductance of the microstrip line 1102. Thus, increasing the sizes of the defect patches 1106 causes the characteristic impedance of the DGS LPF 1004 to be more inductive. In particular, FIG. 21 shows how the characteristic impedance of the DGS LPF with the basic structure as mentioned above changes in response to changes in the sizes of its defect patches (with the size of the space between the defect patches kept constant).

As shown in FIG. 21, the input impedance of the DGS LPF becomes more inductive as the sizes of the defect patches increase. This is useful as a large inductivity is usually needed to compensate for the parasitic capacitances of the control transistors in a switch.

Therefore, in this example implementation, further characteristics of the SPST switch 1000 are determined by first calculating a length of the microstrip line 1102 that allows the microstrip line to operate at a frequency higher than a design guideline frequency of 60 GHz, more specifically at 450 GHz (this allows the use of a shorter microstrip line 1102). With this length of microstrip line 1102 and without the defect patches 1106 and the gap, the SPST switch 1000 also operates at 450 GHz. The next step is to determine the sizes of the defect patches 1106 required to shift this higher frequency of 450 GHz to the design guideline frequency (i.e. 60 GHz). The sizes of the defect patches 1106 are then tuned so that the characteristic impedance of the switch 1000 lies at the normalized 50Ω matching point. This tuning is performed with the constraint that in the final SPST switch 1000, the operating frequency range of the switch 1000 extends from millimeter-wave frequencies up to 75 GHz at least. This is elaborated below.

The length (I) of the microstrip line 1102 is determined using Equations (26)-(28) below, where λ represents the wavelength of signal in the microstrip line 1102, νₚ represents the phase velocity along the microstrip line 1102, f represents the frequency of the microstrip line, c represents the velocity of light, ∈_{eff} represents the effective dielectric constant of the microstrip line 1102, ∈_{k-eq} represents the dielectric constant of the structure the switch 1000 is encapsulated in, h represents the substrate thickness i.e. the thickness of the dielectric encapsulating the DGS LPF 1104 and w represents the width of the microstrip line 1102.

$$\begin{matrix}I = λ = \frac{{v}_{p}}{f} & ( 26 ) \\ {v}_{p} = c / \sqrt{{ɛ}_{eff}} & ( 27 ) \\ {ɛ}_{eff} = \frac{{ɛ}_{k - eq} + 1}{2} + \frac{{ɛ}_{k - eq} - 1}{2} [ {( 1 + 12 \frac{h}{w} )}^{\frac{1}{2}} + 0.04 {( 1 - \frac{w}{h} )}^{2} ] & ( 28 )\end{matrix}$$

Since the thickness of copper is comparable to the substrate thickness h, w_{eff} can be used instead of w. w_{eff} can be calculated using the following Equation (29) where t represents the conductor thickness i.e. the thickness of the microstrip line 1102 which is equal to the thickness of Metal 4 to be used to implement the microstrip line 1102.

$${w}_{eff} = w + \frac{t}{π} ( 1 + ln \frac{2 \times }{t} ) \{ \begin{matrix}x = h for w > h / ( 2 π ) > 2 t \\ x = 2 π t for h / ( 2 π ) > w > 2 t\end{matrix} \qquad ( 29 )$$

By substituting the values t=0.22 μm, h=4.42 μm, w=2 μm and £_{k-eq}=4.187, the required length of the microstrip line 1102 is determined to be about 143 μm at 450 GHz.

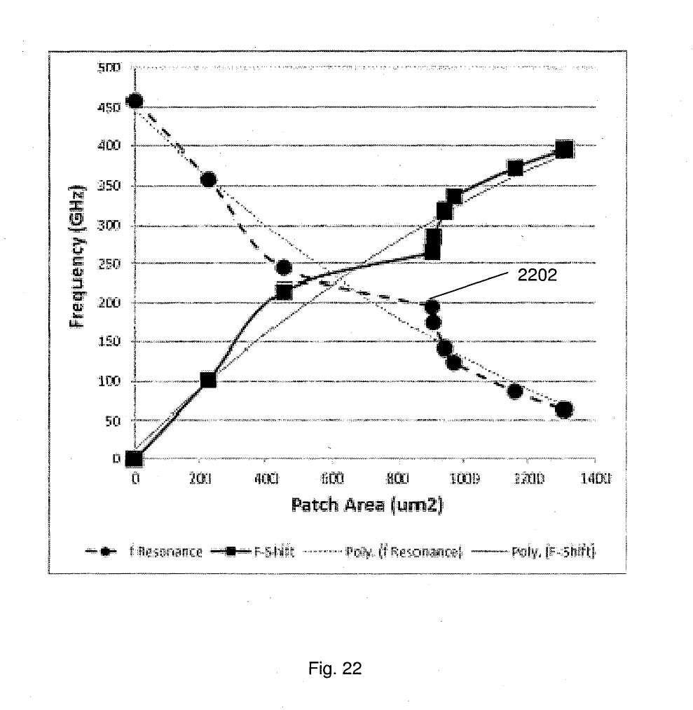

The sizes of the defect patches 1106 required to shift the operating frequency from 450 GHz to 60 GHz is determined using a graphical approach. In particular, FIG. 22 shows simulation results illustrating the expected shift in the operating frequency (or resonance frequency) of the DGS LPF 1004 when defect patches 1106 of different sizes are used. From FIG. 22 (specifically, the “f Resonance” curve 2202), it can be seen that a defect patch 1106 of size 1300 μm² is required on each side of the microstrip line 1102 to shift the operating frequency of the DGS LPF 1004 from 450 GHz to 60 GHz.

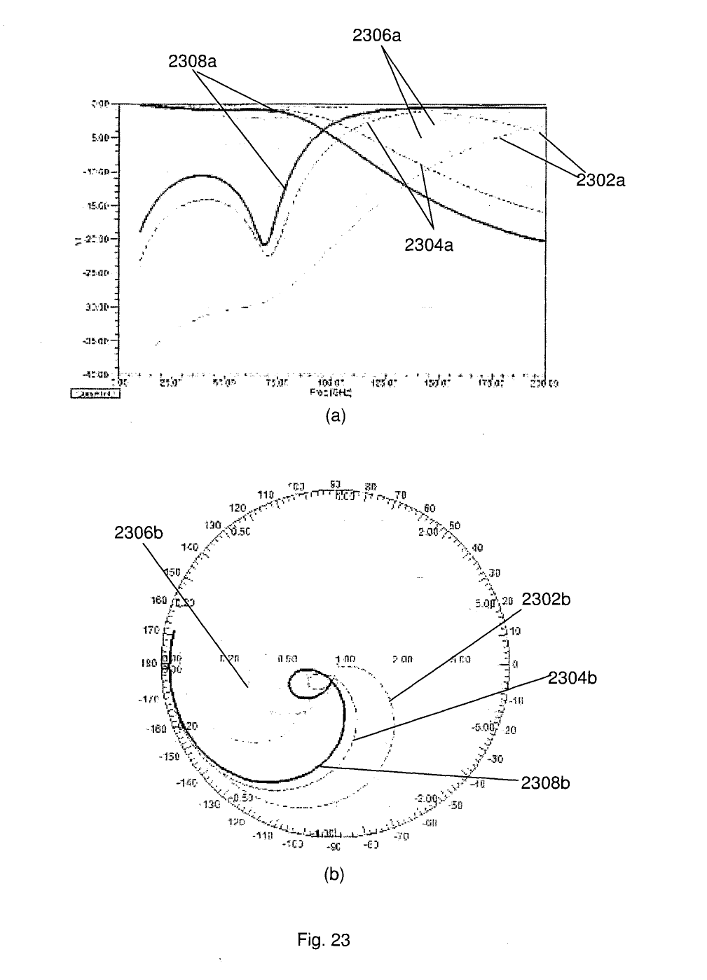

FIG. 23(a) shows simulated frequency responses of (i) the DGS LPF 1004 with the microstrip line 1102 having a length of 143 μm at 450 GHz and the defect patches 1106 each having a size of 1300 μm² (ii) the DGS LPF 1004 in (i) with additional ports metallization i.e. with the addition of conducting pads for implementing the input and output ports 1002a, 1002b of the switch 1000, and (iii) the DGS LPF 1004 in (i) with the addition of the shunt transistor control elements 1006a, 1006b. The frequency responses for (i)-(iii) as mentioned above are shown by curves 2302a, 2304a and 2308a respectively. In particular, FIG. 23(a) shows changes in the return loss and insertion loss of the DGF LPF 1004 as ports and transistors are added to it. Based on the frequency responses shown in FIG. 23(a), the equivalent inductance (L_{GDS}) and equivalent capacitance (C_{GDS}) of the DGS LPF 1004 can be calculated using Equations (3) and (4) above.

FIG. 23(b) shows, via the Smith chart, the changes in the characteristic impedance of the DGS LPF 1004 as ports and transistors are added to it. In particular, FIG. 23(b) shows the characteristic impedance of (i) the DGS LPF 1004 comprising the microstrip line 1102 with a length of 143 μm at 450 GHz and defect patches 1106 each having a size of 1300 μm² on each side of the microstrip line 1102, (ii) the DGS LPF 1004 in (i) with additional ports metallization i.e. with the addition of conducting pads for the input and output ports 1002a, 1002b of the switch 1000, and (iii) the DGS LPF 1004 in (i) with the addition of the shunt transistor control elements 1006a, 1006b. The characteristic impedances of (i)-(iii) are shown by curves 2302b, 2304b and 2308b respectively. As shown by the simulation results in FIG. 23(b) (specifically by the curve 2306b, which is the response of a switch with only the microstrip line with any defect structure), the capacitive loading of the shunt control transistors M₁, M₂ on the DGS LPF 1004 changes the characteristic impedance of the DGS LPF 1004 such that this characteristic impedance shifts away from the normalized 50Ω matching point. This leads to a degradation in the matching performance and the insertion loss of the switch 1000. This degradation can be compensated by adjusting the equivalent series inductance of the DGS LPF 1004. In particular, the degradation can be ameliorated by increasing the sizes of the defect patches 1106 as this increases the equivalent series inductance of the microstrip line 1102 as mentioned above. Therefore, in this example implementation, the sizes of the defect patches 1106 are tuned via simulation until the characteristic impedance of the switch 1000 lies at the normalized 5051 matching point. The frequency response and characteristic impedance of the final SPST switch 1000 are shown as the thick black curves 2308a, 2308b in FIGS. 23(a) and 23(b) respectively.

### Variations to the Example Implementation of the SPST Switch 1000

Variations to the above example implementation of the switch 1000 can be made.

For example, the sizes of the defect patches 1106 may be tuned until the characteristic impedance of the switch 1000 lies at a matching point other than the normalized 50Ω matching point. The matching point can depend on the impedances of other components in the circuit the switch 1000 is to be used in. In particular, it is preferable for the impedance of the switch 1000 to match the impedances of the other components in this circuit.

Furthermore, shunt control transistors M₁, M₂ different from those used in the above example implementation may be used. When determining the type of shunt control transistors M₁, M₂ to be used, the following can be taken into consideration.

Firstly, it can be seen from Equation (25) that at low frequencies, the isolation performance of the SPST switch 1000 is mainly dependent on the on-resistances of the shunt control transistors M_{I}, M₂. Therefore, by using shunt control transistors M₁, M₂ having on-resistances of approximately 4-6Ω, the isolation performance of the SPST switch 1000 can be set to approximately 19 to 23 dB at low frequencies.

Secondly, using shunt control transistors M₁, M₂ with higher substrate resistances R_{sub} has the advantage of reducing insertion loss in the SPST switch 1000 by reducing the substrate loss contribution in the shunt control transistors M₁, M₂.

Thirdly, the aspect ratios of the shunt control transistors M₁, M₂ can affect the performance of the switch 1000 in many ways. In particular, there are trade-offs in using either shunt control transistors M₁, M₂ with larger aspect ratios or shunt control transistors M₁, M₂ with smaller aspect ratios. This is elaborated below.

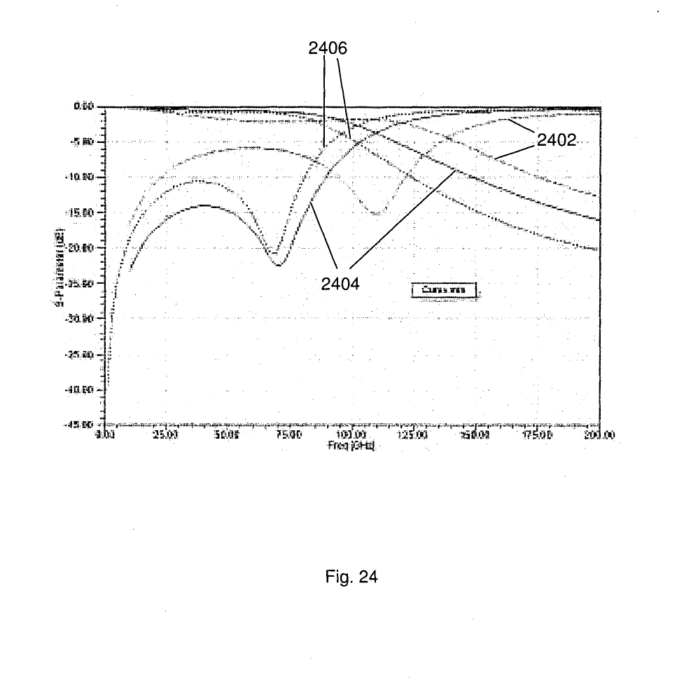

In particular, FIG. 24 shows simulation results illustrating the insertion losses and return losses of (i) a switch identical to the switch 1000 but with the DGS LPF having only the microstrip line 1102 without the defects (see curves 2402), (ii) a device identical to the switch 1000 but without the shunt transistor control elements 1006a, 1006b (see curves 2404), and (iii) the switch 1000 with the defects (including the defect patches 1106 and gap) and the shunt transistor control elements 1006a, 1006b (see curves 2406).

As shown in FIG. 24, the parasitic capacitive loading by the shunt control transistors M₁, M₂ on the DGS LPF 1004 results in a significant bandwidth reduction, a return loss degradation and an increase in the insertion loss by about 0.2 dB in the DGS LPF 1004 (and hence, in the SPST switch 1000). Therefore, it is preferable to keep this parasitic capacitive loading by the shunt control transistors M₁, M₂ on the DGS LPF 1004 low. This can be done by using shunt control transistors M₁, M₂ with lower drain-to-source coupling capacitances C_{ds} as the parasitic capacitive loading by the transistors M₁, M₂ on the DGS LPF 1004 is dominated by the C_{ds} of the transistors M₁, M₂ when these transistors M₁, M₂ are turned off. Therefore, using shunt control transistors M₁, M₂ with lower aspect ratios has the advantage of improving the bandwidth, return loss and insertion loss performance of the switch 1000 as such transistors tend to have lower drain-to-source coupling capacitances C_{ds}.

However, FIG. 24 also shows that the parasitic capacitive loading by the shunt control transistors M₁, M₂ on the DGS LPF 1004 can improve the quality factor of the DGS LPF 1004 (and hence, of the switch 1000) by shifting the anti-resonant frequency of the DGS LPF 1004 to a lower frequency. This can in turn significantly improve the skirt attenuation of the DGS LPF 1004 at a frequency beyond 100 GHz. This means that there is also an advantage in using shunt control transistors M₁, M₂ with larger aspect ratios (i.e. with higher drain-to-source coupling capacitances C_{ds}).

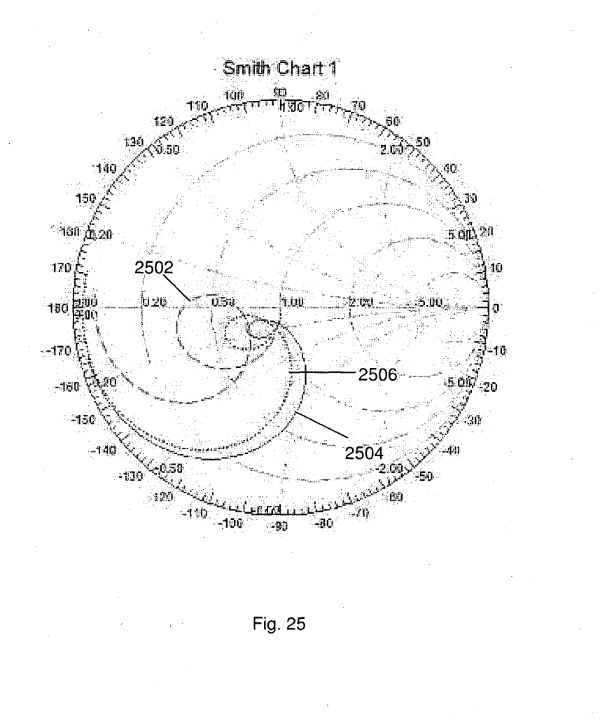

FIG. 25 shows simulation results illustrating the input impedance characteristics of (i) the switch identical to the switch 1000 but with the DGS LPF having only the microstrip line 1102 without the defects (see curves 2502), (ii) the device identical to the switch 1000 but without the shunt transistor control elements 1006a, 1006b (see curves 2504), and (iii) the switch 1000 with the defects (including the defect patches 1106 and the gap) and the shunt transistor control elements 1006a, 1006b (see curves 2506).

As shown in FIG. 25, the input impedance characteristic of the switch in (i) having the DGS LPF with only the microstrip line 1102 deviates greatly from the normalized 50Ω matching point, causing this switch to have a poor matching performance. On the other hand, due to the compensation of the transistor loading effect by the defect patches 1106, the input impedance characteristic of the switch 1000 is much closer to the normalized 50Ω matching point. Furthermore, as shown by the difference in the curves 2504 and 2506 in FIG. 25, the effect of transistor loading by the shunt control transistors M₁, M₂ on the characteristic impedance of the DGS LPF 1004 is similar to the effect of adding shunt capacitors to the input and output of the DGS LPF 1004. This effect increases when shunt control transistors M₁, M₂ having larger aspect ratios (i.e. having higher drain-to-source coupling capacitances C_{ds}) are used. Therefore, using shunt control transistors M₁, M₂ with smaller aspect ratios has the advantage that the transistor loading from these transistors M₁, M₂ tends to shift the characteristic impedance of the DGS LPF 1004 away from the matching point by a smaller amount.

Moreover, the isolation performance of SPST switches with shunt control transistors e.g. M₁, M₂ is dependent on the aspect ratios of these transistors. In particular, at low frequencies, although the isolation performance of the SPST switch 1000 is more dependent on the on-resistances of the shunt control transistors M₁, M₂ (as shown in Equation (25)), using shunt control transistors M₁, M₂ with smaller parasitic capacitances can also help to improve the isolation performance of the SPST switch 1000. This is because for the switch 1000 to be off, ideally there should be no current flowing between the input and output ports 1002a, 1002b. The shunt control transistors M₁, M₂, when turned on, are responsible for sinking most of the current from either the input port 1002a or the output port 1002b to ground. Shunt control transistors M₁, M₂ having smaller parasitic capacitances can sink current to ground more effectively and hence, can reduce the current flow between the input and output ports 1002a, 1002b when the switch 1000 is turned off. This in turn helps to improve the isolation performance of the switch 1000. At high frequencies, the isolation performance of the SPST switch 1000 is more dependent on the parasitic capacitances, especially the drain-to-source coupling capacitances C_{ds}, of the shunt control transistors M₁, M₂. This is because at high frequencies, the parasitic capacitances of the shunt control transistors M₁, M₂ provide alternative paths for the current to flow between the input and output ports 1002a, 1002b. Therefore, at both low and high frequencies, using shunt control transistors M₁, M₂ with smaller aspect ratios (and hence, lower drain-to-source parasitic capacitances C_{ds}) helps to improve the isolation performance of the SPST switch 1000. In addition, using shunt control transistors M₁, M₂ with smaller aspect ratios (and hence, lower drain-to-source parasitic capacitances C_{ds}) also helps to increase the series parasitic resonances of the switch 1000. This can further improve the isolation performance of the switch 1000.

In view of the above, it can be seen that there are trade-offs in using either shunt control transistors M₁, M₂ with larger aspect ratios or shunt control transistors M₁, M₂ with smaller aspect ratios. In particular, by using shunt control transistors M₁, M₂ with smaller aspect ratios, the switch 1000 can achieve a wider operating bandwidth, a better return loss performance, a better insertion loss performance, a better isolation performance and a lower impact on the characteristic impedance of the DGS LPF 1004 due to transistor loading, whereas by using shunt control transistors M₁, M₂ with larger aspect ratios, the switch 1000 can achieve a better quality factor.

Fourthly, the distances between the sources and drains of the shunt control transistors M₁, M₂ can also affect the performance of the switch 1000. In particular, the series parasitic resonances of the switch 1000 can also be increased (and hence, the isolation performance of the switch 1000 can also be improved) by increasing the distances between the sources and drains of the shunt control transistors M₁, M₂. Therefore, in the switch 1000 in the example implementation as described above, the distances between the sources and drains of the shunt control transistors M₁, M₂ are double that of typical transistors. However, shunt control transistors M₁, M₂ with larger distances between their sources and drains have some disadvantages. In particular, the source-to-bulk and drain-to-bulk junction capacitances C_{sb}, C_{db} of such shunt control transistors M₁, M₂ tend to be higher due to the increase in the source and drain areas. This can degrade the linearity and power handling capability of the switch 1000 (although, this can be mitigated by using linearity improvement techniques such as LC-tuned substrate bias in [21], body floating technique in [22], voltage division technique in [23], and switched body floating in [10]).). In other words, there is a trade-off between (i) the linearity and power handling capability of the switch 1000, and (ii) the series parasitic resonances (hence, isolation performance) of the switch 1000. This trade-off can be adjusted by adjusting the distances between the source and drain fingers of the transistors M₁, M₂

### Comparison of the SPST Switch 1000 in the Example Implementation Against Prior Art SPST Switches

Table 1 shows a comparison between the switch 1000 in the example implementation and prior art millimeter-wave CMOS switches described above. Characteristics of the switches compared in Table 1 include the active areas (i.e. the active footprints of the switches without the control pins, testing pads and/or routing of control signals), the total areas (i.e. the total chip areas), the insertion losses (IL), the return losses (RL) and the isolation performances (ISO). The prior art millimeter-wave CMOS switches used for the comparison in Table 1 include the inductor-based SPST switch as proposed by He at al. in references [17]-[18], the inductor-based SPST switch using the 3-bit control signal as proposed by Tomkins et al. in reference [19], the SPDT switch as proposed by Lai et al. in reference [20] and the SPDT switch as proposed by Uzunkol et al. in reference [21]. As shown in Table 1, the SPST switch 1000 in the example implementation generally performs better than the prior art millimeter-wave CMOS switches.

TABLE 1

| | SPST switch | SPST | SPST | SPDT | SPDT |
|---|---|---|---|---|---|
| | 1000 in the | switch in | switch in | switch in | switch in |
| | example | references | reference | reference | reference |
| | implementation | [17]-[18] | [19] | [20] | [21] |
| Active | 112 × 96 | 140 × 96 | 65 × 35 | — | — |
| area | | | | | |
| (μm²) | | | | | |
| Total | 330 × 330 | 340 × 340 | 520 × 290 | 750 × 400 | 550 × 500 |
| Area | | | | | |
| (μm²) | | | | | |
| IL | <1 dB | 2.8 dB | 1.6 dB | 3-4 dB | <2 dB |
| RL | >11 dB | 6 dB | 12 dB | 15 dB | 10 dB |
| ISO | >30 dB | 20 dB | >30 dB | >25 dB | >25 dB |

FIGS. 26-29 show comparisons between the switch 1000 in the example implementation against a SPST switch using an inductor for compensating the parasitic capacitances of the shunt transistors (i.e. an inductor-based switch similar to the SPST switch in references [17]-[18]), and a SPST switch using a transmission line for compensating the parasitic capacitances of the shunt transistors (i.e. a transmission-line-based switch similar to one of the SPST switches 502a, 502b in reference [20]). The aspect ratios of the shunt control transistors in the inductor-based switch and the transmission-line-based switch are equal to that in the switch 1000 in the example implementation (more specifically, equal to 80/0.06).

In particular, FIG. 26 shows simulated narrow band insertion losses of the switch 1000 (see curve 2602), the inductor-based switch (see curve 2604) and the transmission-line-based switch (see curve 2606).

As shown in FIG. 26, the narrow band insertion loss performance of the switch 1000 is superior to that of the other two switches. In particular, the narrow band insertion loss of the switch 1000 is about 1 dB better than that of the transmission-line-based switch (the switch 1000 also has a smaller overall footprint than the transmission-line-based switch). Furthermore, the switch 1000 has a wider bandwidth than the inductor-based switch.

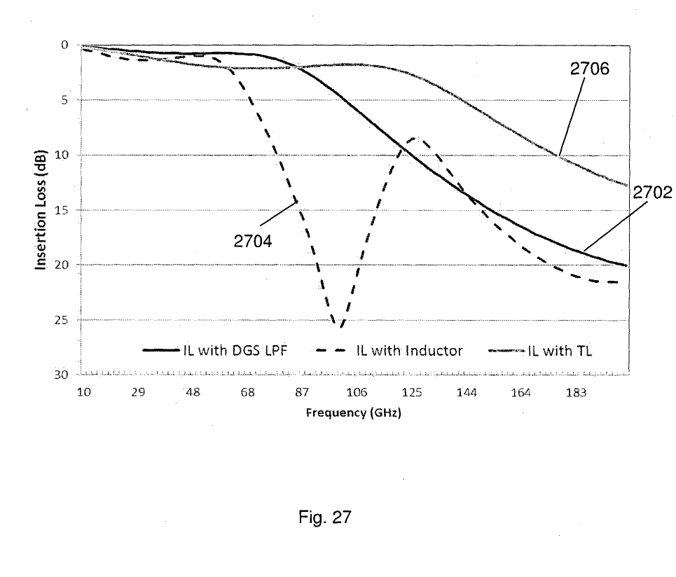

FIG. 27 shows simulated wideband insertion losses of the switch 1000 (see curve 2702), the inductor-based switch (see curve 2704) and the transmission-line-based switch (see curve 2706).

As shown in FIG. 27, the transmission-line-based switch has a much wider bandwidth than the switch 1000. This is because the zero of the transmission line in the transmission-line-based switch resides at a much higher frequency than the zero of the DGS LPF 1004 (more specifically, at 106 GHz as illustrated by FIG. 27). However, this causes a saddling problem in the transmission-line-based switch, which in turn causes the insertion loss of the transmission-line-based switch to increase at around the frequency of 58 GHz. Although this saddling problem can be improved by lowering the resonance frequency of the transmission-line-based switch, this can only be done by increasing the length of the transmission line used in the switch. Such a solution leads to an increase in the footprint of the switch. This in turn causes a decrease in the number of chips per wafer and hence, increases the chip cost for the switch. The larger bandwidth of the transmission-line-based switch also means that the Q-factor of this switch is much lower than the Q-factor of the switch 1000.

However, the Q-factor of the inductor-based switch is higher than the Q-factor of the switch 1000. This is probably due to the use of an inductor with a high Q-factor in the inductor-based switch. However, the use of such an inductor increases the difficulties in matching the inductor to the shunt control transistors in the inductor-based switch. In particular, the impedance of the switch can only reach an acceptable matching point at narrow band frequencies. In other words, the inductor cannot adequately compensate the parasitic capacitances of the shunt control transistors at its bandwidth of operation. This is shown in FIG. 27 wherein a very steep drop in the attenuation performance of the inductor-based switch can be observed at frequencies beyond 66 GHz. On the other hand, the Q-factor of the switch 1000 can be improved by increasing the sizes of the defect patches 1106 and/or decreasing the size of the space 1108 so as to increase the equivalent inductance (L_{DGS}) and capacitance (C_{DGS}) of the DGS LPF 1004 in the switch 1000. Such measures do not affect the matching performance of the switch 1000 as adversely as the use of an inductor with a high Q-factor.

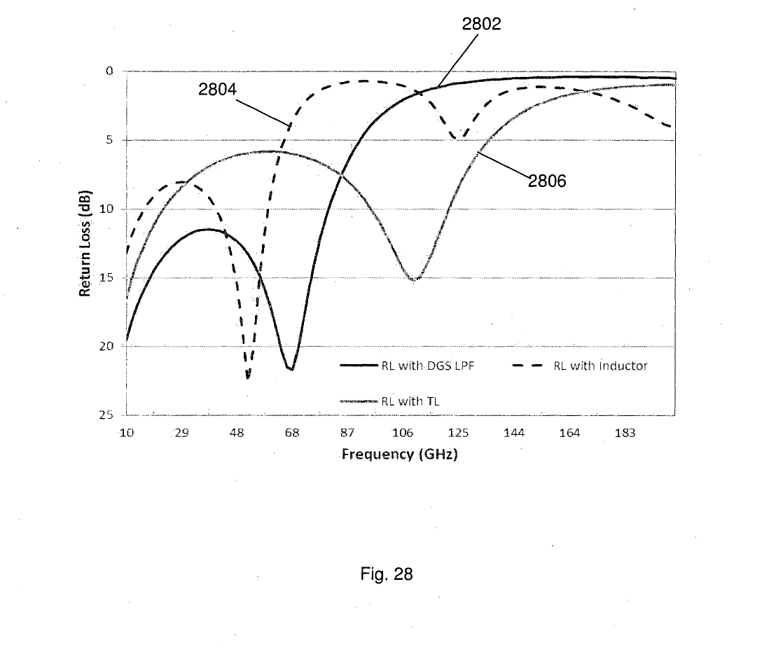

FIG. 28 shows simulated return losses of the switch 1000 (see curve 2802), the inductor-based switch (see curve 2804) and the transmission-line-based switch (see curve 2806).

As shown in FIG. 28, the return loss performance of the switch 1000 is better (in particular, the return losses of the switch 1000 are higher) than that of the other two switches at lower frequencies, more specifically from a frequency of about DC to 80 GHz.

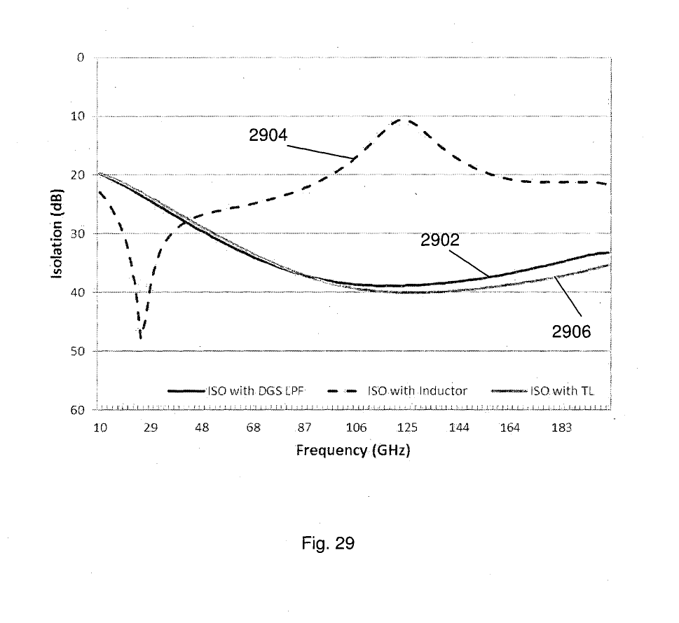

FIG. 29 shows simulated isolation performances of the switch 1000 (see curve 2902), the inductor-based switch (see curve 2904) and the transmission-line-based switch (see curve 2906).

As shown in FIG. 29, using shunt control transistors with an aspect ratio of 80/0.06, all three switches achieve an isolation performance of around 20 dB at low frequencies. However, the isolation performance of the inductor-based switch is not as good as that of the other two switches in the millimeter-wave frequency range (specifically from about 42 GHz onwards). Specifically, the worst isolation performance of the inductor based switch occurs at a frequency around 125 GHz (as can be seen from the “hump” in the curve 2904). This “hump” in the curve 2904 occurs due to the existence of series parasitic resonance in the inductor-based switch, which is dominated by the drain-to-source parasitic capacitances (C_{ds}) in the shunt control transistors of the inductor-based switch.

Furthermore, as mentioned above, the distances between the sources and drains of the shunt control transistors M₁, M₂ in the switch 1000 in the example implementation are double that of typical transistors (the same applies for the inductor-based switch and the transmission-line-based switch). This shifts the series parasitic resonance of the switch 1000 to a frequency beyond 200 GHz, allowing the switch 1000 to achieve an isolation performance that is greater than 30 dB in the millimeter-wave frequency range as shown in FIG. 29.

Another observation from FIG. 29 is that the isolation performance of the transmission-line-based switch is almost identical to the isolation performance of the switch 1000. This indicates that the isolation performances of the SPST switches are mainly dependent on the parasitic capacitances of the shunt control transistors in the switches.

### SPST Switch 3000

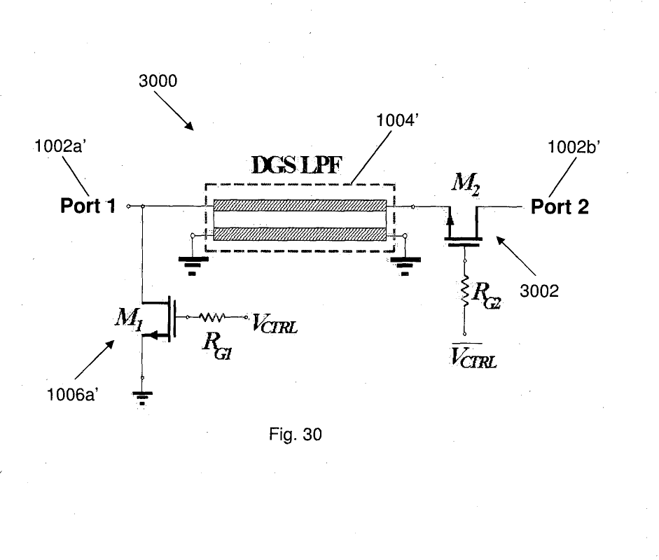

FIG. 30 shows a SPST switch 3000 according to another embodiment of the present invention. The SPST switch 3000 is similar to the SPST switch 1000 of FIG. 10 and thus, the same parts will have the same reference numerals, with the addition of prime. The input and output ports are also labelled with the same reference numerals, with the addition of prime.

As shown in FIG. 30, although the control mechanism of the SPST switch 3000 also comprises a shunt control transistor M/, it comprises a series control transistor M₂ instead of a shunt control transistor M₂. This series control transistor M₂ in the SPST switch 3000 is also in the form of a MOSFET and is connected in series with the DGS LPF 1004′ and the output port 1002b′ when the switch 3000 is in operation. Similar to the shunt control transistor M₂ in the switch 1000, a resistor R_{G2} is connected to the gate of the series control transistor M₂ in the switch 3000. This resistor R_{G2}, together with the series control transistor M₂, forms a series transistor control element 3002. In the switch 3000, the shunt control transistor M₁ is controlled by the control signal V_{CTRL} whereas the series control transistor M₂ is controlled by the inverse of this control signal V_{CTRL} i.e. V̅_{CTRL}.

The SPST switch 3000 works as follows. When the switch 3000 is turned on by switching V_{CTRL} to high, the series control transistor M₂ is turned off. This causes the series control transistor M₂ to act as an open circuit, thus preventing signal propagation between the input and output ports 1002a′, 1002b′. On the other hand, when the switch 3000 is turned off by switching V_{CTRL} to low, the series control transistor M₂ is turned on, providing a path for signal propagation between the input and output ports 1002a′, 1002b′. The shunt control transistor M₁ in the SPST switch 3000 serves as an isolation element to improve the isolation performance of the SPST switch 3000 by sinking any signal from the input or output port 1002a′, 1002b′ to ground when it is turned on by a high V_{CTRL} i.e. when the switch 3000 is turned off.

### SPST Switch 3100

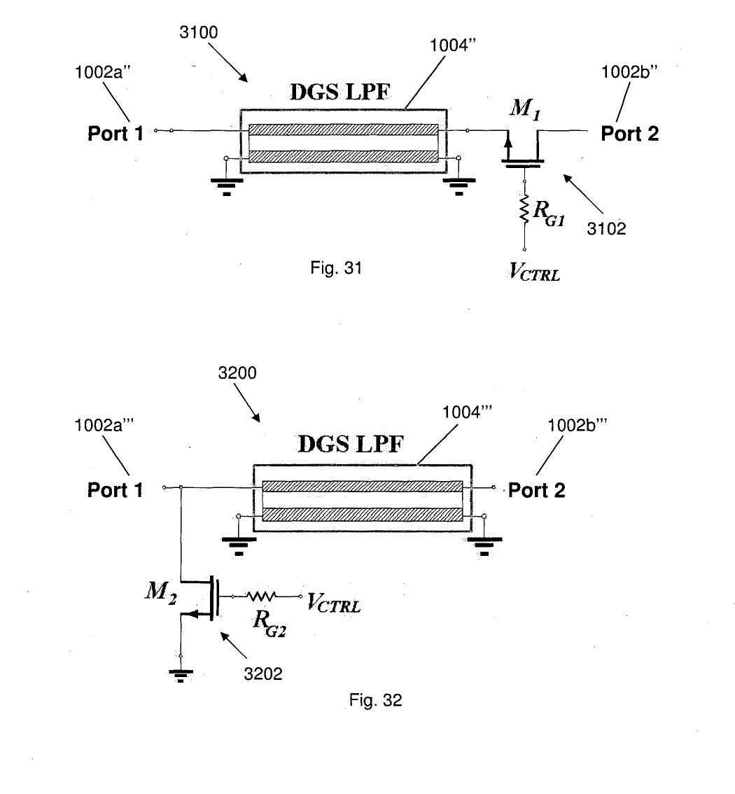

FIG. 31 shows a SPST switch 3100 according to another embodiment of the present invention. The SPST switch 3100 is similar to the SPST switch 1000 of FIG. 10 and thus, the same parts will have the same reference numerals, with addition of double prime. The input and output ports are also labelled with the same reference numerals, with the addition of double prime.

As shown in FIG. 31, the control mechanism in the SPST switch 3100 comprises only a series control transistor M₁. This series control transistor M₁ is also in the form of a MOSFET and is connected in series with the DGS LPF 1004″ and the output port 1002b″ when the switch 3100 is in operation. A resistor R_{G1} is connected to the gate of this series control transistor M₁. The resistor R_{G1}, together with the series control transistor M₁, forms a series transistor control element 3102. The series control transistor M₁ is controlled by a control signal V_{CTRL}.

The SPST switch 3100 works as follows. When the switch 3100 is turned off by switching V_{CTRL} to low, the series control transistor M₁ is turned off and acts as an open circuit preventing signal propagation between the input and output ports 1002a″, 1002b″. On the other hand, when the switch 3100 is turned on by switching V_{CTRL} to high, the series control transistor M₁ is turned on, forming a path for signal propagation between the input and output ports 1002a″, 1002b″.

### SPST Switch 3200

FIG. 32 shows a SPST switch 3200 according to another embodiment of the present invention. The SPST switch 3200 is similar to the SPST switch 1000 of FIG. 10 and thus, the same parts will have the same reference numerals, with addition of triple prime. The input and output ports are also labelled with the same reference numerals, with the addition of triple prime.

As shown in FIG. 32, the control mechanism in the SPST switch 3200 comprises only a shunt control transistor M₂. This shunt control transistor M₂ is also in the form of a MOSFET and is connected to the input port 1002a′″ in parallel with the DGS LPF 1004′″ when the switch 3200 is in operation. A resistor R_{G2} is connected to the gate of this shunt control transistor M₂. The resistor R_{G2}, together with the shunt control transistor M₁, forms a shunt transistor control element 3202. The shunt control transistor M₂ is controlled by a control signal V_{CTRL}.

The SPST switch 3200 works as follows. When the switch 3200 is turned off by switching V_{CTRL} to high, the shunt control transistor M₂ is turned on. This causes the shunt control transistor M₂ to sink signals from the input port 1002a′″, or from the output port 1002b′″ to ground. Therefore, negligible current flows between the input and output ports 1002a′″, 1002b′″. On the other hand, when the switch 3200 is turned on by switching V_{CTRL} to low, the shunt control transistor M₂ is turned off and does not sink the signals between the ports 1002a′″, 1002b″ to ground. Therefore, current is allowed to flow between the input and output ports 1002a′″, 1002b′″.

### Single-Pole-Multi-Throw (SPMT) Switches

The SPST switch 1000 and its above-mentioned variations 3000, 3100, 3200 can be used to form switches with more complicated switch topologies, such as SPMT switches including SPDT switches, SP4T switches and SP8T switches.

### SPDT Switch 3300

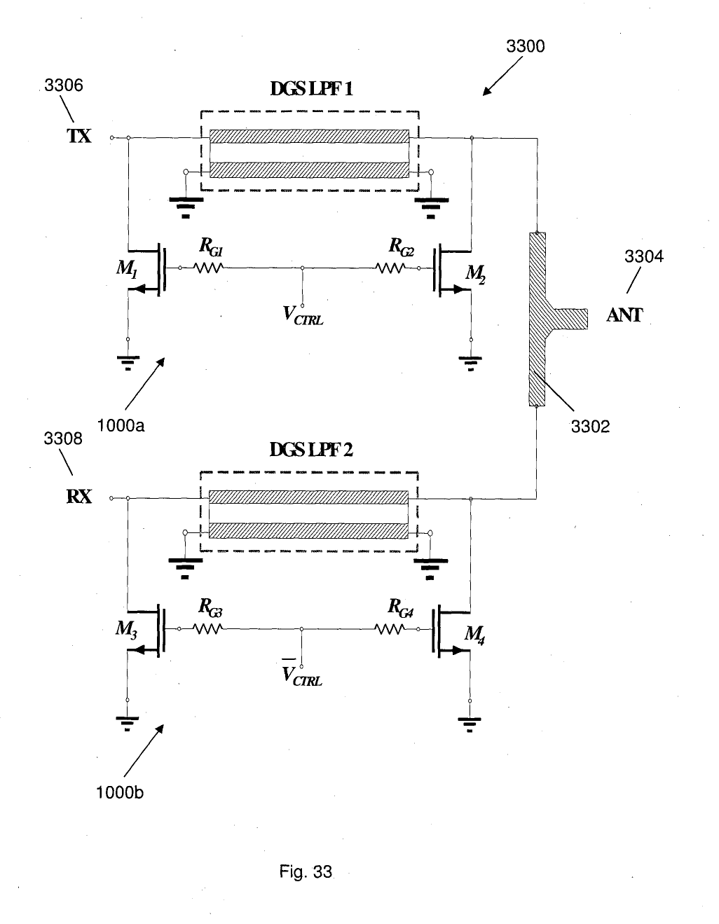

FIG. 33 shows the schematic of a T/R switch in the form of a SPDT switch 3300 according to an embodiment of the present invention.

The SPDT switch 3300 serves to control propagation of signals between a first set of ports (comprising a transmitter port TX 3306 and a receiver port RX 3308), and a second set of ports (comprising an antenna port ANT 3304). The transmitter port TX 3306 serves to connect the SPDT switch 3300 to at least one transmitter (not shown in FIG. 33), the receiver port RX 3308 serves to connect the SPDT switch 3300 to at least one receiver (not shown in FIG. 33) and the antenna port ANT 3304 serves to connect the SPDT switch 3300 to at least one antenna (not shown in FIG. 33).

As shown in FIG. 33, the SPDT switch 3300 is formed using first and second SPST switches 1000a, 1000b having the same structure as the switch 1000 in FIG. 10. In particular, the first SPST switch 1000a comprises two shunt control transistors M₁, M₂ whereas the second SPST switch 1000b comprises two shunt control transistors M₃, M₄. The first and second SPST switches 1000a, 1000b respectively serve as the TX and RX branches of the SPDT switch 3300.

The TX branch is configured to receive a control signal V_{CTRL} and the RX branch is configured to receive the inverse of this control signal V_{CTRL} i.e. V̅_{CTRL}. This can be achieved using an inverter to invert the control signal V_{CTRL}. The inverter can be implemented using a MOSFET and in this case, the increase in the overall chip size due to the use of the inverter is insignificant. The control signal V_{CTRL} serves to turn off either the TX branch or RX branch of the SPDT switch 3300 at any one time.

The SPDT switch 3300 further comprises coupling means in the form of a T-junction 3302 which serves to connect the SPST switches 1000a, 1000b together and to the antenna port ANT 3304 during operation of the switch 3300. This allows for signal propagation between either the transmitter port TX 3306 and the antenna port ANT 3304 through the SPST switch 1000a, or between the receiver port RX 3308 and the antenna port ANT 3304 through the SPST switch 1000b.

The SPDT switch 3300 operates using the control signal V_{CTRL} as follows. When V_{CTRL} is low i.e. V̅_{CTRL} is high, the control transistors M₁ and M₂ are turned off, whereas the control transistors M₃ and M₄ are turned on. As a result, the RX branch is disabled (i.e. turned off) and the TX branch is enabled (i.e. turned on). Conversely, when V_{CTRL} is high i.e. V̅_{CTRL} is low, the control transistors M₃ and M₄ are turned off, whereas the control transistors M₁ and M₂ are turned on. As a result, the TX branch is disabled and the RX branch is enabled.

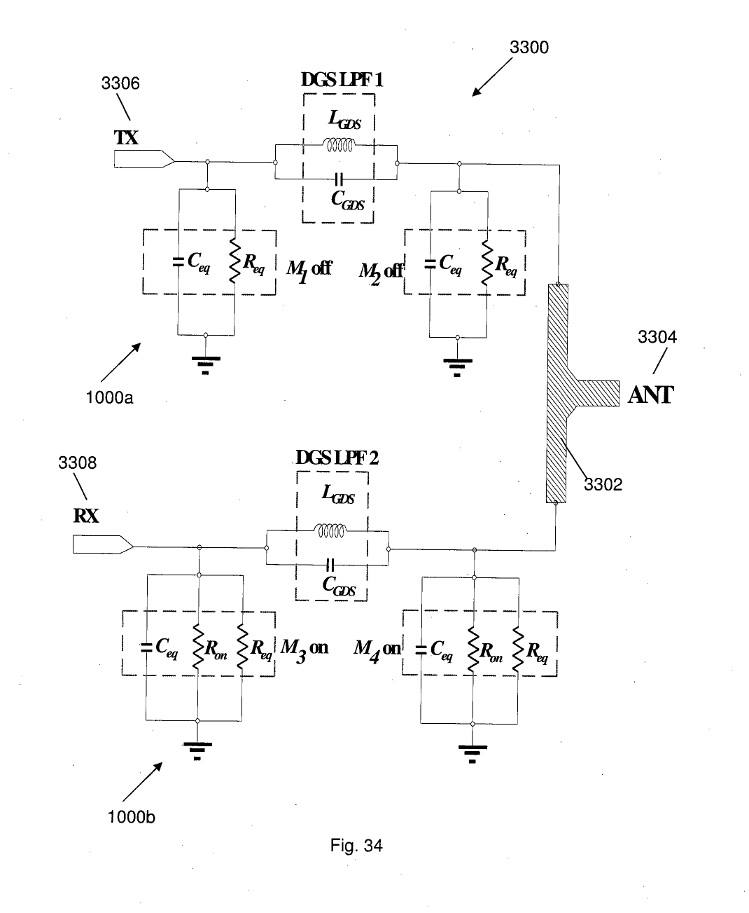

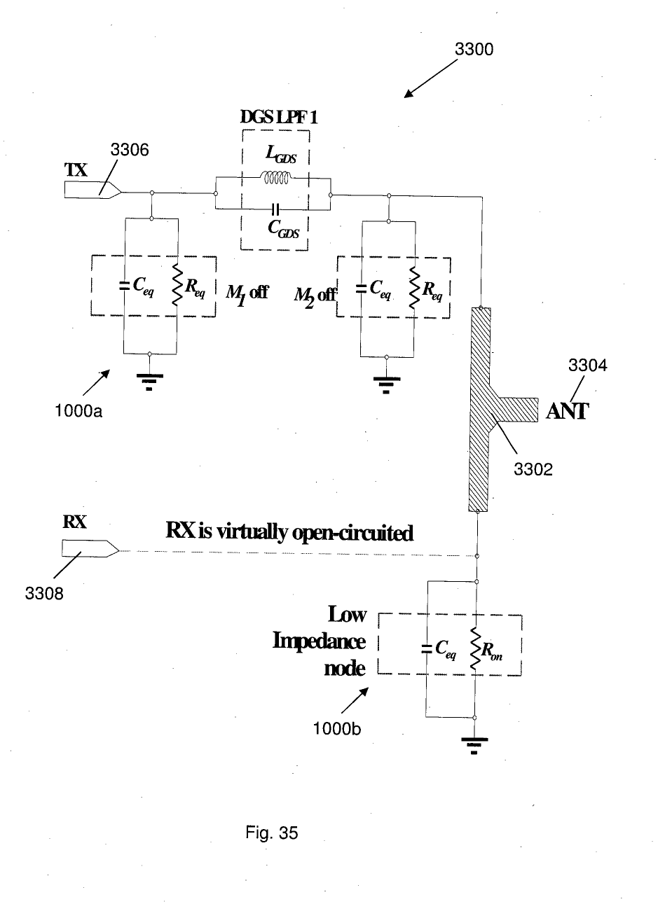

FIG. 34 shows a lump elements equivalent circuit of the SPDT switch 3300 when the RX branch is disabled and the TX branch is enabled. This lump elements equivalent circuit can be further simplified as shown in FIG. 35. This simplification can be done because when the control transistors M₃ and M₄ are turned on, almost no signal from the receiver port RX 3308 can be passed to the antenna port ANT 3304 or vice versa. This is because signals from the receiver port RX 3306 to the antenna port ANT 3304 or vice versa will be sunk to ground via the control transistors M₃ and M₄. Thus, the receiver port RX 3308 is virtually open-circuited by the control transistors M₃ and M₄. Therefore, the lump elements equivalent circuit can be simplified to the circuit as shown in FIG. 35 wherein the antenna port ANT 3308 is connected to the on-state TX branch (represented by the on-state equivalent circuit of the SPST switch 1000a) and to the off-state RX branch (represented by a parallel combination of the equivalent parasitic capacitance C_{eq} and on-resistance Rₒₙ of the shunt control transistors M₃, M₄ in the RX branch).

The parallel combination of C_{eq} and Rₒₙ in FIG. 34 behaves like a low impedance node. Therefore, there is a tendency for signals from the power amplifier of the transmitter port TX 3306 to leak to ground via C_{eq} and Rₒₙ, instead of propagating to the antenna through the antenna port ANT 3304. This can affect the overall functionality of the SPDT switch 3300, in particular, the overall efficiency of the transmission. Therefore, it is preferable to isolate C_{eq} and Rₒₙ from the TX branch to improve the transmission efficiency.

### SPDT Switch 3600

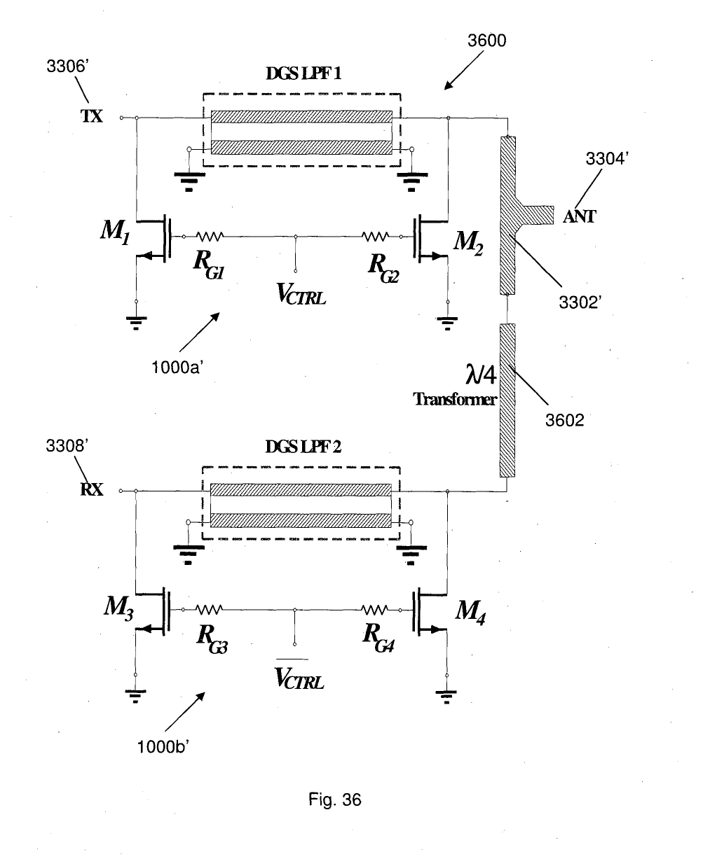

FIG. 36 shows a T/R switch in the form of a SPDT switch 3600 according to another embodiment of the present invention. The SPDT switch 3600 is similar to the SPDT switch 3300 and hence, the same parts will have the same reference numerals with the addition of prime. The ports are also labelled with the same reference numerals, with the addition of prime.

The SPDT switch 3600 is derived from the SPDT switch 3300 with an aim to isolate the parallel combination of C_{eq} and Rₒₙ from the TX branch to improve the transmission efficiency. In particular, the SPDT switch 3600 uses isolating means configured to isolate the transmitter port TX 3306 from the receiver port RX 3308. This isolating means comprises a λ/4-wavelength transformer 3602.

More specifically, the λ/4-wavelength transformer 3602 is connected between the RX branch and the T-junction 3302′ in the SPDT switch 3600. The λ/4-wavelength transformer 3602 serves as a high impedance node. Thus, signals from the TX branch encounter a high impedance node instead of a low impedance node at the T-junction 3302′. As a result, most of the signals from the TX branch propagate through the antenna port ANT 3304′ to the antenna for transmission, instead of leaking to the ground. This improves the transmission efficiency.

However, one drawback of the SPDT switch 3600 is that the λ/4-wavelength transformer 3602 has a large size. Thus the number of chips per wafer for the SPDT switch 3600 is low and in turn, the chip cost of the SPDT switch 3600 is high.

### SPDT Switch 3700

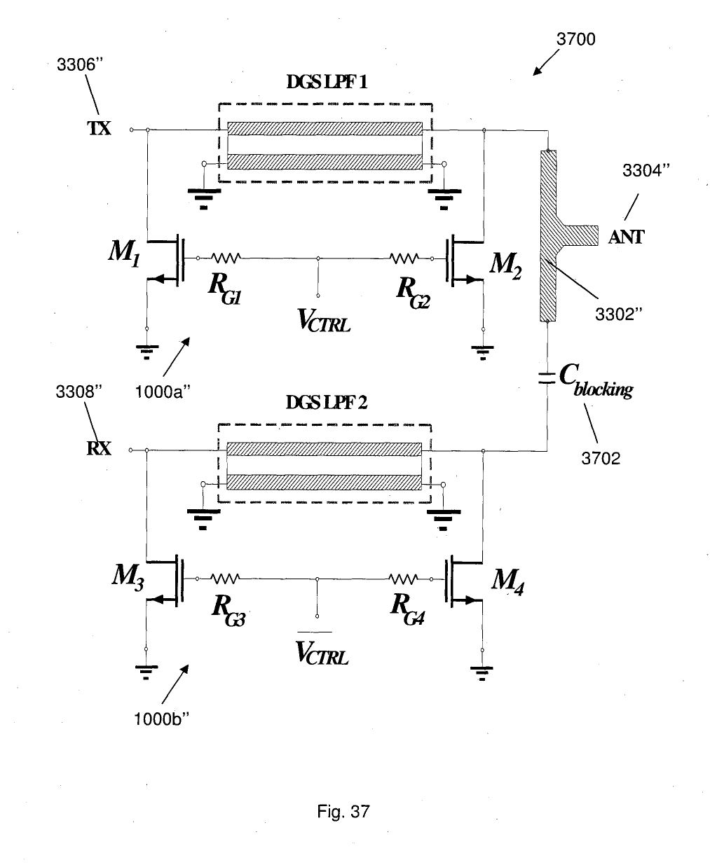

FIG. 37 shows a T/R switch in the form of a SPDT switch 3700 according to another embodiment of the present invention. The SPDT switch 3700 is also similar to the SPDT switch 3300 and hence, the same parts will have the same reference numerals with the addition of double prime. The ports are also labelled with the same reference numerals, with the addition of double prime.

The SPDT switch 3700 is also derived from the SPDT switch 3300 with an aim to isolate the parallel combination of C_{eq} and Rₒₙ from the TX branch to improve the transmission efficiency. In particular, the SPDT switch 3700 also uses isolating means configured to isolate the transmitter port TX 3306″ from the receiver port RX 3308″. However, this isolating means comprises a blocking capacitance 3702 instead of a λ/4-wavelength transformer.

More specifically, the blocking capacitance 3702 is connected between the T-junction 3302″ and the RX branch to isolate the low impedance node (comprising C_{eq} and Rₒₙ) from the T-junction 3302″ when the TX branch is turned on. As a result, most of the signals from the TX branch propagate through the antenna port ANT 3304″ to the antenna for transmission, instead of leaking to the ground via the low impedance node. This improves the transmission efficiency.

However, there are drawbacks in the SPDT switch 3700 as well. Firstly, the size of on-chip blocking capacitance can also be quite large and thus, using the blocking capacitance 3702 can increase the footprint of the SPDT switch 3700. Secondly, placing the blocking capacitance 3702 along the direct signal path from the antenna port ANT 3304″ to the RX branch can degrade the overall insertion loss of the RX branch.

### SPDT Switch 3800

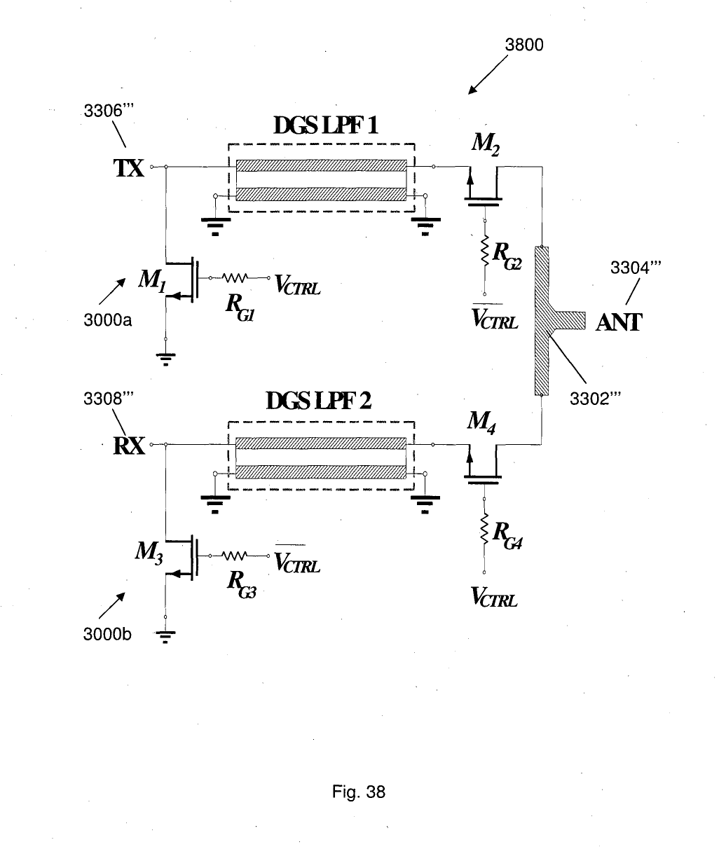

FIG. 38 shows a T/R switch in the form of a SPDT switch 3800 according to another embodiment of the present invention. The SPDT switch 3800 is similar to the SPDT switch 3300 and hence, the same parts will have the same reference numerals with the addition of triple prime. The ports are also labelled with the same reference numerals, with the addition of triple prime.

As shown in FIG. 38, instead of using SPST switches having the same structure as the SPST switch 1000 in FIG. 10, the SPDT switch 3800 comprises first and second SPST switches 3000a, 3000b having the same structure as the SPST switch 3000 in FIG. 30. In particular, the first SPST switch 3000a comprises a shunt control transistor M₁ and a series control transistor M₂, whereas the second SPST switch 3000b comprises a shunt control transistor M₃ and a series control transistor M₄. Preferably, transistors having low on-resistances (Rₒₙ) are used as the series control transistors M₂, M₄ so as to minimize signal loss. The SPST switches 3000a, 3000b are arranged such that the two series control transistors M₂, M₄ are connected in series with the T-junction 3402″. The first and second SPST switches 3000a, 3000b respectively serve as the TX and RX branches of the SPDT switch 3800.

All the control transistors M₁, M₂, M₃, M₄ in the SPDT switch 3800 are controlled by the same control signal V_{CTRL}. However, while the control transistors M₁ and M₄ are controlled by V_{CTRL}, the control transistors M₂ and M₃ are controlled by the inverse of V_{CTRL} i.e. V̅_{CTRL}. The SPDT switch 3800 operates using the control signal V_{CTRL} as follows. When V_{CTRL} is high i.e. V̅_{CTRL} is low, the series control transistor M₂ is turned off whereas the series control transistor M₄ is turned on. Thus, the TX branch is disabled and the RX branch is enabled. On the other hand, when V_{CTRL} is low i.e. V̅_{CTRL} is high, the series control transistor M₂ is turned on whereas the series control transistor M₄ is turned off. Thus, the TX branch is enabled and the RX branch is disabled. Only one of the series control transistors M₂ and M₄ should be turned on at any one time. The shunt control transistors M₁, M₃ serve to improve the isolation performance of the SPDT switch 3800 by grounding any signals from the transmitter port TX 3306′″ or from the receiver port RX 3308′″ when these transistors M₁, M₃ are turned on.

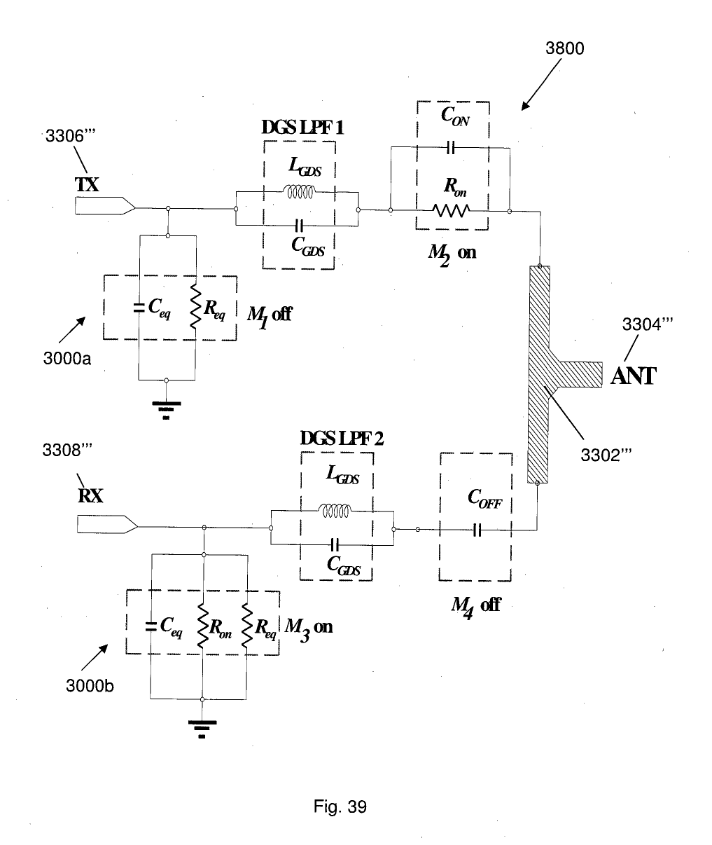

FIG. 39 shows a lump elements equivalent circuit of the SPDT switch 3800 when the TX branch is turned on and the RX branch is turned off. As shown in FIG. 39, when the series control transistor M₂ is turned on, it can be represented by its on-capacitance C_{ON} in parallel with its on-resistance Rₒₙ. When the series control transistor M₄ is turned off, it can be represented by its off-capacitance C_{OFF}. In the circuit in FIG. 39, the equivalent parasitic capacitances C_{eq} of the shunt control transistors M₁ and M₃ are assumed to be equal (although they may be different in an actual implementation of the switch 3800). Similarly, the equivalent substrate parasitic resistances R_{eq} of the shunt control transistors M₁ and M₃ are assumed to be equal (although they may be different in an actual implementation of the switch 3800). The equivalent inductances L_{GDS} and capacitances C_{GDS} of the DGS LPFs in both the TX and RX branches are also assumed to be equal (although they may also be different in an actual implementation of the switch 3800).

The off capacitance C_{OFF} of the series control transistor M₄ performs a similar function as the blocking capacitance 3702 in FIG. 37. More specifically, the off capacitance C_{OFF} helps to isolate the receiver port RX 3308′″ from the antenna port ANT 3304′″. This is because the off capacitance C_{OFF} of the series control transistor M₄ acts as a high impedance node in the RX branch and hence, leakage of the signals from the TX branch through the RX branch is reduced. Furthermore, the series control transistor M₂ of the TX branch provides a low resistive path between the transmitter port TX 3406′″ and the antenna port ANT 3404′″ when it is turned on. This minimizes signal transmission loss. Therefore, the transmission efficiency of the SPDT switch 3900 is better than the transmission efficiency of the SPDT switch 3300 in FIG. 33. Moreover, unlike the SPDT switch 3600 using the λ/4-wavelength transformer 3602 or the SPDT switch 3700 using the blocking capacitance 3702, the SPDT switch 3800 is able to achieve the improved transmission efficiency (over the SPDT switch 3300) without using components additional to those used in the SPDT switch 3300 (hence, no additional footprint is required).

The insertion loss (ANT-TX or TX-ANT) of the SPDT switch 3800 when the TX branch is turned on and the RX branch is turned off is dependent on the ohmic losses that are introduced by the DGS LPF in the TX branch (i.e. DGS LPF 1) and the on-resistance Rₒₙ of the series control transistor M₂. Therefore, the insertion loss of the SPDT switch 3800 can be reduced by using a transistor having a lower on-resistance as the series control transistor M₂. In particular, a transistor having a larger aspect ratio has a lower on-resistance. Also, a multi-fingers transistor has a lower on-resistance than a single-finger transistor.

As shown in FIG. 39, the series control transistor M₂ when turned on can be represented by an equivalent on-parasitic capacitance C_{ON} and an on-resistance Rₒₙ in parallel with each other. In other words, when the TX branch is turned on, the TX branch comprises a parallel combination of C_{ON} and Rₒₙ (C_{ON}//Rₒₙ) in series with a parallel combination of L_{GDS} and C_{GDS} (L_{GDS}//C_{GDS}) which is the equivalent model of the DGS LPF in the TX branch. Due to this series connection, the equivalent impedance seen from the antenna port ANT 3304′″ into the TX branch of the SPDT switch 3800 is higher than that for the SPDT switch 3300. This causes the matching performance of the SPDT switch 3800 to be worse than that of the SPDT switch 3300. The same problem arises in the RX branch when the series control transistor M₄ is turned on. This problem can be ameliorated by reducing the area of the defect patches in the DGS LPFs (i.e. DGS LPF 1 and DGS LPF 2) to reduce the equivalent inductances L_{GDS} of these DGS LPFs and/or by increasing the sizes of the spaces between the defect patches in the DGS LPFs to reduce the equivalent capacitances C_{GDS} of the DGS LPFs. Since the on-capacitances C_{ON} of transistors are usually dominated by the drain-to-source coupling capacitances C_{ds}, the above-mentioned problem can also be ameliorated by using control transistors M₂, M₄ with larger distances between their source and drain metalizations as such transistors tend to have lower drain-to-source coupling capacitances C_{ds}.

The input return loss (TX return loss) and output return loss (ANT return loss) in the SPDT switch 3800 are not the same since the transmitter port TX 3306′″ and the antenna port ANT 3304′″ see different equivalent impedances. In particular, the antenna port ANT 3304′″ sees the impedance of the RX branch in parallel with the impedance of the TX branch. The equivalent impedance seen from the antenna port ANT 3304′″ when the TX branch is turned on and the RX branch is turned off is shown in Equation (30). In particular, in Equation (30), Z_{ANT} represents the equivalent impedance seen from the antenna port ANT 3304′″, Z_{OFF} represents the impedance of the RX branch when the RX branch is turned off and Z_{ON} represents the impedance of the TX branch when the TX branch is turned on.

$${Z}_{ANT} = {Z}_{ON} // {Z}_{OFF} \\ {Z}_{ON} = \frac{1}{jω {C}_{ON}} // {R}_{on} + jω {L}_{DGS} // \frac{1}{jω {C}_{DGS}} + \frac{1}{jω {C}_{eq}} + // {R}_{eq} \\ {Z}_{OFF} = \frac{1}{jω {C}_{OFF}} + jω {L}_{GDS} // \frac{1}{jω {C}_{GDS}} + \frac{1}{jω {C}_{eq}} // {R}_{eq} // {R}_{on} \qquad ( 30 )$$

In the case where control transistors M₁, M₂, M₃, M₄ with R_{eq}>>1/(jωC_{eq}) and with C_{ds} dominating their C_{eq} are used, the parallel combination of C_{eq} and R_{eq} can be expressed as C_{eq}//R_{eq}=1/(jωC_{ds}). If the on-capacitance C_{ON} of the series control transistor M₂ is also dominated by its drain-to-source coupling capacitance C_{ds}, the expression of Z_{ON} can be simplified as shown in Equation (31) where C_{ds1}, C_{ds2} respectively represents the drain-to-source coupling capacitance of the control transistors M₁ and M₂.

$${Z}_{ON} ≅ \frac{1}{jω {C}_{ds 2}} // {R}_{on} + jω {L}_{GDS} // \frac{1}{jω {C}_{GDS}} + \frac{1}{jω {C}_{ds 1}} \qquad ( 31 )$$

The on-resistances Rₒₙ of the control transistors M₁, M₂, M₃, M₄ tend to be much lower than their equivalent resistances R_{eq} especially at low frequencies. In other words, Rₒₙ<<1/(jωC_{eq})<<R_{eq}. Furthermore, C_{ds} also tends to dominate the off-capacitance C_{off} of the control transistors M₁, M₂, M₃, M₄. Therefore, the impedance of the RX branch when the RX branch is turned off (i.e. Z_{OFF}) can be simplified as shown in Equation (32), where C_{ds3}, C_{ds4} respectively represents the drain-to-source coupling capacitance of the control transistors M₃ and M₄.

$${Z}_{OFF} ≅ \frac{1}{jω {C}_{ds 4}} + jω {L}_{GDS} // \frac{1}{jω {C}_{GDS}} + \frac{1}{jω {C}_{ds 3}} // {R}_{on} \qquad ( 32 )$$

Equations (30)-(32) can be used as guidelines for tuning the return loss, insertion loss and the isolation performance of the SPDT switch 3800. These equations also provide meaningful information to aid the development of more complicated switches comprising more TX and/or RX branches from the SPDT switch 3800.

### SPDT Switch 4000

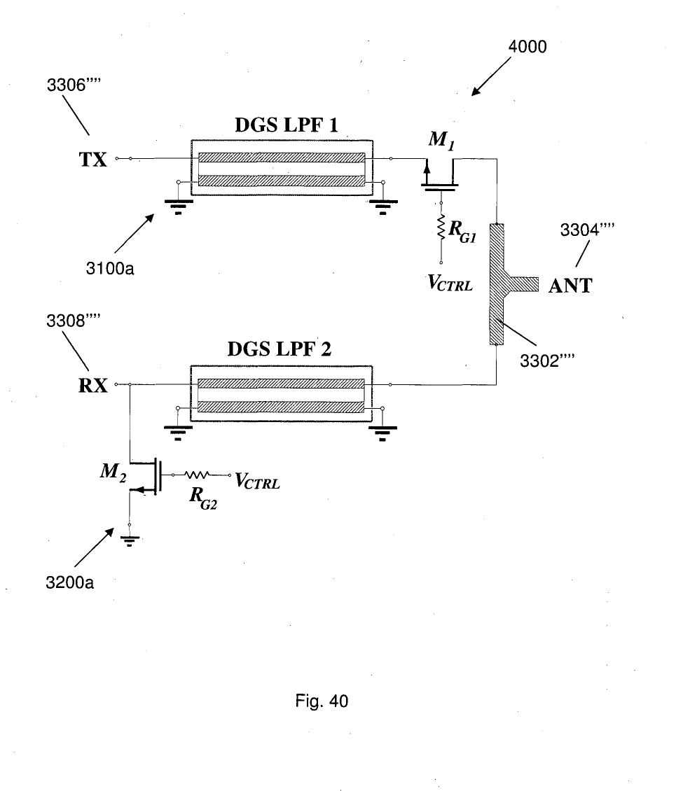

FIG. 40 shows the schematic of a T/R switch in the form of a SPDT switch 4000 according to another embodiment of the present invention. The SPDT switch 4000 is also similar to the SPDT switch 3300 and hence, the same parts will have the same reference numerals with the addition of quadraple prime. The ports are also labelled with the same reference numerals, with the addition of quadraple prime.

As shown in FIG. 40, instead of comprising two SPST switches having the same structure as the SPST switch 1000 in FIG. 10, the SPDT switch 4000 comprises a SPST switch 3100a having the same structure as the SPST switch 3100 in FIG. 31 and a SPST switch 3200a having the same structure as the SPST switch 3200 in FIG. 32. In particular, the SPST switch 3100a comprises a series control transistor M₁, whereas the SPST switch 3200a comprises a shunt control transistor M₂. In other words, the SPDT switch 4000 comprises only two control transistors M₁ and M₂, and has an asymmetrical topology.

Both the series control transistor M₁ and the shunt control transistor M₂ are controlled by the same control signal V_{CTRL} having the same polarity. Hence, the SPDT switch 4000 does not require an inverter. In other words, the SPDT switch 4000 requires less components (and hence has a smaller overall footprint) than the SPDT switches 3300, 3600, 3700 and 3800 as shown in FIGS. 33, 36, 37 and 38 respectively.

The SPDT switch 4000 in FIG. 40 operates using the control signal V_{CTRL} as follows. When the control signal V_{CTRL} is high, the series control transistor M₁ and the shunt control transistor M₂ are both turned on. Hence, the RX branch is disabled and the TX branch is enabled. On other hand, when the control signal V_{CTRL} is low, the series control transistor M₁ and the shunt control transistor M₂ are both turned off. Hence, the RX branch is enabled and the TX branch is disabled.

The isolation performance of the SPDT switch 4000 is dependent on two factors. The first factor is the effectiveness of the series control transistor M₁ as an open circuit to prevent signal propagation between the transmitter port TX 3306″″ and the antenna port ANT 3304″″ when this series control transistor M₁ is turned on. The second factor is the effectiveness of the shunt control transistor M₂ in sinking any signals from the receiver port RX 3308″ or from the antenna port ANT 3304″″ to ground when this shunt control transistor M₂ is turned on.

In the SPDT switch 4000, the impedances of the TX and RX branches as seen from the antenna port ANT 3304″″ when the TX branch is turned on and the RX branch is turned off (i.e. Z_{ON} and Z_{OFF}) can be expressed as:

$$\begin{matrix}{Z}_{ON} ≅ \frac{1}{jω {C}_{ds 1}} // {R}_{on} + jω {L}_{GDS} // \frac{1}{jω {C}_{GDS}} & ( 33 ) \\ {Z}_{OFF} ≅ jω {L}_{GDS} // \frac{1}{jω {C}_{GDS}} + \frac{1}{jω {C}_{ds 2}} // {R}_{on} & ( 34 )\end{matrix}$$

Similarly, Equations (33)-(34) can be used as guidelines for tuning the return loss, insertion loss and the isolation performance of the SPDT switch 4000. These equations also provide meaningful information to aid the development of more complicated switches comprising more TX and/or RX branches from the SPDT switch 4000.

### SP4T Switch 4100

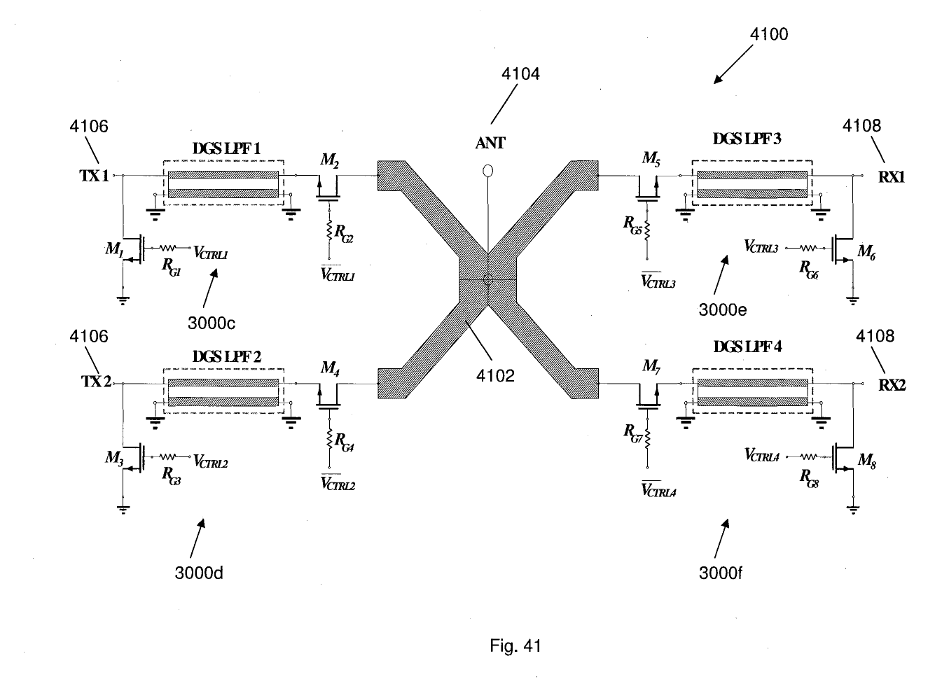

FIG. 41 shows the schematic of a T/R switch in the form of a SP4T switch 4100 according to an embodiment of the present invention.

Similar to the SPDT switches 3300, 3600, 3700, 3800, 4000, the SP4T switch 4100 serves to control propagation of signals between a first set of ports and a second set of ports. However, while the second set of ports in FIG. 41 also comprises a single antenna port ANT 4104, the first set of ports in FIG. 41 comprises more transmitter and receiver ports. In particular, the first set of ports in FIG. 41 comprises first and second transmitter ports TX1, TX2 4106 and first and second receiver ports RX1, RX2 4108. Each transmitter port TX1, TX2 4106 serves to connect the SP4T switch 4100 to at least one transmitter (not shown in FIG. 41), each receiver port RX1, RX2 4108 serves to connect the SP4T switch 4100 to at least one receiver (not shown in FIG. 41) and the antenna port ANT 4104 serves to connect the SP4T switch 4100 to at least one antenna (not shown in FIG. 41).

As shown in FIG. 41, the SP4T switch 4100 is formed using two SPDT switches, each having a similar structure as the SPDT switch 3800 in FIG. 38. In other words, the SP4T switch 4100 comprises four SPST switches 3000c, 3000d, 3000e, 3000f, each having the same structure as the SPST switch 3000 in FIG. 30. The SPST switches 3000c, 3000d respectively serve as the TX1 and TX2 branches, whereas the SPST switches 3000e, 3000f respectively serve as the RX1 and RX2 branches.

Similar to the SPDT switches 3300-4000 as mentioned above, the SP4T switch also comprises coupling means which serves to connect its SPST switches 3000c, 3000d, 3000e, 3000f together and to the antenna port ANT 4104 during operation of the switch 4100. This allows signal propagation between a port in the first set of ports and the antenna port ANT 4104 through one of the SPST switches 3000c, 3000d, 3000e, 3000f. However, instead of a T-junction, the coupling means used by the SP4T switch 4100 comprises a 4-way power combiner 4102.

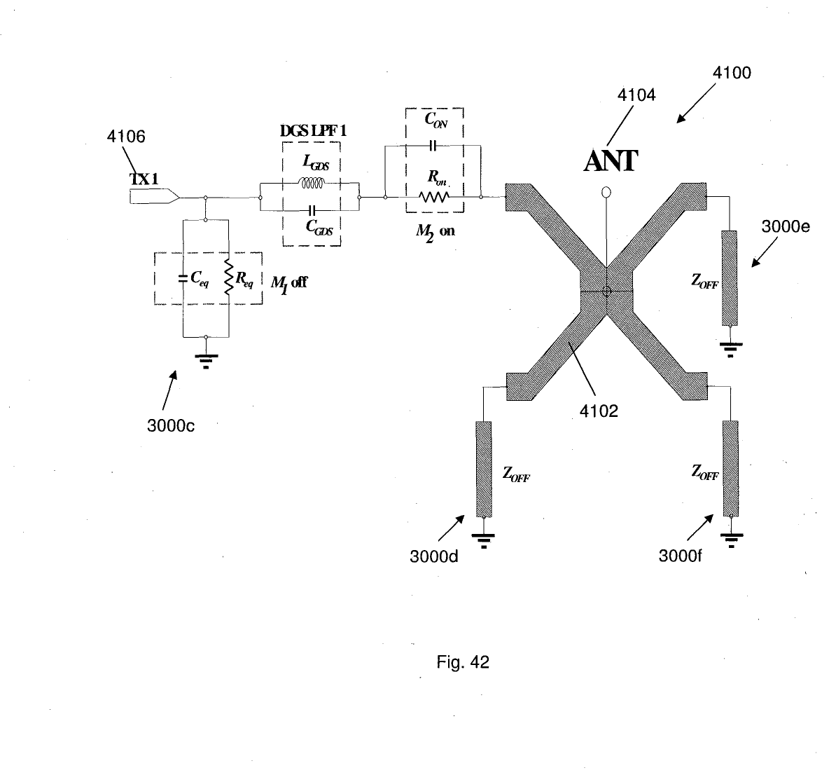

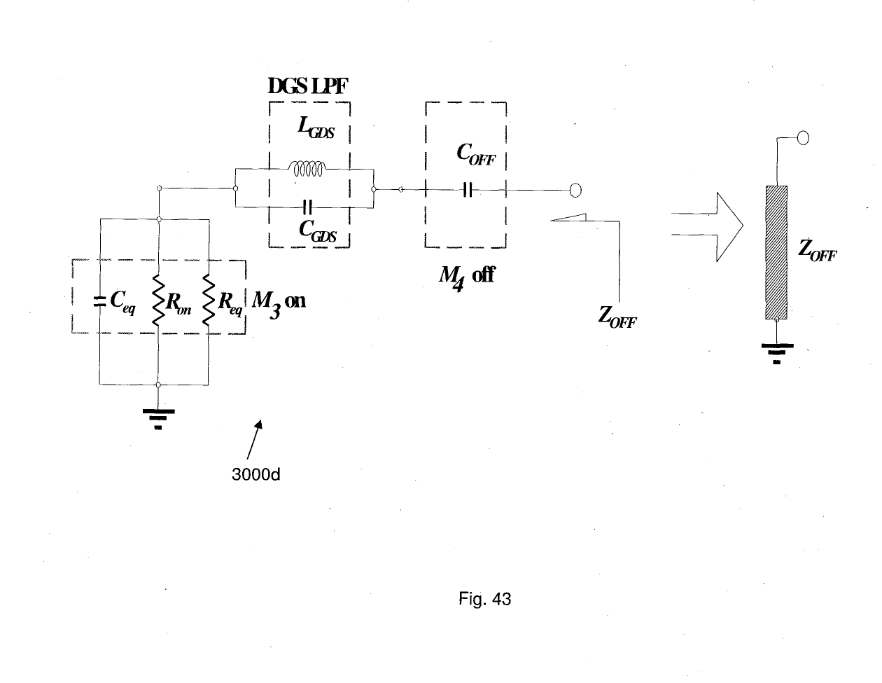

Each of the TX1, TX2, RX1, RX2 branches are configured to be controlled by a respective control signal V_{CTRL1}, V_{CTRL2}, V_{CTRL3}, V_{CTRL4} so that only one branch of the SP4T switch 4100 is enabled at any one time. Therefore, when in operation, the SP4T switch 4100 can be represented by one active path comprising the on-impedance (Z_{ON}) of the active (i.e. enabled) branch and three non-active paths comprising the off-impedances (Z_{OFF}) of the remaining non-active (i.e. disabled) branches. This is illustrated in FIG. 42 which shows the equivalent circuit of the SP4T switch 4100 when the TX1 branch is turned on and the remaining branches are turned off. The off-impedance Z_{OFF} of one of the disabled branches (in particular, the TX2 branch) as seen from the antenna port ANT 4104 is shown in FIG. 43.

When the switch 4100 is in operation, the equivalent impedance seen by the antenna port ANT 4104 is almost half of the impedance seen by the antenna port ANT 3304′″ when the switch 3800 is in operation. This is because when the SP4T switch 4100 is in operation, the antenna port ANT 4104 is connected to 3 non-active branches (e.g. TX2, RX1, and RX2 branches), with each of these branches having an off-impedance of Z_{OFF}. Since these non-active branches are connected in parallel, their equivalent impedance is only (⅓)Z_{OFF}. This lower equivalent impedance seen by the antenna port ANT 4104 can adversely affect the matching performance (and hence, the return loss performance) of the SP4T switch 4100 at the antenna port ANT 4104.

One way of improving the matching performance of the SP4T switch 4100 is to increase the off-impedance Z_{OFF} of each of its branches i.e. each of its SPST switches 3000c, 3000d, 3000e, 3000f by three times so as to achieve the original matching condition i.e. the matching condition of the SPDT switch 3800. In other words, the off-impedance Z_{OFF} of each branch in the SP4T switch 4100 can be set as Z_{OFF}=3Z_{OFF} to improve its matching performance, where T_{OFF} represents the off-impedance of each branch in the SP4T switch 4100 whereas Z_{OFF} represents the off-impedance of each branch in the SPDT switch 3800. From Equation (32), it can be seen that Z_{OFF} of each branch in the SP4T switch 4100 is inversely proportional to the drain-to-source coupling capacitance C_{ds} of the series control transistor (i.e. M₂, M₄, M₅ or M₇) in the branch. Hence, by using control transistors having larger distances between their source-to-drain metalizations (and hence, lower drain-to-source capacitances C_{ds}) as the series control transistors M₂, M₄, M₅, M₇, the Z_{OFF} of each branch in the SP4T switch 4100 can be increased.

Although the SP4T switch 4100 has a poorer matching performance as compared to the SPDT switch 3800 without the above-mentioned adjustment to the off-impedance Z_{OFF} of each of its branches, the return loss performance of the SP4T switch 4100 at the transmitter ports TX1, TX2 4106 is superior to that of the SPDT switch 3800 at the transmitter port TX 3306′″. This is because the equivalent impedance of (⅓)Z_{OFF} contributed by the non-active branches, the off-capacitance C_{ON} of the series control transistor in the active branch (e.g. M₂), the DGS LPF in the active branch (e.g. DGS LPF1) and the equivalent parasitic capacitance C_{eq} of the shunt control transistor in the active branch (e.g. M₁) form a π-network.

### SP4T Switch 4400

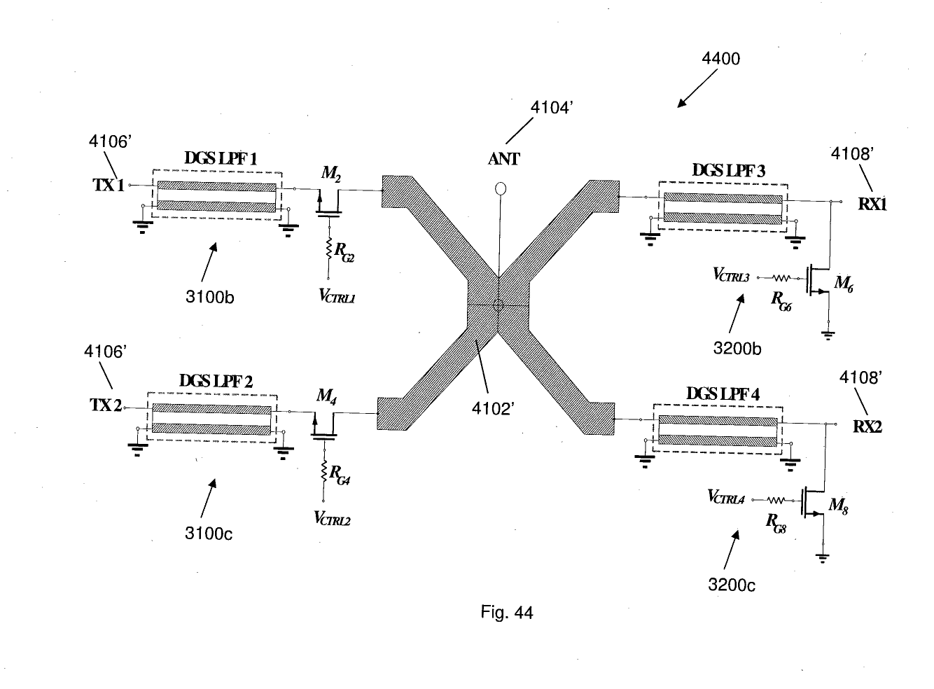

FIG. 44 shows the schematic of a T/R switch in the form of a SP4T switch 4400 according to another embodiment of the present invention. The SP4T switch 4400 is similar to the SP4T switch 4100, and hence the same parts will have the same reference numerals with the addition of prime. The ports are also labelled with the same reference numerals with the addition of prime.

As shown in FIG. 44, instead of comprising two SPDT switches having a similar structure as the SPDT switch 3800 in FIG. 38, the SP4T switch 4400 comprises two SPDT switches having a similar structure as the SPDT switch 4000 in FIG. 40. Hence, the SP4T switch 4400 also has an asymmetric topology. More specifically, the SP4T switch 4400 comprises two SPST switches 3100b, 3100c having the same structure as the SPST switch 3100 in FIG. 31, and two SPST switches 3200b, 3200c having the same structure as the SPST switch 3200 in FIG. 32. The SPST switches 3100b, 3100c respectively serve as the TX1 and TX2 branches, whereas the SPST switches 3200b, 3200c respectively serve as the RX1 and RX2 branches. In other words, the TX branches (TX1, TX2) comprise series control transistors M₂, M₄ which serve to isolate the RX branches (RX1, RX2) from the transmitter ports TX1, TX2 4106′, whereas the RX branches (RX1, RX2) comprise shunt control transistors M₆, M₈ which serve to isolate the TX branches (TX1, TX2) from the receiver ports RX1, RX2 4108′.

As compared to the SP4T switch 4100 in FIG. 41, the SP4T switch 4400 in FIG. 44 comprises four less control transistors. Furthermore, unlike the SP4T switch 4100 in FIG. 41, the SP4T switch 4400 in FIG. 44 does not require inverters since it is based on the SPDT switch 4000 which does not require inverters. Therefore, a smaller overall chip footprint can be achieved for the SP4T switch 4400. Furthermore, both the SP4T switches 4100, 4400 use 4 independent control signals V_{CTRL1}-V_{CTRL4}, but while it is necessary to route the inverters to the respective transistors in the SP4T switch 4100 to provide these transistors with the inverse of the control signals, it is not necessary to do so in the SP4T switch 4400. Therefore, there is less routing complexity in the SP4T switch 4400. This allows the fabrication of the switch 4400 to be more economical.

### SPMT Switch 4500 Using a Cascaded Multi-Throws Approach

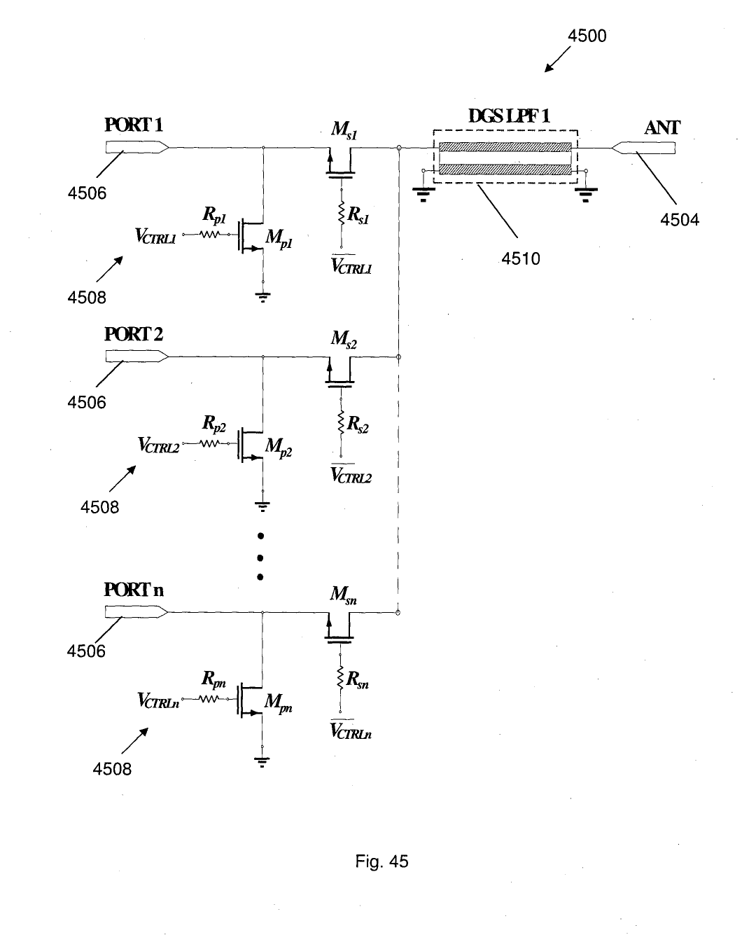

FIG. 45 shows the schematic of a SPMT switch 4500 according to an embodiment of the present invention. This SPMT switch 4500 is implemented using a cascaded multi-throws approach.

Similar to the above-mentioned SPDT switches 3300-4000 and SP4T switches 4100, 4400, the SPMT switch 4500 serves to control propagation of signals between a first set of ports and a second set of ports. In this case, the first set of ports comprises n ports (PORT1-PORTn) 4506 whereas the second set of ports comprises an antenna port ANT 4504.

As shown in FIG. 45, the SPMT switch 4500 comprises a plurality of (n) circuits 4508 and a DGS LPF 4510. Each circuit 4508 in turn comprises a shunt control transistor Mₛ₁-Mₛₙ and a series control transistor Mₚ₁-Mₚₙ. The series control transistors Mₛ₁-Mₛₙ are connected in parallel with each other from the DGS LPF 4510. Furthermore, when the switch 4500 is in operation, the shunt control transistor Mₚ₁-Mₚₙ in each circuit is connected in parallel with the series control transistor Mₛ₁-Mₛₙ in the circuit from a port in the first set of ports (PORT1-PORTn).

Each circuit 4508 is controlled by a respective control signal V_{CTRL1}-V_{CTRLn} and together with the DGS LPF 4510, operates in the same manner as the SPST switch 3000 in FIG. 30. In particular, when V_{CTRL1} is low and the remaining control signals V_{CTRL2}-V_{CTRLn} are high, the series control transistor Mₛ₁ in the circuit controlled by V_{CTRL1} is turned on whereas the series control transistor Mₛ₂-Mₛₙ in the remaining circuits are turned off, and the shunt control transistor Mₚ₁ in the circuit controlled by V_{CTRL1} is turned off whereas the shunt control transistors Mₚ₂-Mₚₙ in the remaining circuits are turned on. This causes the circuit controlled by V_{CTRL1} to be enabled and the remaining circuits to be disabled. The switch 4500 is configured such that only one of the control signals V_{CTRL1}-V_{CTRLn} is low at any one time.

In other words, the SPMT switch 4500 is effectively the same as a SPMT switch comprising a plurality of SPST switches 3000 coupled together by coupling means (e.g. SPDT switches 3300-4000 or SP4T switches 4100, 4400), except that the SPMT switch 4500 comprises a single DGS LPF 4510 which serves as the DGS LPF 1004′ for all the SPST switches 3000 in a manner such that signals propagate through the microstrip line of the single DGS LPF 4510 whenever signals are allowed to propagate between a port in the first set of ports (PORT1-PORTn) and the antenna port ANT 4504 through any one of the SPST switches 3000.

### Example Implementation of the SPMT Switch 4500 as a SPDT Switch

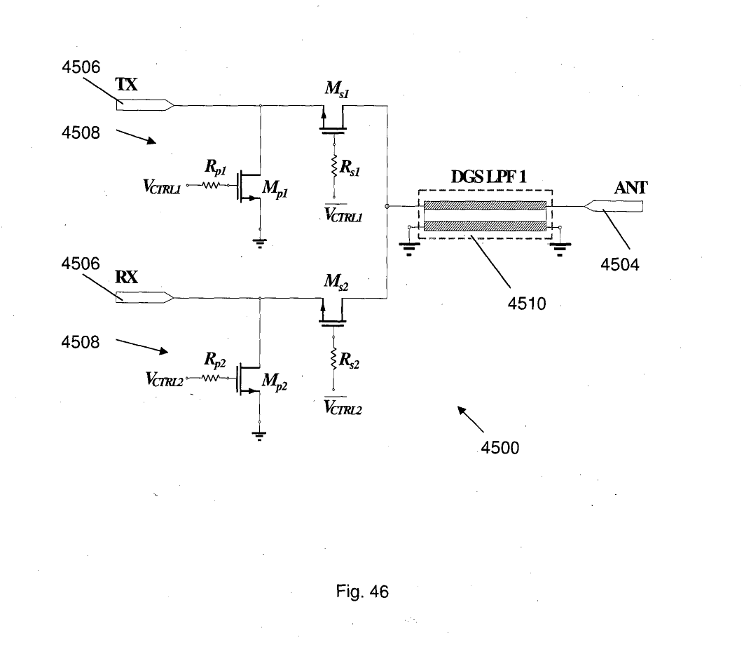

FIG. 46 shows an example implementation of the SPMT switch 4500 as a T/R switch in the form of a SPDT switch (i.e. n=2). The first set of ports in FIG. 46 comprises a transmitter port TX 4506 and a receiver port RX 4506, whereas the second set of ports in FIG. 46 comprises an antenna port ANT 4504.

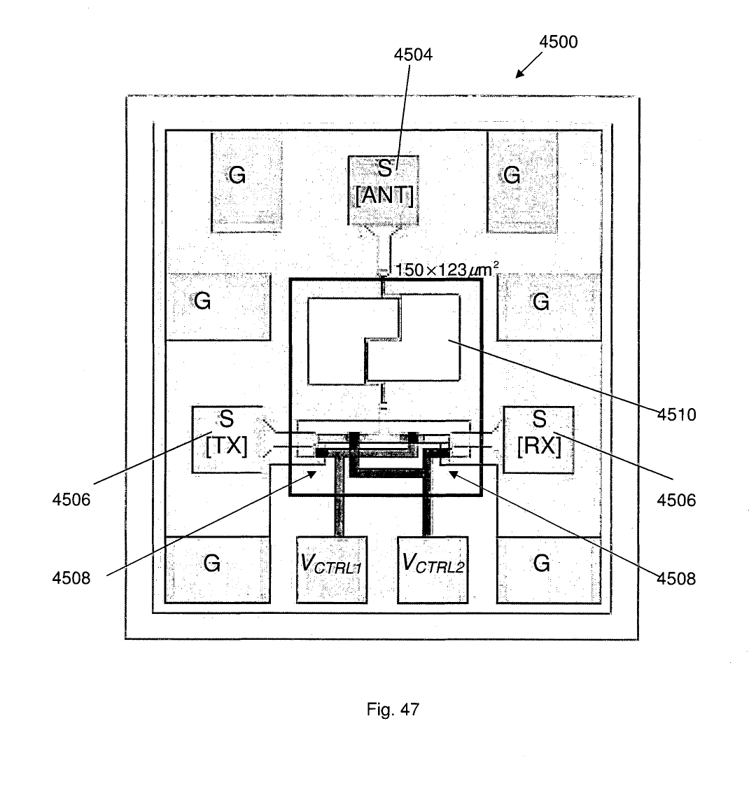

FIG. 47 shows an example layout implementation of the SPDT switch 4500 in FIG. 46. With this layout implementation, the SPDT switch 4500 has an active area of 150×123 μm² and a total chip area (inclusive of the input and output probe pads) of 370×330 μm².

### Example Implementation of the SPMT Switch 4500 as a SP4T Switch

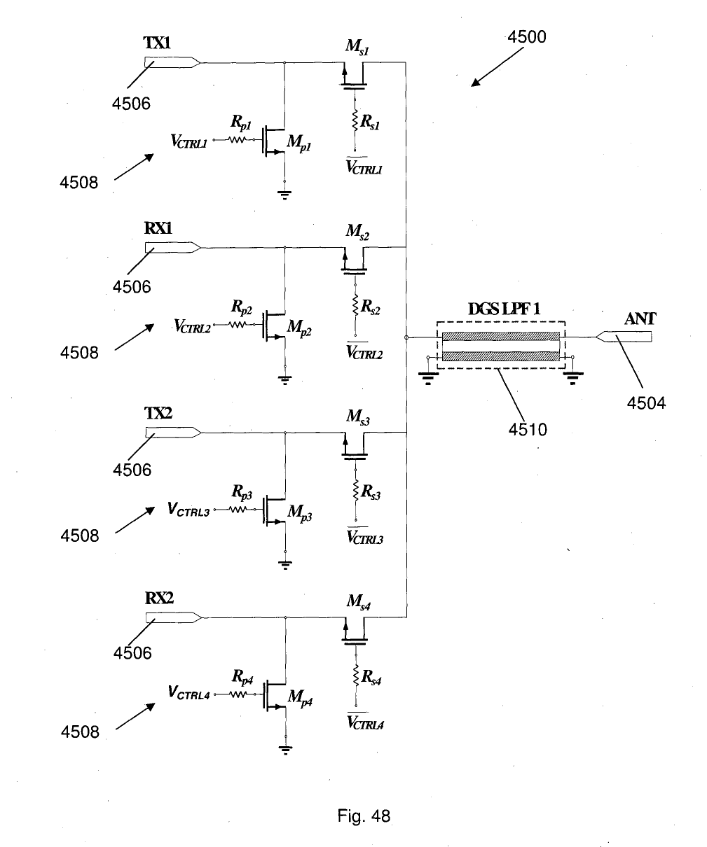

FIG. 48 shows an example implementation of the SPMT switch 4500 as a T/R switch in the form of a SP4T switch (i.e. n=4). The first set of ports in FIG. 48 comprises two transmitter ports TX1, TX2 4506 and two receiver ports RX1, RX2 4506, whereas the second set of ports in FIG. 48 comprises an antenna port ANT 4504.

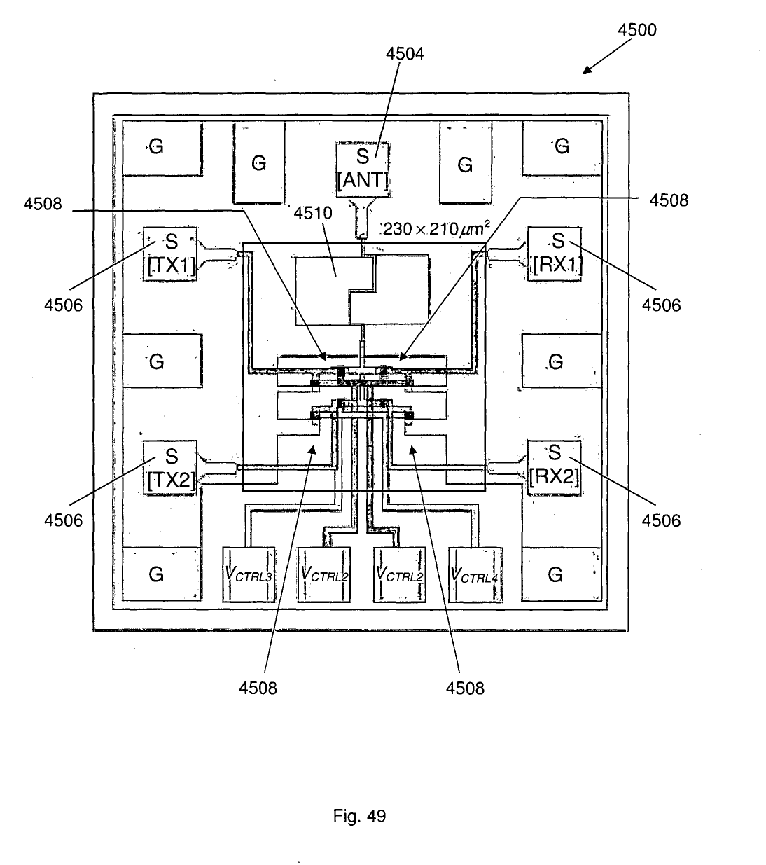

FIG. 49 shows an example layout implementation of the SP4T switch 4500 in FIG. 48. With this example layout implementation, the SP4T switch 4500 has an active area of 230×210 μm² and a total chip area (inclusive of the testing pads) of 475×460 μm².

### Example Implementation of the SPMT Switch 4500 as a SP8T Switch

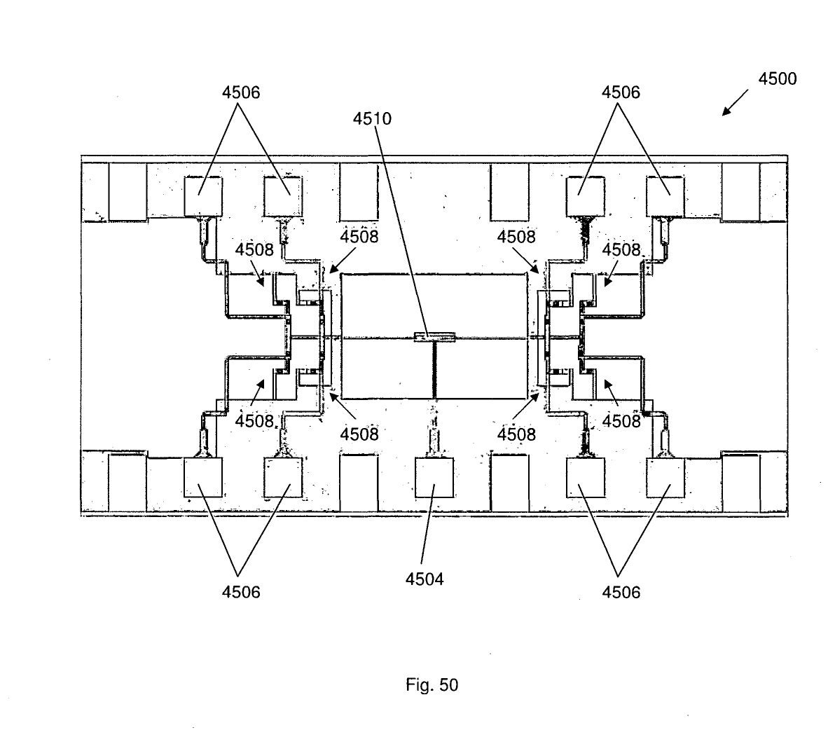

The SPMT switch 4500 can also be implemented as a T/R switch in the form of a SP8T switch (i.e. n=8). FIG. 50 shows an example layout implementation of such a SP8T switch 4500. With this example layout implementation, the SP8T switch 4500 has an active area of 421×162 μm² and a total chip area (inclusive of the testing pads) of 930×475 μm².

### Advantages of the Cascaded Multi-Throws Approach

Using the cascaded multi-throws approach to implement a SPMT switch has many advantages. This is elaborated below.

Firstly, a good matching at the antenna port ANT 4504 can be obtained by simply designing the single DGS LPF 4510 such that its output impedance is at a desired matching point e.g. the 50Ω matching point.

Secondly, using the cascaded multi-throws approach allows the SPMT switch 4500 to use only one DGS LPF 4510. This single DGS LPF 4510 is sufficient for compensating the parasitic capacitances from the shunt control transistors Mₛ₁-Mₛₙ in all the n branches. Therefore, the overall active area and total footprint of the SPMT switch 4500 is lower than the other SPMT switches as mentioned above (i.e. SPDT switches 3300-4000 and SP4T switches 4100-4400) which use multiple DGS LPFs.

Thirdly, using the cascaded multi-throws approach removes the need for coupling means (such as the T-junction 3302 or the 4-way power combiner 4102 used by the SPDT switches 3300-4000 and SP4T switches 4100, 4400 for coupling their SPST switches together). This is because the antenna port ANT 4504 can be directly connected to the DGS LPF 4510 as shown in FIG. 45. Therefore, the silicon area required to implement the SPMT switch 4500 can be reduced. This helps to reduce the overall active area and total footprint of the SPMT switch 4500 and in turn, lower the chip cost for the SPMT switch 4500.

Fourthly, in the SPMT switch 4500, the impedance seen by the ports in the first set of ports (PORT1-PORTn) 4506 can be tuned simultaneously by tuning characteristics (e.g. the sizes of the defect patches) of the single DGS LPF 4510. Thus, almost similar input return losses can be obtained at all the ports 4506. This greatly reduces the design effort for the SPMT switch 4500.

### Performance of the SPMT Switches

Simulation results are obtained for the SPDT switch 3800 in FIG. 38 and the SP4T switch 4100 in FIG. 41 to investigate the performance of these switches 3800, 4100. As mentioned above, the SPDT switch 3800 comprises two SPST switches 3000a, 3000b having the same structure as the SPST switch 3000 in FIG. 30 whereas the SP4T switch 4100 comprises four SPST switches 3000c, 3000d, 3000e, 3000f having the same structure as the SPST switch 3000 in FIG. 30.

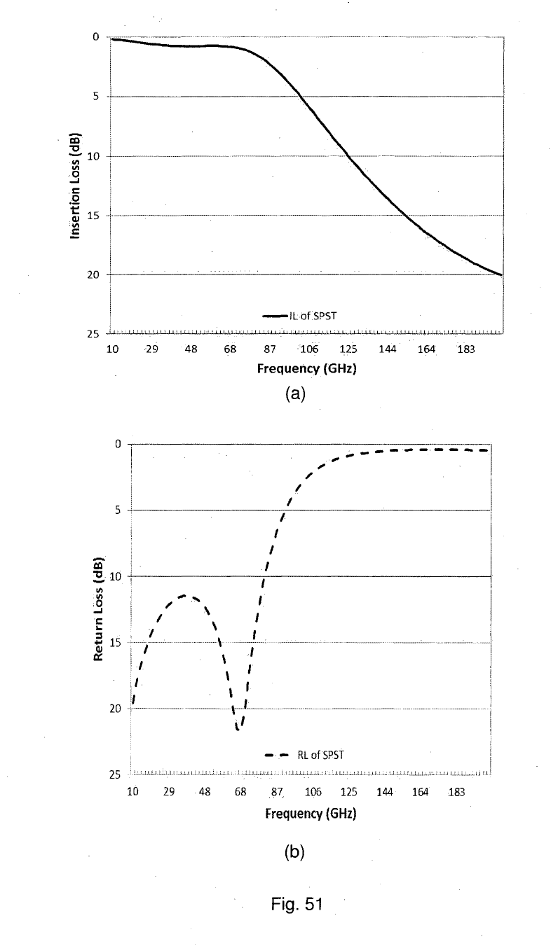

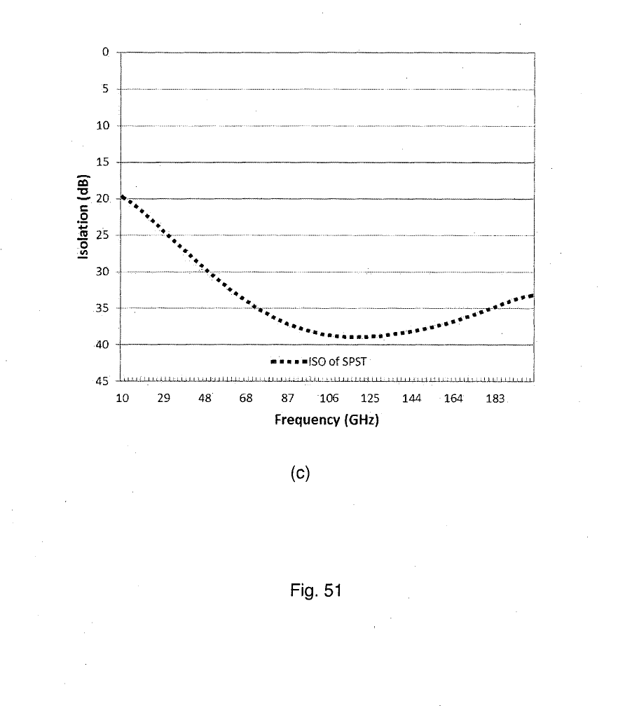

In the simulations, each of the SPST switches 3000a, 3000b, 3000c, 3000d, 3000e, 3000f in the SPDT switch 3800 and the SP4T switch 4100 is implemented using a SPST switch whose performance is shown in FIGS. 51(a)-(c). This SPST switch can be implemented with an overall active size of less than 112×96 μm². In particular, FIGS. 51(a)-(c) respectively show the insertion loss, return loss and isolation performance of this SPST switch. As shown in FIGS. 51(a)-(c), the SPST switch has an insertion loss of less than 1 dB, an isolation performance of larger than 20 dB and a return loss of larger than 11 dB in the frequency range from DC to millimeter-wave frequencies (specifically, to 72 GHz). The SPDT and SP4T switches 3800, 4100 are derived directly from the SPST switch with the performance shown in FIGS. 51(a)-(c) without any tuning or changes in the device's parameters.

### SPDT Switch 3800

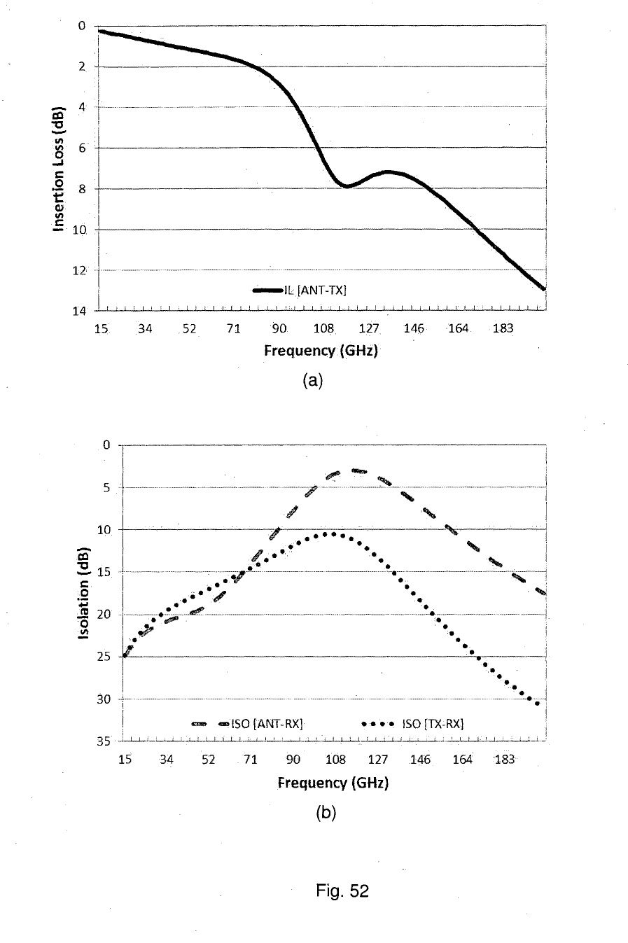

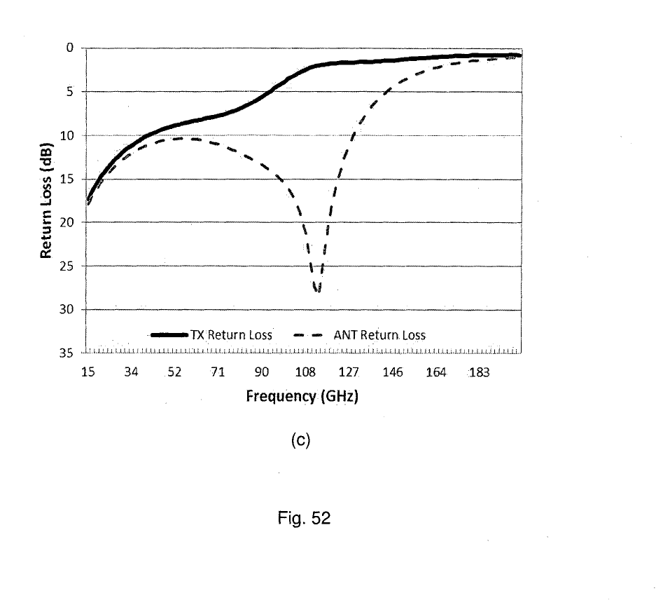

FIGS. 52(a)-(c) respectively shows simulation results illustrating the insertion loss performance (ANT-TX), the isolation performance (TX-RX and RX-TX), and the input and output return loss performance (TX return loss, ANT return loss) of the implemented SPDT switch 3800

As described above, the SPDT switch 3800 in FIG. 38 differs from the SPDT switch 3300 in FIG. 33 in that it uses SPST switches having the structure in FIG. 30 rather than the structure in FIG. 10. In other words, the control transistors M₂, M₄ closer to the antenna port ANT 3304′″ in the TX and RX branches of the SPDT switch 3800 are connected in series rather than in parallel. This allows the SPDT switch 3800 to have a better matching performance and isolation performance than the SPDT switch 3300. This is shown in FIGS. 52(a)-(c). In particular, at 60 GHz, the insertion loss of the SPDT switch 3800 is about 1.7 dB when the TX branch is turned on and the RX branch is turned off, the isolation performance of the SPDT switch 3800 between the TX and RX branches is about 15 dB (max), and the return loss of the SPDT switch 3800 is about 8.3 dB at the transmitter port TX 3306′″ or receiver port RX 3308′″ (TX return loss) and about 10.3 dB at the antenna port 3304′″ (ANT return loss).

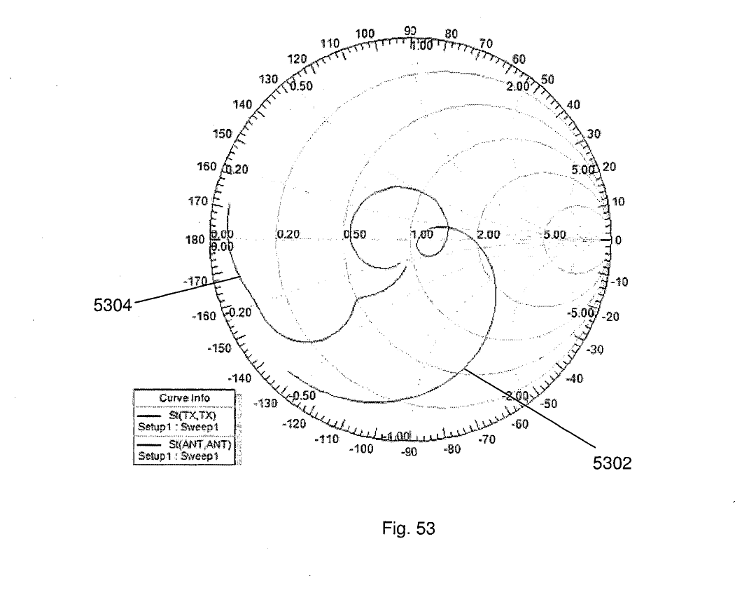

FIG. 53 shows the simulated characteristic impedance of the implemented SPDT switch 3800 as seen by the antenna port ANT 3304′″ (see curve 5302) and as seen by the transmitter port TX 3306′″ (see curve 5304).

As shown in FIG. 53 (specifically, by curve 5302), the impedance seen from the antenna port ANT 3304′″ of the SPDT switch 3800 is higher than the 50Ω matching point. This is because both the TX and RX branches of the SPDT switch 3800 comprise series control transistors M₂, M₄ near the antenna port ANT 3304′″ and the series equivalent impedance of these series control transistors M₂, M₄ contribute to the equivalent impedance seen from the antenna port ANT 3304′″.

Furthermore, the resultant characteristic impedance seen by the transmitter port TX 3306′″ is very capacitive. This is because the equivalent impedance seen from the antenna port ANT 3304′″ is translated to the transmitter port TX 3306′″ through the capacitances C_{ON}, C_{GDS} and the equivalent inductance L_{GDS} of the DGS LPF1. This translated antenna impedance to the transmitter port TX 3306′″ is then combined with the high capacitive loading of the shunt control transistor M₁ in the TX branch. To improve the matching condition at the transmitter port TX 3306′″, a transistor having lower parasitic capacitances can be used to implement the shunt control transistor M₁ of the TX branch. In particular, since the drain-to-source coupling capacitance (C_{ds}) is the major contributor of the parasitic capacitances in the control transistor M₁, the matching condition at the transmitter port TX 3306′″ can be improved by using a transistor with a larger drain-to-source distance as the shunt control transistor M₁ since such a transistor has a lower drain-to-source coupling capacitance C_{ds}.

### SP4T Switch 4100

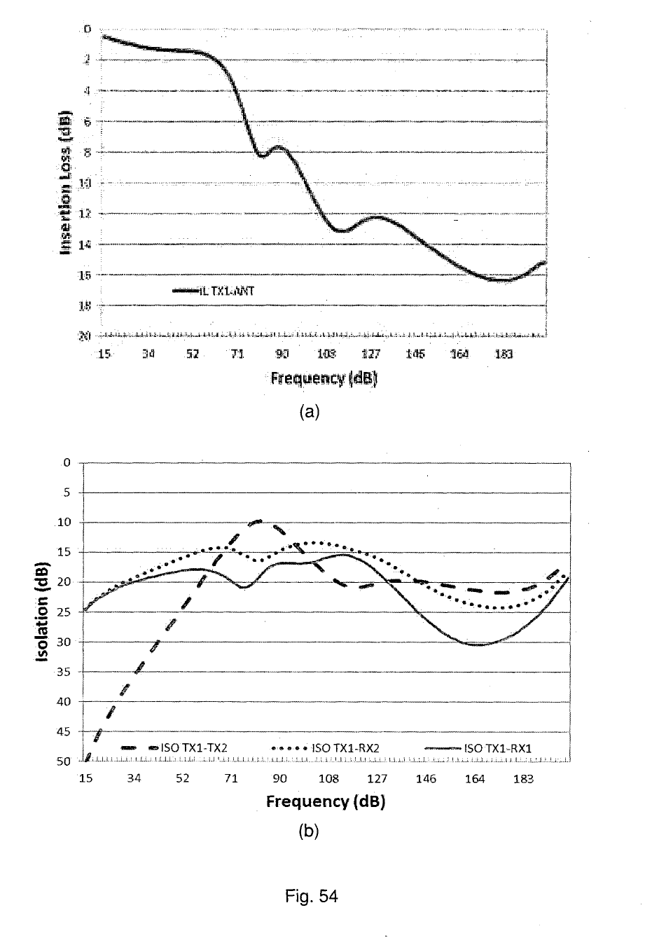

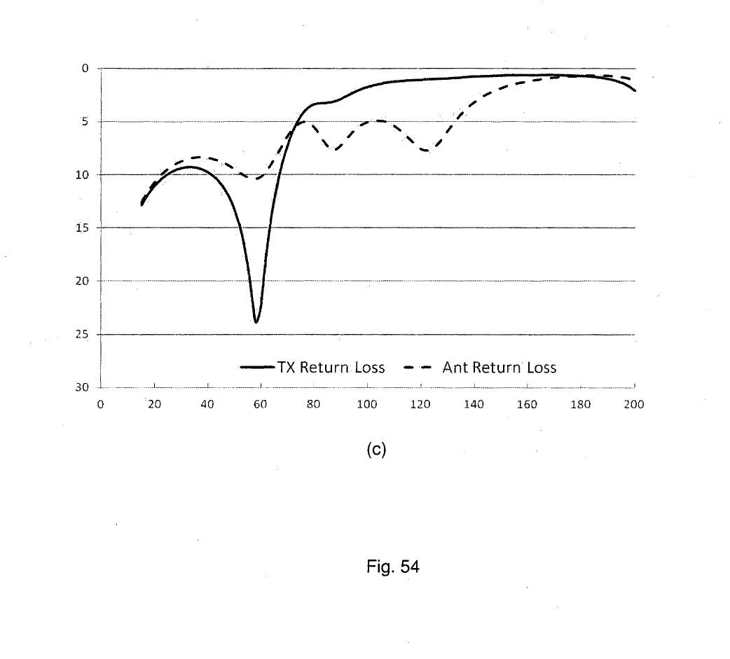

FIGS. 54(a)-(c) respectively shows the simulated insertion loss performance, isolation performance and return loss performance of the implemented SP4T switch 4100. This implemented SP4T switch 4100 has a total active area of less than 299×285 μm²

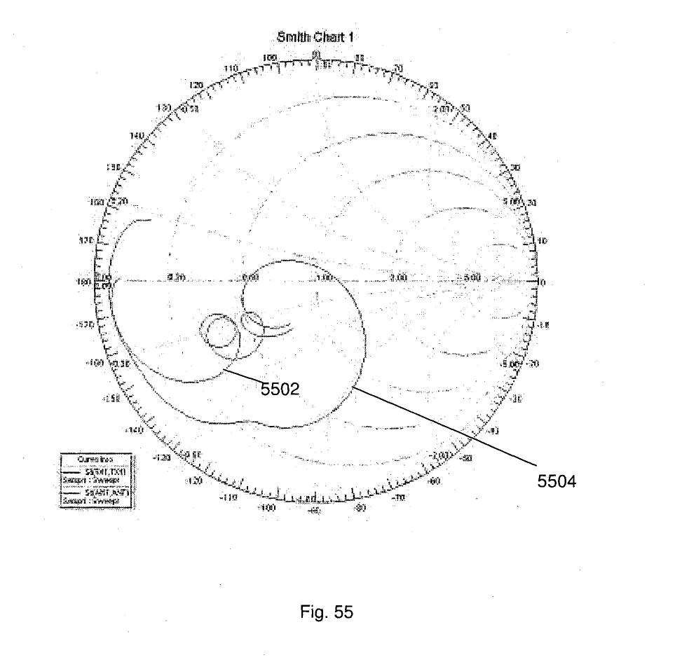

As shown in FIGS. 54(a)-(b), at 60 GHz, the insertion loss of the implemented SP4T switch 4100 is about 1.8 dB when the TX1 branch is enabled and the remaining branches are disabled, whereas the isolation performances of the SP4T switch 4100 are about 17.9 dB between the TX1 and RX1 branches (TX1-RX1), 14.7 dB between the TX1 and RX2 branches (TX1-RX2), and 19.7 dB between the TX1 and TX2 branches (TX1-TX2). Furthermore, as shown in FIG. 54(c), the return loss of the implemented SP4T switch 4100 at the transmitter port TX1 4106 (TX Return Loss) at 60 GHz is about 11 dB. This return loss performance is better than that of the implemented SPDT switch 3800 at the transmitter port TX 3306′″. As mentioned above, this superior return loss performance occurs because the impedance of (⅓)Z_{OFF} contributed by the non-active branches in the SP4T switch 4100, the off-capacitance C_{ON} of the control transistor in the active branch, the DGS LPF in the active branch and the equivalent parasitic capacitance C_{eq} of the control transistor in the active branch form a π-network. However, the return loss of the implemented SP4T switch 4100 calculated at the antenna port ANT 4104 (ANT Return Loss) at 60 GHz is worse than that of the implemented SPDT switch 3800 calculated at the antenna port ANT 3404′″. This is because of the poorer matching performance of the SP4T switch 4100 as mentioned above and as shown in the next figure i.e. FIG. 55.

In particular, FIG. 55 shows the simulated characteristic impedance of the implemented SP4T switch 4100 as seen by the antenna port ANT 4104 (see curve 5502) and as seen by the transmitter port TX 4106 (see curve 5504). As shown by the curve 5502, the characteristic impedance of the SP4T switch 4100 seen by the antenna port ANT 4104 is much lower than the 50Ω matching point. Therefore, the matching performance of the SP4T switch 4100 is poorer than that of the SPDT switch 3800. As explained earlier on, this poorer matcing performance is caused by the lower equivalent impedance of (⅓)Z_{OFF} of the parallel non-active branches in the SP4T switch 4100 when the SP4T switch 4100 is in operation.

### SPMT Switch 4500 Using the Cascaded Multi-Throws Approach

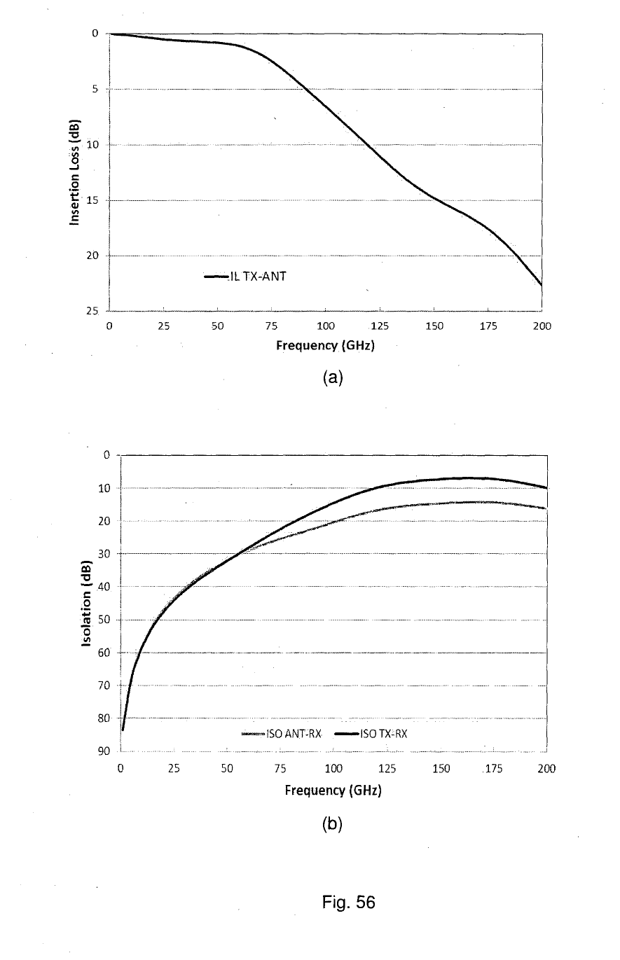

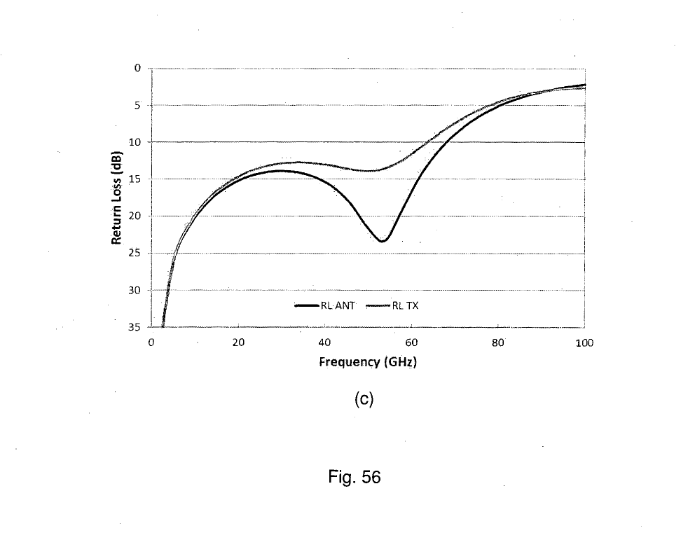

FIGS. 56(a)-(c) shows simulation results for the SPMT switch 4500 implemented as a SPDT switch 4500 as shown in FIG. 46. In particular, FIGS. 56(a)-(c) respectively shows the insertion loss (TX-ANT), the isolation performance (ANT-RX and TX-RX) and the return losses at the antenna port ANT 4504 (see “RL ANT” curve) and at the transmitter port TX 4506 (see RL TX” curve) of the SPDT switch 4500.

As shown in FIGS. 56(a)-(c), the performance of the SPDT switch 4500 using the cascaded multi-throws approach is generally as good as (if not, better) than that of the SPDT switch 3300 which uses more DGS LPFs and requires an additional T-junction 3302. In particular, the isolation performance of the implemented SPDT switch 4500 between the antenna port ANT 4504 and the RX branch is greater than 20 dB at frequencies up to 75 GHz. Furthermore, the return loss of the SPDT switch 4500 at the TX branch is about 13 dB.

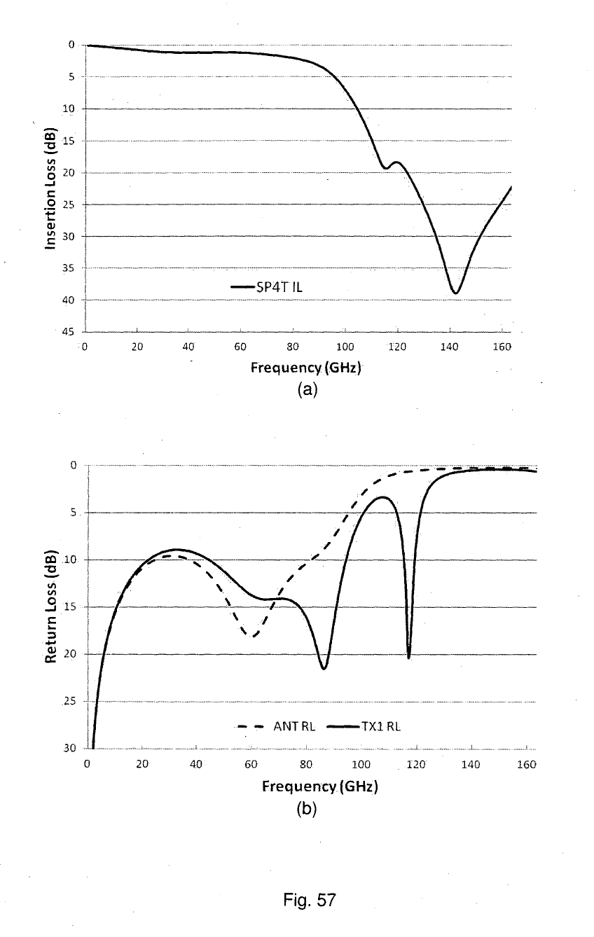

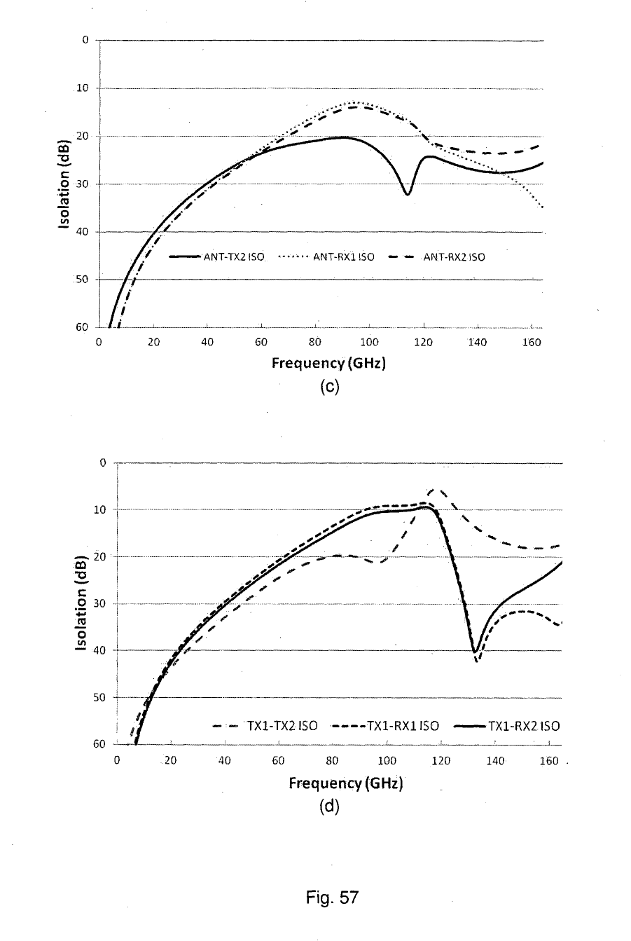

Simulation results are also obtained for the SPMT switch 4500 implemented as a SP4T switch 4500 as shown in FIG. 48. These results are shown in FIGS. 57(a)-(d). In particular, FIG. 57(a) shows the insertion loss performance of the switch 4500 whereas FIG. 57(b) shows the return loss performance of the switch 4500 at the antenna port ANT 4504 (ANT RL) and at the transmitter port TX 4506 (TX1 RL). FIG. 57(c) shows the antenna isolation performance of the switch 4500 including the isolation between the antenna and the TX2 branch (ANT-TX2), the isolation between the antenna and the RX1 branch (ANT-RX1) and the isolation between the antenna and the RX2 branch (ANT-RX2). FIG. 57(d) shows the TX1 isolation performance of the switch 4500 including the isolation between the TX1 and TX2 branches (TX1-TX2), the isolation between the TX1 and RX1 branches (TX1-RX1) and the isolation between the TX1 and RX2 branches (TX1-RX2).

As shown in FIGS. 57(a)-(d), the performance of the SP4T switch 4500 using the cascaded multi-throws approach is also generally as good as (if not, better) than that of the SP4T switch 4100 which uses more DGS LPFs and requires an additional 4-way power combiner 4102. For example, the isolation performance of the SP4T switch 4500 is also greater than 16 dB at frequencies up to 75 GHz.

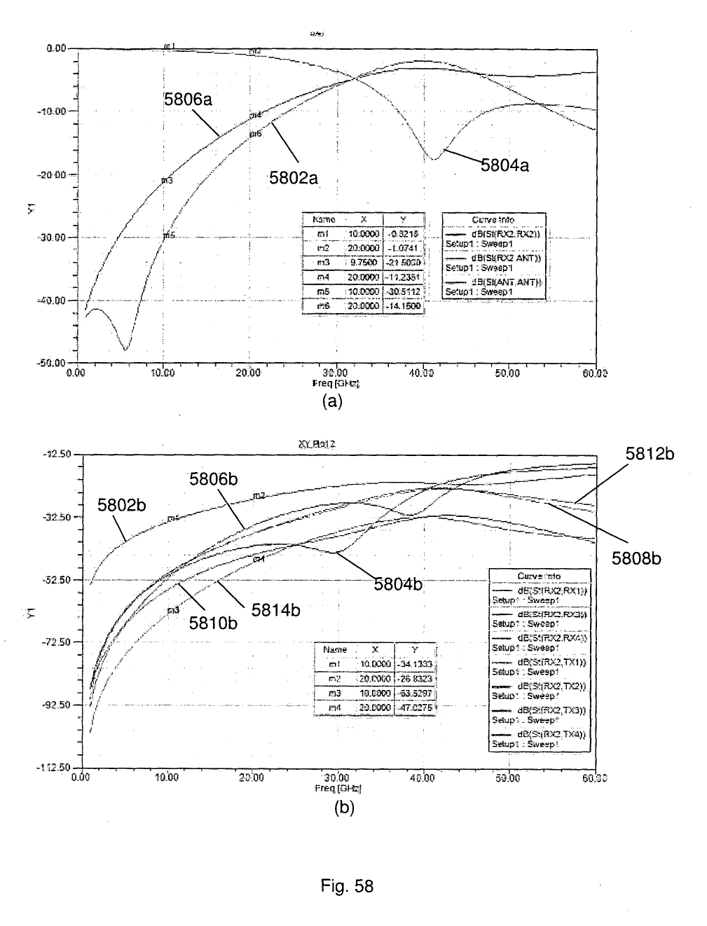

Similarly, simulation results are obtained for the SPMT switch 4500 implemented as a SP8T switch 4500 as shown in FIG. 50. These results show that the SP8T switch 4500 can attain an operating frequency of up to 20 GHz. Furthermore, FIG. 58(a) shows the insertion loss performance at the antenna port ANT 4504 and at the receiver port RX2 4506 of the SP8T switch 4500 when only the RX2 branch of the switch 4500 is turned on. In particular, the curves 5802a, 5804a, 5806a respectively represent the insertion loss at the receiver port RX2 4506 i.e. St(RX2, RX2), the insertion loss at the junction between the receiver port RX2 4506 and the antenna port ANT 4504 i.e. St(RX2, ANT) and the insertion loss at the antenna port ANT 4504 i.e. St(ANT, ANT). As shown in FIG. 58(a), St(RX2, ANT) is less than 1 dB at 10 GHz. FIG. 58(b) shows the isolation performances of the SP8T switch 4500, with the curves 5802b, 5804b, 5806b, 5808b, 5810b, 5812b, 5814b respectively representing the isolation between the receiver ports RX1, RX2 4506 i.e. St(RX2, RX1), the isolation between the receiver ports RX2, RX3 4506 i.e. St(RX2, RX3), the isolation between the receiver ports RX2, RX4 4506 i.e. St(RX2, RX4), the isolation between the receiver and transmitter ports RX1, TX1 4506 i.e. St(RX2, TX1), the isolation between the receiver and transmitter ports RX2, TX2 4506 i.e. St(RX2, TX2), the isolation between the receiver and transmitter ports RX2, TX3 4506 i.e. St(RX2, TX3), and the isolation between the receiver and transmitter ports RX2, TX4 4506 i.e. St(RX2, TX4). As shown in FIG. 58(b), the isolation performances range between 34 dB-63 dB at 10 GHz and between 26 dB-47 dB at 20 GHz.

### Variations to the Above-Mentioned Embodiments of the Present Invention

Although a few embodiments of the invention have been described in detail above, it is to be understood that many variations are possible within the scope of the invention, as defined by the claims. A few examples of such variations are given below.

In particular, the SPST switch 3000 in FIG. 30 can be configured to operate using two control signals V_{CTRL1}, V_{CTRL2} instead of a single control signal V_{CTRL}. For instance, the SPST switch 3000 can be configured such that its shunt control transistor M₁ is controlled by the control signal V_{CTRL1}, whereas its series control transistor M₂ is controlled by the other control signal V_{CTRL2}. In this case, when V_{CTRL1} is high, V_{CTRL2} has to be low and vice versa. Similarly, the SPDT switches 3300, 3600, 3700, 3800 in FIGS. 33, 36-38 can also be controlled by two or more control signals instead of a single control signal V_{CTRL}. Furthermore, in SPDT switches 3600 and 3700, isolating means other than the λ/4-wavelength transformer or the blocking capacitance may be used. For example, besides the λ/4-wavelength transformer, other components which can serve as high impedance nodes (ideally behaving like open circuits) may be used in the SPDT switch 3600.

Also, although the SPMT switch 4500 in FIG. 45 uses the SPST switch 3000 in FIG. 30 as its basis, the cascaded multi-throws approach can be used to implement SPMT switches using other SPST switches (for example, the SPST switch 1000 in FIG. 10, the SPST switch 3100 in FIG. 31 and/or the SPST switch 3200 in FIG. 32).

Furthermore, a DGS LPF with a different structure from the DGS LPF 1004 in FIG. 11 may be used for the embodiments of the present invention. FIG. 59 shows a DGS LPF 5900 with a basic structure (from which the structure of the DGS LPF 1004 is derived and from which other types of DGS LPF structures can be derived). As shown in FIG. 59, the DGS LPF 5900 comprises a microstrip line spaced apart from a ground plane, with the ground plane comprising defects. These defects are in the form of a dumb-bell shaped structure including two rectangular symmetrical defect patches (each with a dimension of a×b) which are separated by a space, and an elongate gap (of size of w×g) bridging the two rectangular defect patches across the space. Also, the microstrip line in the DGS LPF 5900 is straight and runs parallel to the space across the gap.

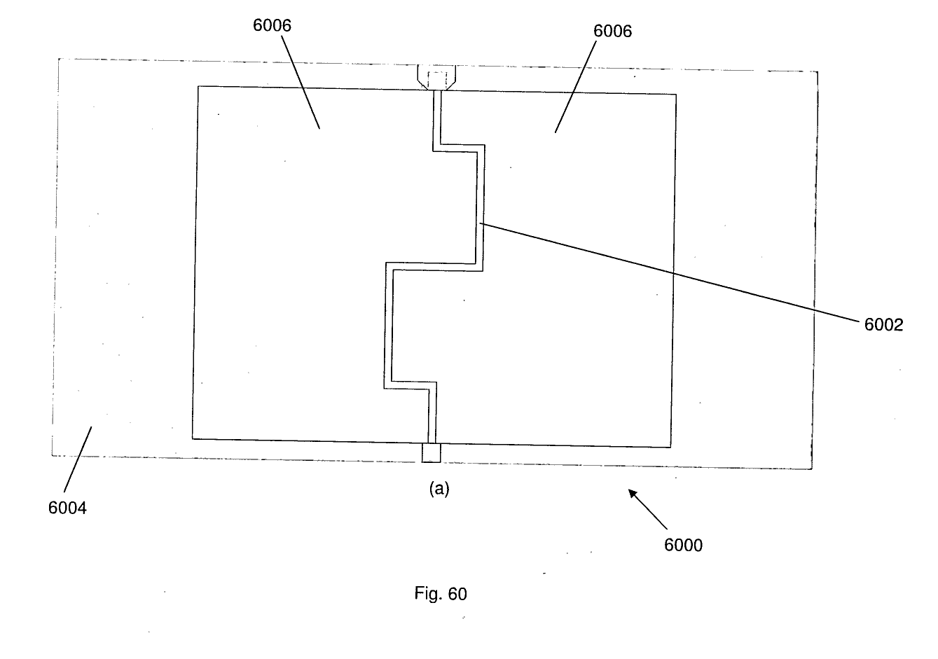

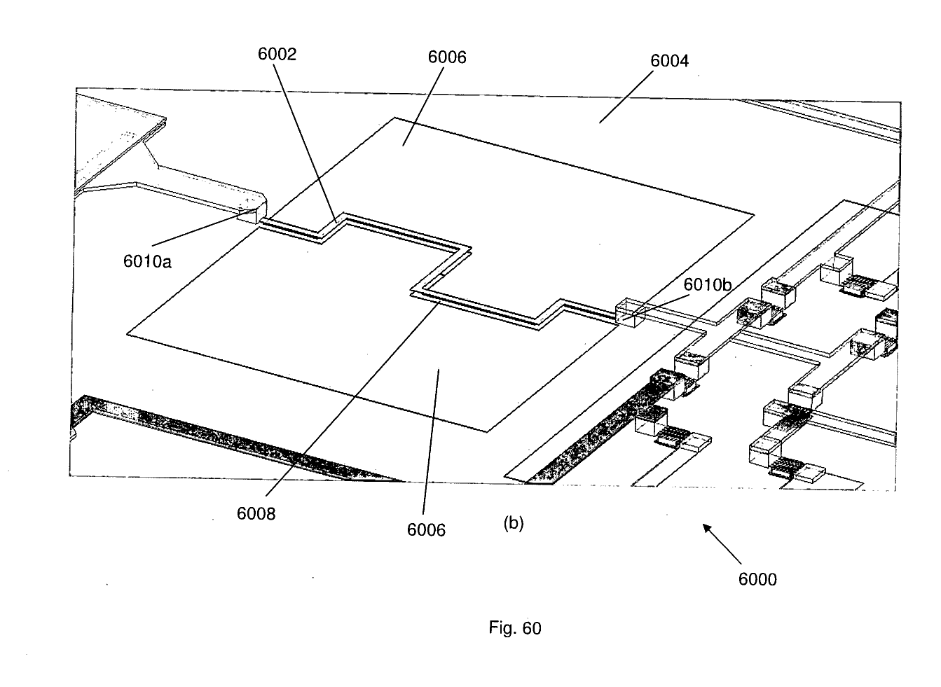

FIGS. 60(a)-(b) respectively show a plan view of a DGS LPF 6000 and a 3D view of the DGS LPF 6000 arranged with input and output ports 6010a, 6010b. The structure of the DGS LPF 6000 is derived from the basic structure in FIG. 59 and is similar to the structure of the DGS LPF 1004 in some ways. For example, the DGS LPF 6000 also comprises a microstrip line 6002 spaced apart from a ground plane 6004. The ground plane 6004 also comprises defect patches 6006 spaced apart from each other via a space 6008 and an elongate gap bridging the defect patches 6006 across the space 6008 (the gap is not visible in FIGS. 60(a)-(b)). The microstrip line 6002 in the DGS LPF 6000 is of the same shape as the microstrip line 1102 in the DGS LPF 1004 (more specifically, it comprises a s-shaped part too). However, the defect patches 6006 in the DGS LPF 6000 are not L-shaped. Instead, the defect patches 6006 are in a shape that has more protrusions and indentations such that the space 6008 comprises more bends than the space 1108 in the DGS LPF 1004. More specifically, the space 6008 has four parallel elongate portions, spaced pairwise apart by three further elongate portions which are parallel to each other and transverse to the four parallel elongate portions. These portions of the space 6008 are parallel to corresponding portions of the microstrip line 6002 and spaced therefrom in the vertical direction. In other words, the microstrip line 6002 runs parallel and adjacent to the space 6008.

Note that it is good to use a DGS LPF (such as the DGS LPF 1004 in FIG. 11) that is optimized for wideband operation as this can achieve switches with better insertion loss and matching performance. Such a DGS LPF is preferable over DGS LPFs which are optimized for good insertion loss but have steep skirt attenuation.

Also, note that the resonance characteristics of a DGS LPF depend on the shapes and sizes of the defect patches in the ground plane of the DGS LPF and how these defect patches are arranged. This is because the defect patches in the ground plane of a DGS LPF serve to disturb the current distribution pattern on the ground plane to create a distinctive inductive effect in the DGS LPF [19]. In particular, having the defect patches spaced apart from one another via one or more spaces (such as the space 1108) and arranging the microstrip line to run parallel and adjacent to at least part of the one or more spaces, spaced apart from the one or more spaces is advantageous as this allows charges to be accumulated at the one or more spaces which can in turn enhance the capacitance of the DGS LPF. This helps to lower the operating frequency of the DGS LPF (and hence, the switch). Arranging the microstrip line to run parallel and adjacent to at least part of the one or more spaces also helps to increase the equivalent inductance of the DGS LPF. Further, as mentioned above with reference to FIGS. 20(a) (b) and 21, having larger defect patches also helps to lower the operating frequency of the DGS LPF.

The shapes and sizes of the one or more spaces, the gap(s) connecting pair(s) of defect patches across the one or more spaces, and the microstrip line can also affect the resonance characteristics of the DGS LPF. This is elaborated below.

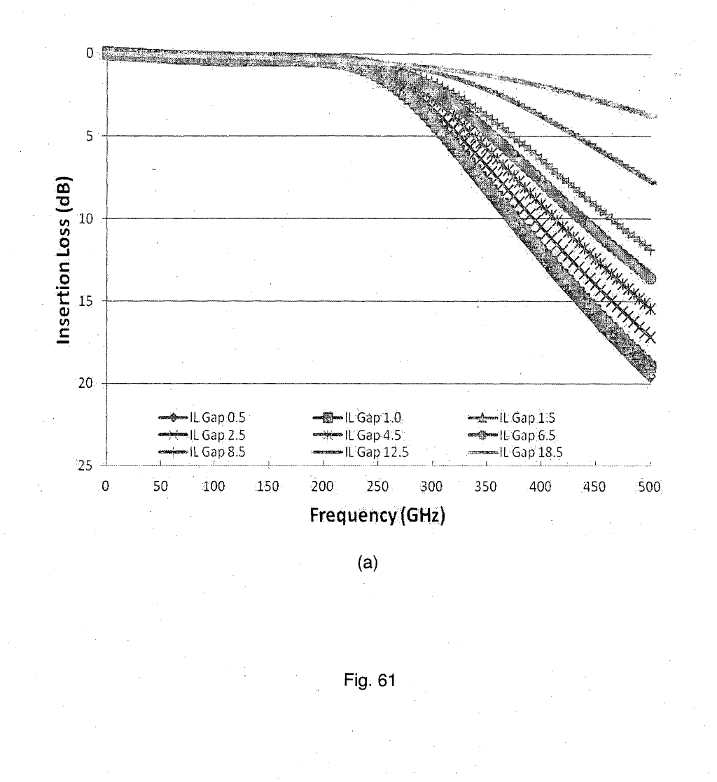

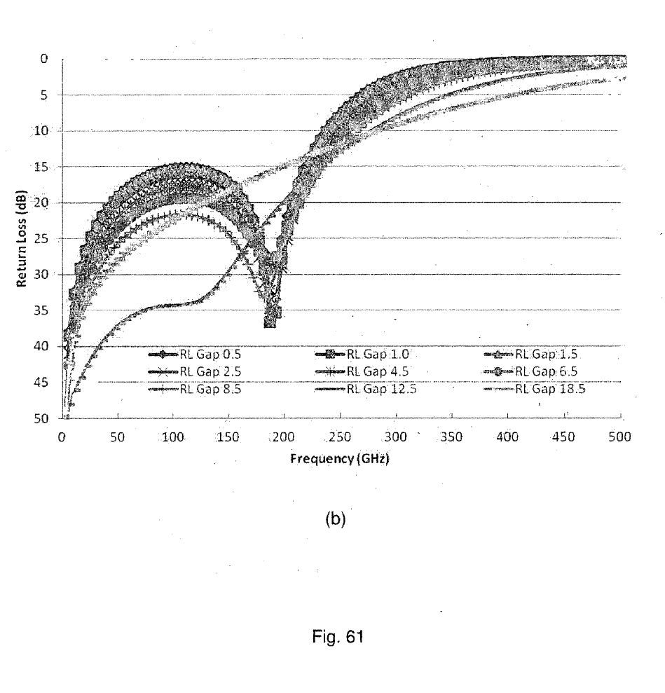

For example, FIGS. 61(a)-(b) respectively show how the insertion loss performance and the return loss performance of the DGS LPF 5900 change as a dimension (specifically, g) of the gap increases from 0.5 μm to 18.5 μm. As shown in FIG. 61(a), increasing g in turn increases the bandwidth and the skirt attenuation level of the DGS LPF 5900. This can affect the quality factor of the DGS LPF 5900. More specifically, the smaller the value of g, the higher the attainable quality factor of the DGS LPF 5900. As shown in FIG. 61(b), the height of the saddle in the return loss of the DGS LPF 5900 also depends on g. With a larger g, a lower saddle can be obtained and hence, a better return loss performance can be achieved. However, when g reaches the value of 18.5 μm, the saddle disappears and the return loss performance of the DGS LPF 5900 becomes similar to that of a standard line or wire. Thus, from FIGS. 61(a)-(b), it can be seen that the dimension g of the gap can influence parameters of the DGS LPF 5900, which can in turn influence the performance of the switch the DGS LPF 5900 is used in. Thus, a desired switch performance can be achieved by setting g accordingly. For example, g is set to be 0.2 μm in the example implementation of the switch 1000 described above and this achieves a relatively good return loss and insertion loss performance for the switch 1000.

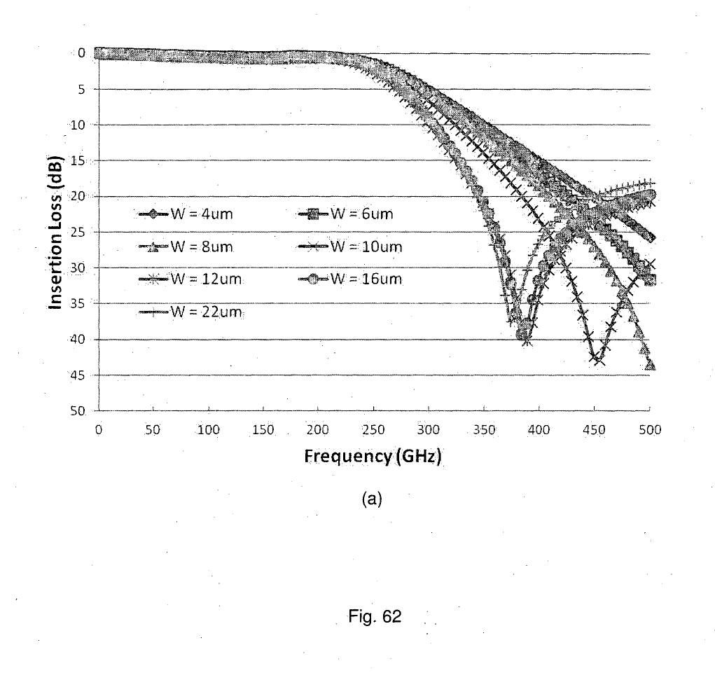

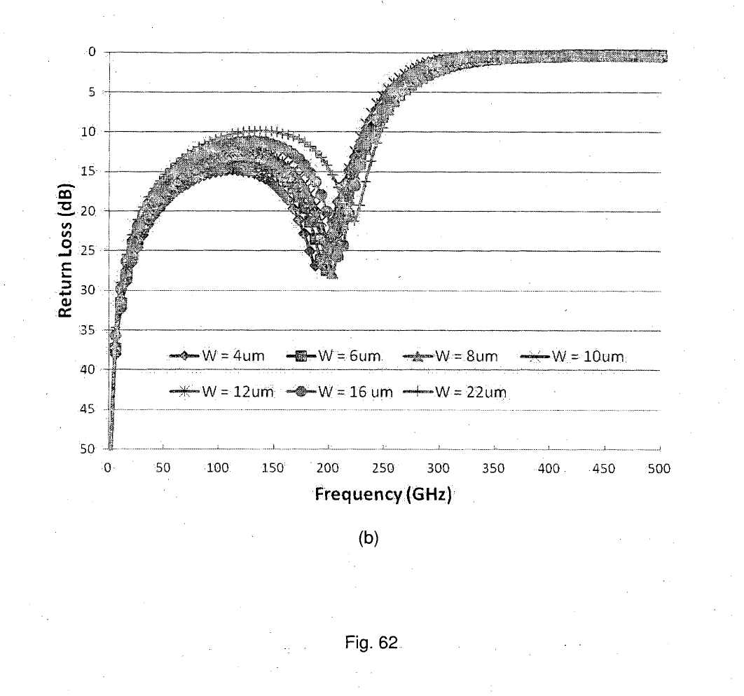

FIGS. 62(a)-(b) respectively show how the insertion loss performance and the return loss performance of the DGS LPF 5900 changes as another dimension (specifically, the width w of the gap) changes. From FIG. 62(a), it can be seen that the anti-resonance of the DGS LPF 5900 shifts in an opposite direction from the resonance of the DGS LPF 5900 as the width w of the gap increases. This makes the distance between the anti-resonance and the resonance smaller. This causes the skirt attenuation of the DGS LPF 5900 to get steeper. From FIG. 62(b), it can be seen that the poles of the DGS LPF 5900 shift to higher frequencies as the width w of the gap increases. Because of this, the saddle in the return loss of the DGS LPF 5900 gets higher and the return loss performance of the DGS LPF worsens. When implementing a switch using a DGS LPF, it is preferable for the distance between the resonance and anti-resonance of the DGS LPF to be as large as possible so as to achieve a better insertion loss and return loss performance. Therefore, it is good to set the width w of the gap as small as possible. For example, in the example implementation of the switch 1000 as described above, the width w of the gap connecting the defect patches 1106 is set as 2 μm which is relatively small and which is close to the limit of CMOS technology when a thin microstrip line of length greater than 10 μm is used. This value of w in the example implementation helps to achieve a good return loss and insertion loss performance for the switch 1000.

Also, using a microstrip line comprising bends along its length (such as the microstrip line 1102 with a s-shaped part) can significantly increase the length of the current return path in the ground plane. This can enhance the inductivity of the DGS LPF, and in turn lower the length of the microstrip line required to achieve the desired operating frequency for the DGS LPF (and hence, for the switch).

In fact, the DGS LPF in the switches in the embodiments can be replaced by any other type of structure as long as the structure has a transmission line and a ground plane, with the ground plane comprising defects configured and arranged with the transmission line so as to affect the inductance and/or capacitance of the transmission line when signals propagate through the transmission line. For example, it may be possible to use a ground plane that simply consists of the space 1108 in FIG. 11 and the gap across the space 1108 (i.e. the ground plane consists of two narrow strips of conductive material spaced apart from each other, with these two narrow strips having a similar structure to part of the microstrip line, arranged parallel to the microstrip line and spaced from the line in the vertical direction). However, it is not preferable to use such a ground plane as this can adversely impact the performance of the switch. This is because the current return path of the switch is dependent on the portions of the ground plane away from the space 1108. For example, if the narrow regions above and below the defect patches 1106 in the 2D view in FIG. 11(b) are removed, the current return path through these regions no longer exists and this significantly reduces the inductive effect in the DGS LPF 1004 (although, to obtain a larger inductivity in the DGS LPF 1004, it is good to minimize the width of these narrow regions).

Another example of how the above-mentioned embodiments can be varied is that the control mechanism in these embodiments can use other types of transistors instead of the MOSFETs mentioned above. In fact, the control mechanism in these embodiments need not use transistors and can use other types of devices that can perform similar functions as the MOSFETs mentioned above.

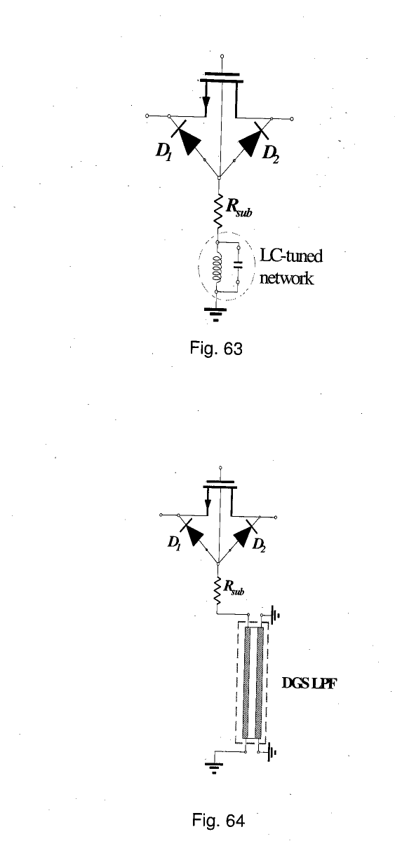

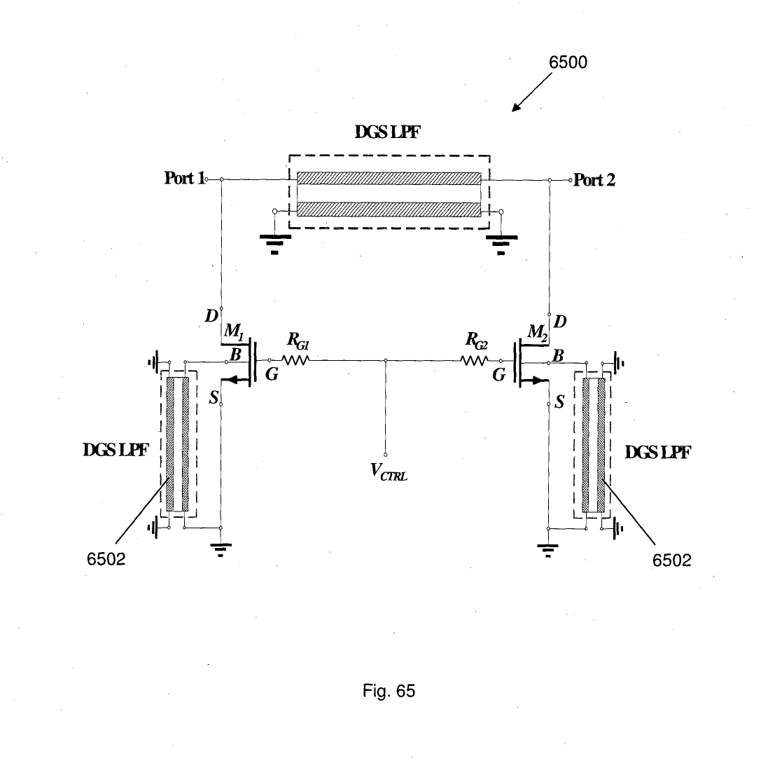

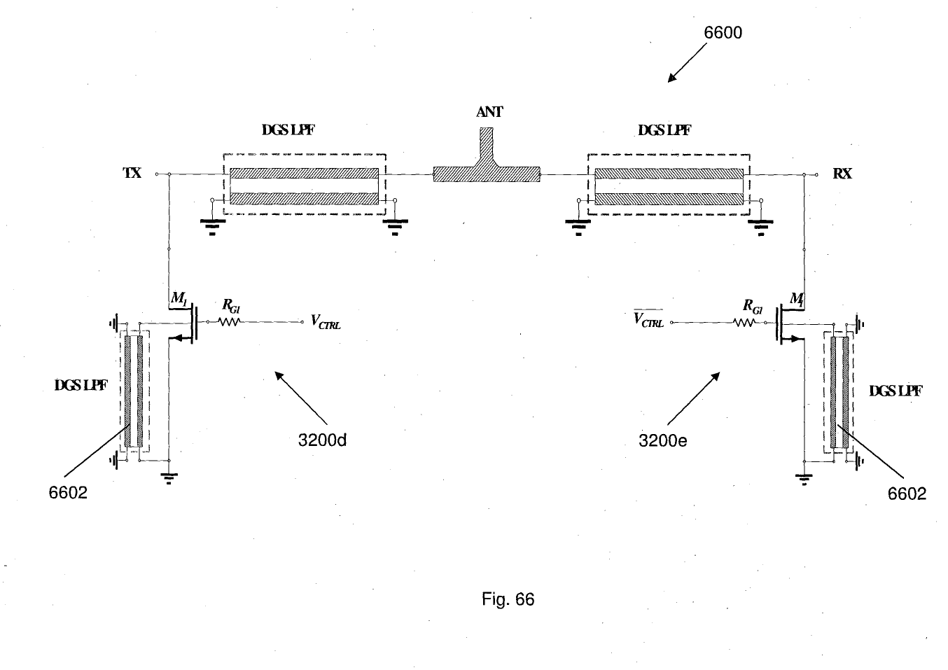

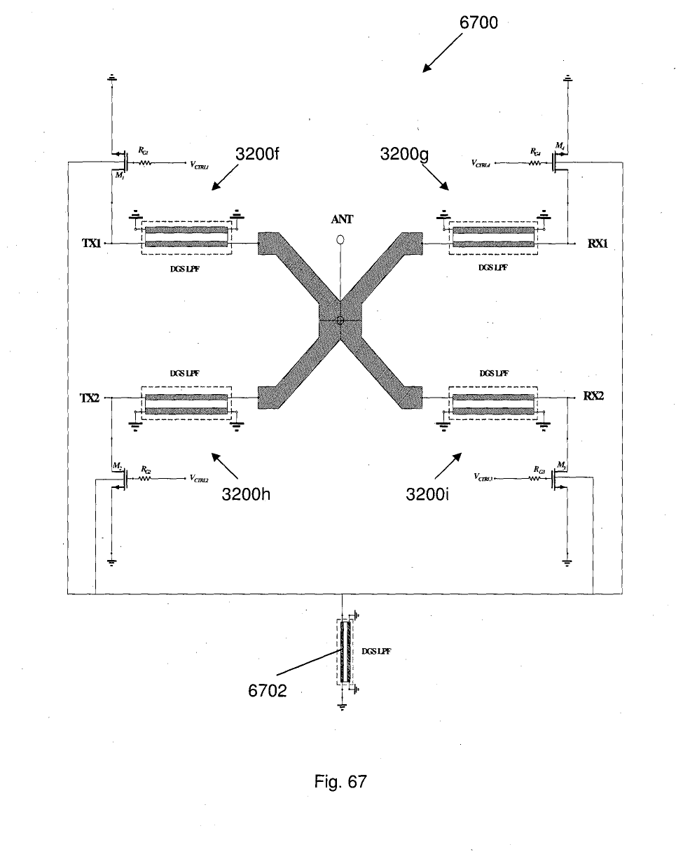

In addition, floating mechanisms may be included in the switches to float the bulks of the control transistors to improve the linearity of the switches. FIG. 63 shows an example of a floating mechanism. Specifically, FIG. 63 shows a NMOS transistor arranged with a LC network, wherein the LC network is connected between the bulk of the NMOS transistor and ground to float the bulk of the NMOS transistor [29]. Since a DGS LPF is equivalent to a LC network, the LC network in FIG. 63 may be replaced by a DGS LPF. This is shown in FIG. 64. As compared to LC networks, DGS LPFs are smaller in dimension and can be more easily implemented with standard CMOS technology. Thus, it is more cost effective to use DGS LPFs to implement the floating mechanisms in the switches. The problem of narrow bandwidth coverage caused by the use of LC networks can also be resolved with the use of DGS LPFs. This is because the bandwidths and skirt attentuations of the switches can be tuned by changing the characteristics of the defects in the DGS LPFs. FIGS. 65-67 show switches comprising floating mechanisms implemented using DGS LPFs. In particular, FIG. 65 shows a SPST switch 6500 having the same structure as the SPST switch 1000, except that it includes a floating mechanism comprising two DGS LPFs 6502 configured to float the bulks of the shunt control transistors M₁, M₂. FIG. 66 shows a SPDT switch 6600 comprising two SPST switches 3200d, 3200e each having the same structure as the SPST switch 3200 in FIG. 32, and a floating mechanism including two DGS LPFs 6602 configured to float the bulks of the control transistors M₁, M₂. Although the floating mechanism of both the SPST switch 6500 and the SPDT switch 6600 comprises two DGS LPFs, this is not necessary. Instead, a single DGS LPF may be used to float the bulks of a plurality of control transistors. An example of this is shown in FIG. 67. Specifically, FIG. 67 shows a SP4T switch 6700 comprising four SPST switches 3200f, 3200g, 3200h, 3200i having the same structure as the SPST switch 3200 in FIG. 32. The SP4T switch 6700 also comprises a floating mechanism which includes a single DGS LPF 6702 configured to float the bulks of all the control transistors M₁-M₄. Thus, as shown in FIGS. 65-67, the utility of DGS LPFs in switch implementation is not limited to tuning and improving the frequency responses of the switches. The DGS LPFs can also be used to improve the linearity of the switches.

Also, the switches in the above-mentioned embodiments can be used for implementing switches other than T/R switches. Furthermore, although only a few SPMT switches have been described above, the SPST switches 1000, 3000, 3100, 3200 can be used to implement further SPMT switches, MPST switches and MPMT switches similar to those described above. In particular, each of these switches may also serve to control signal propagation between first and second sets of ports, wherein each set of ports can comprise one or more ports. The SPST switches in each of these switches may be arranged so that the first and second contacts for each SPST switch is located for each SPST switch to control signal propagation between a port in the first set of ports and a port in the second set of ports. Furthermore, each of these SPMT switches, MPST and MPMT switches may use only one type of SPST switches (having the structure of the SPST switch 1000, 3000, 3100 or 3200), or may use two or more types of SPST switches.

The SPMT, MPST and MPMT switches implemented using SPST switches 1000 may also comprise isolating means (such as the λ/4-wavelength transformer in SPDT switch 3600 or the blocking capacitance in SPDT switch 3700) which serve to isolate the ports in the first set of ports from one another and/or isolate the ports in the second set of ports from one another.

To improve the matching performance of a SPMT, MPST or MPMT switch implemented using the SPST switches 1000, 3000, 3100, 3200, the impedance of each SPST switch when the SPST switch is turned off (i.e. the off-impedance of each SPST switch) may be adjusted in a manner similar to the suggested way of improving the matching performance of the SP4T switch 4100 as stated above. More specifically, the off-impedance of each SPST switch may be configured such that the impedance of the SPMT, MPST or MPMT switch matches the impedance of one or more other components in a circuit the SPMT, MPST or MPMT switch is to be used in.

### Advantages of the Embodiments of the Present Invention

The following describes some advantages of the embodiments of the present invention.

One advantage of the switches in the embodiments is that they have small active footprints. For example, both the SPST switches 1000, 3000 in FIGS. 10 and 30 can be implemented with an overall active footprint of less than 112×96 μm². Furthermore, a SPDT switch (e.g. SPDT switch 3800), a SP4T switch (e.g. SP4T switch 4100) and a SP8T switch derived from the SPST switch 3000 can be respectively implemented with an overall footprint of less than 285×88 μm², 285×299 μm² and 475×930 μm². With the cascaded multi-throws approach, the overall footprints of the switches can be even smaller. In particular, the SPDT switch, SP4T switch and SP8T switch implemented using the cascaded multi-throws approach as shown in FIGS. 46-50 has an overall active footprint of less than 150×123 μm², 230×210 μm² and 421×162 μm² respectively.

Furthermore, the general performance (including the insertion loss performance, the return loss performance, isolation performance, characteristic impedance etc.) of the switches in the embodiments is good as can be seen from the results presented above. The switches in the embodiments also have very wide operating bandwidths (from DC-Millimetre wave frequencies). Thus, these switches can be used for many applications such as applications in mobile phones, automotive-related products (e.g. GPS and key fobs), consumer electronics (e.g. digital TV) and industrial applications in the Industrial Scientific and Medical (ISM) radio bands.

The above advantages of the switches in the embodiments are achieved at least in part due to the use of the DGS LPF.

In particular, using the DGS LPF (instead of an inductor or a transmission line) in a SPST switch for compensating the parasitic capacitances of the control transistors is advantageous because the DGS LPF has a compact structure. Moreover, due to its planar structure, the DGS LPF can be fabricated using standard CMOS processes via simple fabrication processes which are compatible with multi-layer metallization CMOS processes. Thus, using the DGS LPF in a SPST switch can reduce the required footprint for the switch and can in turn increase the number of chips per wafer and decrease the chip cost for the switch.

Furthermore, using a DGS LPF in a SPST switch helps to lower the operating frequency of the switch. In particular, the DGS LPF is a Low Pass Filter (LPF) with a microstrip line through which signals can pass through and with defects introduced into its ground plane. This introduction of defects creates a pole of attenuation at a certain frequency and in turn improves the stop band or attenuation performance of the LPF [19], [20]. This is because the defects disturb the flow of the ground current and hence, the current distribution on the ground plane. This disturbance enhances the equivalent capacitance and the inductance of the microstrip line in the LPF, hence increasing the equivalent capacitance and inductance of the LPF. The presence of defects also increases the current route path in the microstrip line of the LPF and this further increases the equivalent inductance of the LPF. If the defects in the ground plane comprise defect patches spaced apart via a space (such as the space 1108), the equivalent capacitance of the LPF is further enhanced. The above-mentioned enhancement in the equivalent inductance and capacitance of the LPF shift the equivalent series and parallel resonances of the LPF, thereby lowering the 3-dB frequency (f_{3dB}) of the LPF. Therefore, the operating frequency of a SPST switch using a DGS LPF can be lower.

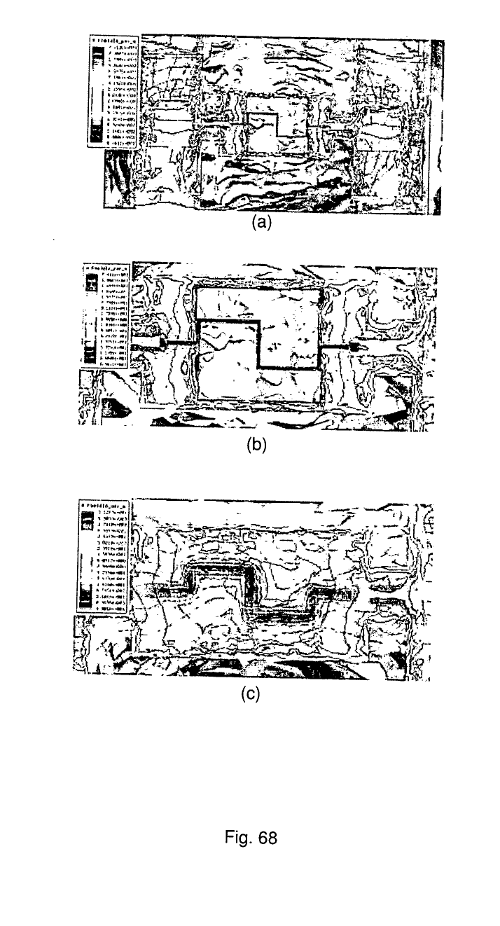

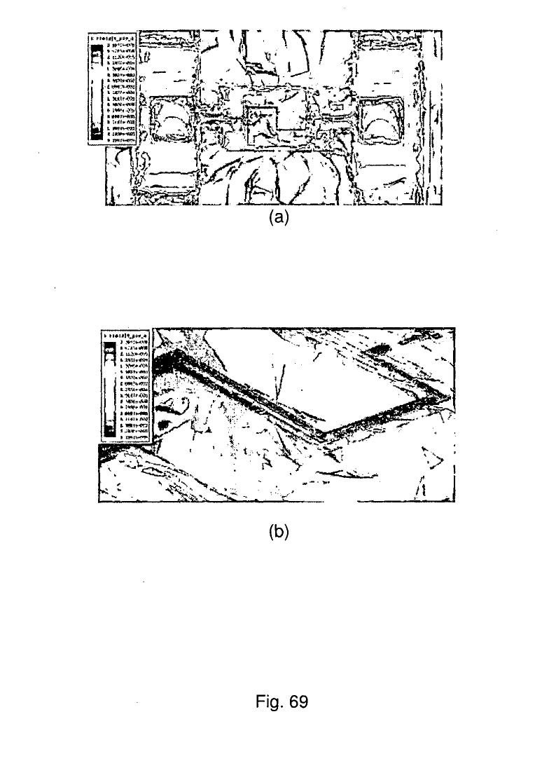

The enhancement of the inductance and capacitance of the LPF due to the defects introduced into its ground plane is illustrated by FIGS. 68(a)-(c) and FIGS. 69(a)-(b) as follows.

In particular, FIG. 68(a) shows a simulated magnetic field (H-field) distribution across the switch 1000 in the above-mentioned implementation at 60 GHz, whereas FIG. 68(b) shows a magnified version of the H-field distribution in FIG. 68(a) across the DGS LPF 1004. As shown in FIGS. 68(a) and (b), there is a large H-field concentration in the thin microstrip line 1102 of the switch 1000. More specifically, the peak H-field in the microstrip line 1102 reaches a value of 7.4×10³ A/m. This creates a large inductive effect in the DGS LPF 1004. Furthermore, the H-field is concentrated at the outer edge of the DGS LPF 1004 and also in the thin space 1108 under the microstrip line 1102. This shows that the presence of the defect patches 1106 and the space 1108 can increase the length of the current return path (this in turn further enhances the inductive effect of the DGS LPF 1004). These inductive effects in the DGS LPF 1004 help to compensate the parasitic capacitances of the control transistors in the SPST switch 1000 and are represented by the equivalent inductance L_{GDS} in the DGS LPF model as shown in FIG. 13. On the other hand, FIG. 68(c) shows a simulated H-field distribution across a switch having the same structure as the switch 1000 but without the defect patches 1106, the gap and the space 1108 (i.e. with a standard ground structure without defects). As shown in FIG. 59(c), without the defect patches 1106, the H-field in the switch is less concentrated. More specifically, instead of concentrating along the microstrip line 1102, the H-field gradually spreads. The ground current under the microstrip line 1102 is also less dense when defect patches 1106 are not present. Therefore, the inductive effect in this switch with a standard ground plane is lower.

FIG. 69(a) shows a simulated E-field distribution across the entire switch 1000 in the above-mentioned example implementation whereas FIG. 69(b) shows a magnified view of the E-field distribution in FIG. 69(a) across the DGS LPF 1004. The peak E-field in the switch 1000 is 3.4×10⁶ V/m and as shown in FIG. 69(b), is observed at the space 1108. This huge concentration of the E-field at the space 1108 introduces a large capacitive effect in the DGS LPF. This capacitive effect is represented by the equivalent capacitance C_{GDS} in the DGS LPF model as shown in FIG. 13.

Since using a DGS LPF in a SPST switch can lower the operating frequency of the switch, a shorter microstrip line can be used in the switch. This helps to reduce the footprint of the SPST switch. In particular, the microstrip line in the DGS LPF can be set to operate at a higher frequency (and thus, can have a shorter length) since this higher frequency can be reduced to the desired lower operating frequency of the SPST switch via the defects in the DGS LPF. For example, in the above-mentioned example implementation of the SPST switch 1000, a microstrip line 1102 operating at 450 GHz is used and the operating frequency of the SPST switch 1000 is shifted from 450 GHz to 60 GHz via the defect patches 1106 in the DGS LPF 1004.

Moreover, using the DGS LPF to implement a SPST switch increases the flexibility and effectiveness in tuning different characteristics of the SPST switch. This is elaborated below.

In particular, using the DGS LPF in a SPST switch provides additional parameters to tune the operating frequency of the switch. More specifically, the dimension and/or arrangement of the defects in the DGS LPF can be adjusted to tune the pole of attenuation created due to the defects. This allows the tuning of the equivalent inductance and capacitance of the DGS LPF and in turn, allows the tuning of the operating frequency of the SPST switch.

The ability to change the poles and zeros of the DGS LPF by adjusting the dimension of the defects also allows tuning of the insertion loss, return loss and isolation performance of the SPST switch.

Moreover, since the inductance of the DGS LPF affects the characteristic impedance of the SPST switch, the characteristic impedance of the SPST switch can also be tuned by adjusting the dimension of the defects in the ground plane of the DGS LPF. In other words, the DGS LPF provides the SPST switch with a self-matching capability. This makes connecting the SPST switch to other switches, components and/or ports easier as the need for additional matching networks can be eliminated.

The compensation of the parasitic capacitances from the control transistors can also be adjusted by changing the dimension of the defects in the DGS LPF to change the inductivity of the DGS LPF. This is advantageous because if increased inductivity of the DGS LPF is required due to the use of control transistors with higher parasitic capacitances, the adjustment of the dimension of the defects to achieve this increased inductivity does not require additional footprint. In other words, the increased inductivity can be achieved without increasing the number of chips per wafer and the chip cost for the switch. On the other hand, to increase the inductance of inductors used in prior art inductor-based SPST switches so as to compensate larger parasitic capacitances from the control transistors, the sizes of the inductors have to be increased and this requires additional footprint. Similarly, to increase the inductance of transmission lines in prior art transmission-line-based switches so as to compensate larger parasitic capacitances from the control transistors, longer and thinner transmission lines have to be used and this also requires additional footprint.

Besides the dimension of the defects, the frequency response of the DGS LPF (and hence, the switch the DGS LPG is used in) can also be tuned using other parameters such as the dimensions of the gap (w and g).

The above-mentioned advantages of a SPST switch using a DGS LPF also extend to SPMT, MPST, MPMT switches implemented using such a SPST switch. In addition, using the DGS LPF allows the implementation of SPMT, MPST and MPMT switches via the cascaded multi-throws approach as shown in FIGS. 45-50. As mentioned above, this approach can reduce the active area required to implement each switch, and hence reduce the silicon area and total footprint of the switch. This in turn lowers the chip cost for the switch. The design effort required for a SPMT, MPST or MPMT switch using the cascaded multi-throws approach is also lower.

### REFERENCES

[1] S. Geng and P. Vainikainen, “Millimeter-Wave Propagation in Indoor Corridors”, IEEE Antennas and Wireless Propagation Letters, Vol. 8, 2009
[2] S. Singh, F. Ziliotto, U. Madhow, E. M. Belding, and Rodwell, “Blockage and Directivity in 60 GHz Wireless Personal Area Networks: From Cross-Layer Model to Multi-hop MAC Design”, IEEE Journal on selected areas in communication, Vol. 27, no. 8, October 2009
[3] A. A. Kidwai, C.-T. Fu, J. C. Jensen, and S. S. Taylor, “A fully integrated ultra low loss insertion loss T/R switch for 802.11b/g/n application in 90 nm CMOS process”, IEEE J. Solid-State Circuits, Vol. 44, no. 5, pp. 1352-1360, May 2009
[4] F. J. Huang and K. O, “A 0.5 μm CMOS T/R switch for 900-MHz wireless applications”, IEEE J. Solid-State Circuits, Vol. 36, no. 3, pp. 486-492, March 2001
[5] R. H. Caverly and J. J. Manosca, “Transient switching behavior in Silicon MOSFET RF switches”, IEEE Topical Meeting Silicon Monolithic Integrated Circuits RF Systems (SiRF), January 2008, pp. 179-182
[6] Y. P. Zhang, Q. Li, W. Fan, C. H. Ang, and H Li, “A differential CMOS T/R switch for multi-standard applications”, IEEE Trans. Circuits Syst. IIL Express Briefs, vol. 53, no 8, pp. 782-786, August 2006
[7] Q. Li and Y. P. Zhang, “CMOS T/R switch design: toward ultra-wideband and higher frequency”, IEEE J. Solid-State Circuits, Vol. 42, no. 3, pp. 563-570, March 2007
[8] Z. Li and K. K. O, “15-GHz fully integrated NMOS switches in a 0.13 μm CMOS process”, IEEE J. Solid-State Circuits, Vol. 40, no. 11, pp. 2323-2338, November 2005
[9] Y. Kin and C. Nguyen, “Ultra-compact high linearity high power fully integrated DC-20-GHz 0.18 μm CMOS T/R switch”, IEEE Trans. Microw. Theory Tech., Vol. 55, no. 1, pp. 30-36, January 2007
[10] R. H. Caverly, “Linear and nonlinear characteristic of the silicon CMOS monolithic 50 Ohm microwave and RF control element”, IEEE J. Solid-State Circuit, Vol. 34, no. 1, pp. 124-126, January 1999
[11] M. Madihian, L. Desclos, T. Drenski, Y Kinoshita, H. Fujii, and T. Yamazaki, “CMOS RF ICs for 900 MHz-2.4 GHz band wireless communication networks”, IEEE Radio Frequency Integrated Circuit (RFIC) Symp., June 1999, pp. 13-16
[12] Q. Li, Y. P. Zhang, K. S. Yeo and W. M. Lim, “16.6- and 28-Ghz fully integrated CMOS RF Switches with improved body floating”, IEEE Trans Microw. Theory Tech., Vol. 56, no. 2, pp. 339-345, February 2008
[13] P. Sun, P. Upadhyaya, D-H. Jeong, D. Heo and G. S. L. Rue, “A Novel SiGe PIN Diode SPST Switch for Broadband T/R Module”, IEEE Microwave and Wireless Components Letters, Vol. 17, no. 5, May 2007
[14] P. Sun, P. Liu, P. Upadhyaya, D. H. Jeong, D. Heo and E. Minal, “Silicon-based PIN SPST RF Switches for Improved Linearity”, Microwave Symposium Digest, pp. 948-951, May 2010
[15] P. Park, D. H. Shin, and C. P. Yue, “High-linearity CMOS T/R switch design above 20 GHz using asymmetrical topology and AC-floating bias”, IEEE Trans. Microw. Theory Tech., Vol. 57, no. 4, pp 948-956, April 2009
[16] J. J. Lee, D. Y. Jung, K. C. Eun, I. Y. Oh and C. S. Park, “A low power CMOS single-chip receiver and system-on package for 60 GHz mobile applications”, 2009 IEEE International Symposium on Radio-Frequency Integration Technology
[17] Jin He, Y. P. Zhang, Y-Z Xiong, “A 60 GHz Single-Pole-Single-Throw Switch in 65-nm Bulk CMOS”, International Journal of RF and Microwave Computer-Aided Engineering, Vol. 21-issue 2, pp. 190-198, March 2011
[18] J. He, Y. P. Zhang, “Design of SPST/SPDT switches in 65-nm CMOS for 60-GHz applications”, Proc. Asia Pacific Microw Conf., 16-19 Dec. 2008, Hong Kong, China
[19] A. Tomkins, P. Garcia, and S. P. Voinigescu, “94 GHz SPST Switch in 65 nm Bulk CMOS”, Compound Semiconductor Integrated Circuits Symposium, pp. 1-4, October 2008
[20] R-B. Lai, J-J. Kuo, and H. Wang, “A 60-110 GHz Transmission-Line Integrated SPDT Switch in 90 nm CMOS Technology”, IEEE Microwave and Wireless Components Letters, Vol. 20, no. 2, February 2010
[21] M. Uzunkol, and G. M. Rebeiz, “A Low-Loss 50-70 GHz SPDT Switch in 90 nm CMOS”, IEEE Journal of Solid-State Circuit, Vol. 45, no. 10, October 2010
[22] K. Hettak, T. Ross, J. Wight, and G. Morin, “DC to 70 GHz 90 nm 3D CMOS SPDT using Elevated CPW and CPS Series Stubs”, 2011 IEEE
[23] M-C. Yeh. Z-M. Tsai and H. Wang, “A Miniature DC-to-50 GHz CMOS SPDT Distributed Switch”, IEEE
[24] H-Y. Chang, and C-Y. Chan, “A Low Loss High Isolation DC-60 GHz SPDT Traveling-Wave Switch With a Body Bias Technique in 90 nm CMOS Process”, IEEE Microwave and Wireless Components Letters, Vol. 20, no. 2, February 2010
[25] S-F. Chao, H. Wang, C-Y. Su, and J. G. J Chern, “A 50 to 94 GHz CMOS SPDT Switch using Traveling-Wave Concept”, IEEE Microwave and Wireless Components Letters, Vol. 17, no. 2, February 2007
[26] T. Quémerais, L. Moquillon, J.-M. Fournier, P. Benech, “A SPDT Switch in a standard 45 nm CMOS process for 94 GHz Applications”, Proceedings of the 40^{th} European Microwave Conference, September 2011
[27] X. Guan, G. Li, and Z. Ma, “Optimized Design of a Low-Pass Filter Using Defected Ground Structures”, APMC2005 Proceedings, 2005
[28] X. Q. Chen, R. Li, S. J. Shi, Q. Wang, L. Xu, and X. W. Shi, “A Novel Low Pass Filter Using Elliptic Shape Defective Ground Structure”, Progress in Electromagnetics Research B, Vol. 9, pp. 117-126, 2008
[29] N. A. Talwalkar, C. P. Yue, G. Haitao, and S. S. Wong, “Integrated CMOS transmit-receive switch using LC-tuned substrate bias for 2.4 GHz and 5.2 GHz applications,” IEEE J. Solid-State Circuits, Vol. 39, no. 6, pp. 863-870, June 2004
[30] M-C. Yeh, Z-M. Tsai, R-C. Liu, K. Y. Lin, Y.-T. Chang and H. Wang, “Design and analysis for a miniature CMOS SPDT switch using body-floating technique to improve power performance,” IEEE Trans. Microw. Theory Tech, Vol. 54, no. 1, pp. 31-39, January 2006
[31] T. Ohnakado, S. Yamakawa, T. Murakami, A. Furukawa, E. Taniguchi, H. Ueda, N. Suematsu, and T. Oomori, “21.5-dBm power-handling 5-GHz transmit/receive CMOS switch realized by voltage division effect of stacked transistor configuration with depletion-layer-extended transistors (DETs),” IEEE J. Solid-State Circuits, Vol. 39, no. 4, pp. 577-584, April 2004

1. A Single-Pole-Single-Throw (SPST) switch for controlling signal propagation between a first and second contact, the SPST switch comprising:
a control mechanism configured to allow signal propagation between the first and second contacts when the SPST switch is turned on and prevent signal propagation between the first and second contacts when the SPST switch is turned off; and
a compensating member having a transmission line and a ground plane, wherein signals allowed by the control mechanism to propagate between the first and second contacts propagate through the transmission line and wherein the ground plane comprises at least one defect configured and arranged with the transmission line so as to affect one or both of the inductance and capacitance of the transmission line when signals propagate through the transmission line.

2. A SPST switch according to claim 1, wherein the compensating member comprises a DGS LPF.

3. A SPST switch according to claim 1 or 2, wherein the ground plane comprises a plurality of first defects spaced apart from one another via one or more spaces and at least one second defect connecting a pair of the first defects across the one or more spaces, wherein the transmission line runs parallel and adjacent to at least part of the one or more spaces.

4. A SPST switch according to any one of the preceding claims, wherein the transmission line comprises bends along its length.

5. A SPST switch according to claim 4, wherein the transmission line comprises an s-shaped part.

6. A SPST switch according to any one of the preceding claims, wherein the control mechanism comprises at least one control element configured to sink signals from the first contact or from the second contact to ground when the SPST switch is turned off, thereby preventing signal propagation between the first and second contacts.

7. A SPST switch according to any one of claims 1-5, wherein the control mechanism comprises at least one control element configured to act as an open circuit between the first and second contacts when the SPST switch is turned off, thereby preventing signal propagation between the first and second contacts.

8. A SPST switch according to claim 7, wherein the SPST switch further comprises at least one further control element configured to sink signals from the first contact or from the second contact to ground when the SPST switch is turned off.

9. A SPST switch according to any one of claims 6-8, wherein each control element comprises a transistor.

10. A switch for controlling signal propagation between a first set of ports and a second set of ports, wherein the switch comprises a plurality of SPST switches,
wherein each SPST switch is a SPST switch according to one of the preceding claims; and
wherein the first and second contacts for each SPST switch is located in the switch such that each SPST switch controls the signal propagation between a port in the first set of ports and a port in the second set of ports.

11. A switch according to claim 10, wherein each SPST switch is a SPST switch according to claim 6, and wherein the switch further comprises isolating means configured to perform one or both of the following: (i) isolate the ports in the first set of ports from one another; (ii) isolate the ports in the second set of ports from one another.

12. A switch according to claim 11, wherein the isolating means comprises at least one λ/4-wavelength transformer configured to serve as a high impedance node.

13. A switch according to claim 11, wherein the isolating means comprises at least one blocking capacitance.

14. A switch according to claim 10, wherein each SPST switch is a SPST switch according to claim 8.

15. A switch according to claim 10, wherein the switch comprises at least one SPST switch according to claim 6 and at least one SPST switch according to claim 7.

16. A switch according to any one of claims 10-15, wherein the switch further comprises coupling means configured to couple the plurality of SPST switches together to allow signal propagation between a port in the first set of ports and a port in the second set of ports through one or more of the SPST switches.

17. A switch according to any one of claims 10-15, wherein a single compensating member serves as the compensating member for all the SPST switches such that signals propagate through the transmission line of the single compensating member whenever signals are allowed to propagate between a port in the first set of ports and a port in the second set of ports through one or more of the SPST switches.

18. A switch according to any one of claims 10-17, wherein the impedance of each SPST switch when the SPST switch is turned off is configured such that the impedance of the switch matches the impedance of one or more other components in a circuit the switch is to be used in.

19. A transmit/receive (T/R) switch for use in a TDMA system wherein the T/R switch comprises a switch according to any one of claims 10-18, with
the first set of ports comprising at least one transmitter port for connection to at least one transmitter and at least one receiver port for connection to at least one receiver, and
the second set of ports comprising at least one antenna port for connection to at least one antenna.

20. A SPST switch according to any one of claims 1-8, wherein the control mechanism comprises at least one transistor having a bulk and wherein the SPST switch further comprises a floating mechanism configured to float the bulk of said at least one transistor.

21. A switch according to any one of claims 10-18, wherein the control mechanism of at least one of the SPST switches comprises at least one transistor having a bulk, and wherein the switch further comprises a floating mechanism configured to float the bulk of said at least one transistor.

22. A switch according to claim 20 or 21 wherein the floating mechanism comprises at least one DGS LPF.

23. A method of designing a SPST switch according to any one of claims 1-9, the method comprising:
determining a length of the transmission line that allows the transmission line to operate at a first frequency above a particular frequency range; and
determining a size of the at least one defect of the ground plane that allows the at least one defect to affect one or both of the inductance and capacitance of the transmission line such that the SPST switch operates in the particular frequency range.

24. A method according to claim 23, wherein the method further comprises tuning the size of the at least one defect of the ground plane to allow the at least one defect to affect one or both of the inductance and capacitance of the transmission line such that the impedance of the SPST switch matches the impedance of one or more other components in a circuit the SPST switch is to be used in.

25. A DGS LPF comprising:
a transmission line through which signals can propagate; and
a ground plane comprising a plurality of first defects spaced apart from one another via one or more spaces and at least one second defect connecting a pair of the first defects across the one or more spaces;
wherein the transmission line runs parallel and adjacent to at least part of the one or more spaces and wherein the transmission line comprises bends along its length.

26. A DGS LPF according to claim 25, wherein the transmission line comprises an s-shaped part.
